(19) United States
(12) Patent Application Publication
(10) Pub. No.: US 2025/0244670 A1
(43) Pub. Date: Jul. 31, 2025

(54) ACTINIC RAY-SENSITIVE OR RADIATION-SENSITIVE RESIN COMPOSITION, ACTINIC RAY-SENSITIVE OR RADIATION-SENSITIVE FILM, PATTERN FORMING METHOD, AND METHOD FOR PRODUCING ELECTRONIC DEVICE

(71) Applicant: FUJIFILM CORPORATION, Tokyo (JP)

(72) Inventors: Tsutomu Yoshimura, Shizuoka (JP); Masafumi Kojima, Shizuoka (JP); Akiyoshi Goto, Shizuoka (JP); Asahi Takaki, Shizuoka (JP); Hideyuki Ishihara, Shizuoka (JP)

(21) Appl. No.: 19/003,811

(22) Filed: Dec. 27, 2024

Related U.S. Application Data
(63) Continuation of application No. PCT/JP2023/023009, filed on Jun. 21, 2023.

(30) Foreign Application Priority Data
Jun. 29, 2022 (JP) 2022-105177

(51) Int. Cl. G03F 7/039; C08F 20/10; G03F 7/00; G03F 7/004

(52) U.S. Cl. CPC G03F 7/0397; C08F 20/10; G03F 7/0046; G03F 7/70033

(57) ABSTRACT

The present invention provides an actinic ray-sensitive or radiation-sensitive resin composition containing a resin (A) including a repeating unit (i) represented by a specified formula (1) and a repeating unit (ii) represented by a specified formula (2), and an ionic compound (Y) having an anionic moiety represented by a specified formula (3) in which a structure represented by “—SO₂—N⁻—” in the anionic moiety has a pKa of −3.00 or more; an actinic ray-sensitive or radiation-sensitive film formed from the actinic ray-sensitive or radiation-sensitive resin composition; a pattern forming method and a method for producing an electronic device that use the actinic ray-sensitive or radiation-sensitive resin composition.

### CROSS REFERENCE TO RELATED APPLICATION

This is a continuation of International Application No. PCT/JP2023/023009 filed on Jun. 21, 2023, and claims priority from Japanese Patent Application No. 2022-105177 filed on Jun. 29, 2022, the entire disclosures of which are incorporated herein by reference.

### BACKGROUND OF THE INVENTION

### 1. Field of the Invention

The present invention relates to an actinic ray-sensitive or radiation-sensitive resin composition, an actinic ray-sensitive or radiation-sensitive film, a pattern forming method, and a method for producing an electronic device.

### 2. Description of the Related Art

In the manufacturing process of semiconductor devices such as IC (Integrated Circuit, integrated circuits) and LSI (LargeScale Integrated circuit, large-scale integrated circuits), microfabrication by lithography using photosensitive compositions has been performed.

Examples of the lithography method include a method of using a photosensitive composition to form a resist film, subsequently exposing the obtained film, and subsequently developing the film. In particular, in recent years, the use of, in addition to the ArF excimer laser, EB (Electron Beam) or EUV (Extreme ultraviolet) light during exposure has been studied, and an actinic ray-sensitive or radiation-sensitive resin composition suitable for EUV exposure has been developed.

In the formation of a resist pattern using EUV (having a wavelength of 13.5 nm) or an electron beam for the purpose of forming a fine pattern, requirements for various performances are stricter than in the related-art cases of using ArF (having a wavelength of 193 nm) light or the like.

For example, JP2020-8842A and JP2020-503549A specifically disclose resist compositions including a resin having a repeating unit having a structure in which a polar group such as a phenolic hydroxyl group or a carboxyl group in methacrylic acid is protected by a group that leaves by the action of an acid and an ionic compound serving as a photoacid generator or an acid diffusion control agent.

JP2011-154216A discloses an actinic ray- or radiation-sensitive resin composition including a resin having a repeating unit having a structure in which a polar group such as a phenolic hydroxyl group or a carboxyl group in methacrylic acid is protected by a group that leaves by the action of an acid and a repeating unit that is decomposed upon irradiation with an actinic ray or a radiation to generate an acid.

### SUMMARY OF THE INVENTION

In recent years, with the reduction in the sizes of patterns formed using EUV light or an electron beam, further improvements in various performances have been in demand. In particular, there remains room for studies on defect suppression performance and roughness performance.

Accordingly, an object of the present invention is to provide an actinic ray-sensitive or radiation-sensitive resin composition having both of high defect suppression performance and high roughness performance in formation of an ultrafine pattern (for example, a line-and-space pattern having a line width or a space width of 30 nm or less, or a hole pattern having a hole diameter of 30 nm or less); an actinic ray-sensitive or radiation-sensitive film formed from the actinic ray-sensitive or radiation-sensitive resin composition, and a pattern forming method and a method for producing an electronic device that use the actinic ray-sensitive or radiation-sensitive resin composition.

The inventors of the present invention have found that the following features can address the above-described object.

[1]

An actinic ray-sensitive or radiation-sensitive resin composition containing:
a resin (A) including a repeating unit (i) represented by a formula (1) below and a repeating unit (ii) represented by a formula (2) below; and
an ionic compound (Y) having an anionic moiety represented by a formula (3) below in which a structure represented by “—SO₂—N⁻—” in the anionic moiety has a pKa of −3.00 or more,

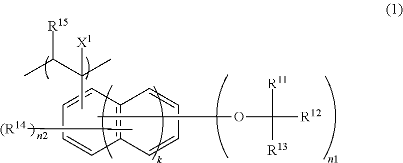

wherein, in the formula (1), X¹ represents a hydrogen atom, a halogen atom, a hydroxy group, or an organic group,
R¹¹ to R¹³ each independently represent an alkyl group having 1 to 12 carbon atoms or a cycloalkyl group having 3 to 12 carbon atoms, and any two among R¹¹ to R¹³ may be bonded together to form a ring,
R¹⁴ represents a halogen atom, a hydroxy group, or an organic group,
R¹⁵ represents a hydrogen atom or an organic group, and R¹⁵ may be bonded to R¹⁴ to form a ring,
k represents 0 or 1,
n1 represents an integer of 1 to 2k+5,
n2 represents an integer of 0 to 2k+4,

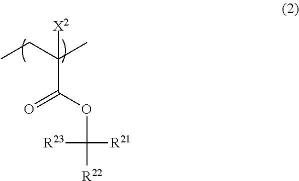

in the formula (2), X² represents a hydrogen atom, a halogen atom, a hydroxy group, or an organic group,
R²¹ to R²³ each independently represent a hydrocarbon group having 1 to 12 carbon atoms, any two among R²¹ to R²³ may be bonded together to form a ring, and a part of alkylene groups in R²¹ to R²³ may be converted into an ether group, a thioether group, or a carbonyl group,

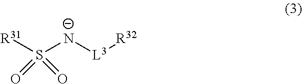

in the formula (3), R³¹ and R³² represent an organic group, and
L³ represents a single bond or a divalent linking group.
   [2]

The actinic ray-sensitive or radiation-sensitive resin composition according to [1], wherein the repeating unit represented by the formula (1) is a repeating unit represented by a formula (1A) below:

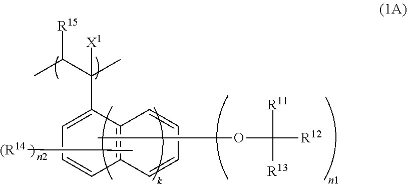

in the formula (1A), X¹ represents a hydrogen atom, a halogen atom, a hydroxy group, or an organic group,
R¹¹ to R¹³ each independently represent an alkyl group having 1 to 12 carbon atoms or a cycloalkyl group having 3 to 12 carbon atoms, and any two among R¹¹ to R¹³ may be bonded together to form a ring,
R¹⁴ represents a halogen atom, a hydroxy group, or an organic group,
R¹⁵ represents a hydrogen atom or an organic group, and R¹⁵ may be bonded to R¹⁴ to form a ring,
k represents 0 or 1,
n1 represents an integer of 1 to 2k+5, and
n2 represents an integer of 0 to 2k+4.
   [3]

The actinic ray-sensitive or radiation-sensitive resin composition according to [1], wherein the repeating unit represented by the formula (1) is a repeating unit represented by a formula (1a) below:

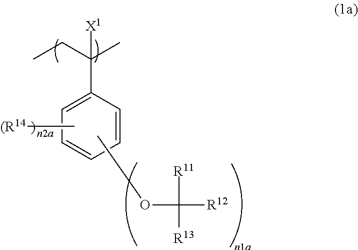

in the formula (1a), X¹ represents a hydrogen atom, a halogen atom, a hydroxy group, or an organic group,
R¹¹ to R¹³ each independently represent an alkyl group having 1 to 12 carbon atoms or a cycloalkyl group having 3 to 12 carbon atoms, and any two among R¹¹ to R¹³ may be bonded together to form a ring,
R¹⁴ represents a halogen atom, a hydroxy group, or an organic group,
n1a represents an integer of 1 to 5, and
n2a represents an integer of 0 to 4.
   [4]

The actinic ray-sensitive or radiation-sensitive resin composition according to any one of [1] to [3], wherein the anionic moiety represented by the formula (3) is an anionic moiety represented by a formula (3-1) below:

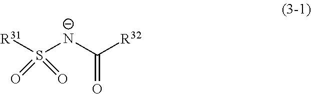

in the formula (3-1), R³¹ and R³² represent an organic group.
   [5]

The actinic ray-sensitive or radiation-sensitive resin composition according to any one of [1] to [4], wherein the repeating unit represented by the formula (2) is a repeating unit represented by a formula (2a) or a formula (2b) below:

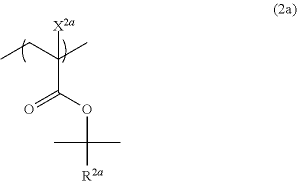

in the formula (2a), X^{2a} represents a hydrogen atom, a halogen atom, or a methyl group,
R^{2a} represents a methyl group, an ethyl group, a phenyl group, or an adamantyl group,

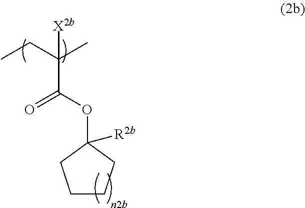

in the formula (2b), X^{2b} represents a hydrogen atom, a halogen atom, or a methyl group,
R^{2b} represents a hydrocarbon group having 6 or less carbon atoms, and
n2b represents 1 or 2.
   [6]

The actinic ray-sensitive or radiation-sensitive resin composition according to [3], wherein the repeating unit represented by the formula (1a) is a repeating unit represented by a formula (1b) below:

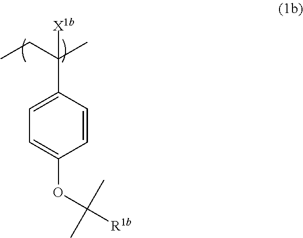

in the formula (1b), X^{1b} represents a hydrogen atom, a halogen atom, or a methyl group, and
R^{1b} represents a methyl group or an ethyl group.
   [7]

The actinic ray-sensitive or radiation-sensitive resin composition according to [5], wherein the repeating unit represented by the formula (2b) is a repeating unit represented by a formula (2c) below:

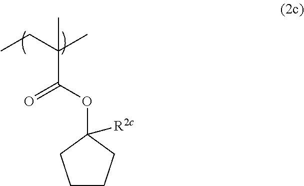

in the formula (2c), R^{2e} represents a methyl group, an ethyl group, an isopropyl group, a t-butyl group, or a phenyl group.
   [8]

The actinic ray-sensitive or radiation-sensitive resin composition according to any one of [1] to [7], wherein the resin (A) contains a repeating unit (iii) having a phenolic hydroxyl group.

[9]

An actinic ray-sensitive or radiation-sensitive film formed from the actinic ray-sensitive or radiation-sensitive resin composition according to any one of [1] to [8].

[10]

A pattern forming method including:
using the actinic ray-sensitive or radiation-sensitive resin composition according to any one of [1] to [8] to form an actinic ray-sensitive or radiation-sensitive film on a substrate;
exposing the actinic ray-sensitive or radiation-sensitive film; and
using a developer to develop the exposed actinic ray-sensitive or radiation-sensitive film to form a pattern.
   [11]

A method for producing an electronic device, the method including the pattern forming method according to [10].

The present invention can provide an actinic ray-sensitive or radiation-sensitive resin composition having both of high defect suppression performance and high roughness performance in formation of an ultrafine pattern (for example, a line-and-space pattern having a line width or a space width of 30 nm or less, or a hole pattern having a hole diameter of 30 nm or less); an actinic ray-sensitive or radiation-sensitive film formed from the actinic ray-sensitive or radiation-sensitive resin composition; and a pattern forming method and a method for producing an electronic device that use the actinic ray-sensitive or radiation-sensitive resin composition.

### DESCRIPTION OF THE PREFERRED EMBODIMENTS

Hereinafter, the present invention will be described in detail.

Features may be described below on the basis of representative embodiments according to the present invention; however, the present invention is not limited to the embodiments.

In this Specification, for written forms of groups (atomic groups), written forms without referring to substituted or unsubstituted encompass, in addition to groups not having a substituent, groups including a substituent without departing from the spirit and scope of the present invention. For example, “alkyl group” encompasses not only alkyl groups not having a substituent (unsubstituted alkyl groups), but also alkyl groups having a substituent (substituted alkyl groups). In this Specification, “organic group” refers to a group including at least one carbon atom.

The substituent is preferably a monovalent substituent unless otherwise specified.

In this Specification, in the case of using a phrase “may have a substituent”, the type of the substituent, the position of the substituent, and the number of such substituents are not particularly limited. The number of the substituents may be, for example, one, two, three, or more. Examples of the substituents include monovalent non-metallic atomic groups except for the hydrogen atom and, for example, can be selected from the group consisting of the following Substituents T.

### Substituents T

Substituents T include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and a tert-butylsulfanyl group; arylsulfanyl groups such as a phenylsulfanyl group and a p-tolylsulfanyl group; alkyl groups; cycloalkyl groups; aryl groups; heteroaryl groups; a hydroxyl group; a carboxyl group; a formyl group; a sulfo group; a cyano group; alkylaminocarbonyl groups; arylaminocarbonyl groups; a sulfonamide group; a silyl group; an amino group; monoalkylamino groups; dialkylamino groups; arylamino groups; a nitro group; a formyl group; and combinations of the foregoing.

In this Specification, “actinic ray” or “radiation” means, for example, the emission line spectrum of a mercury lamp, far-ultraviolet rays represented by excimer lasers, extreme ultraviolet rays (EUV: Extreme Ultraviolet), X-rays, or an electron beam (EB: Electron Beam).

In this Specification, “light” means an actinic ray or a radiation.

In this Specification, “exposure” includes, unless otherwise specified, not only exposure using, for example, the emission line spectrum of a mercury lamp, far-ultraviolet rays represented by excimer lasers, extreme ultraviolet rays, or X-rays, but also patterning using a corpuscular beam such as an electron beam or an ion beam.

In this Specification, “a value ‘to’ another value” is used to mean that it includes the value and the other value as the lower limit value and the upper limit value.

In this Specification, the bonding directions of divalent linking groups are not limited to the written forms unless otherwise specified. For example, in a compound represented by a formula “X—Y—Z” where Y is —COO—, Y may be —CO—O— or may be —O—CO—. The compound may be “X—CO—O—Z” or may be “X—O—CO—Z”.

In this Specification, (meth)acrylate represents acrylate and methacrylate, and (meth)acrylic represents acrylic and methacrylic.

In this Specification, the weight-average molecular weight (Mw), the number-average molecular weight (Mn), and the dispersity (hereafter, also referred to as “molecular weight distribution”) (Mw/Mn) are defined as polystyrene-equivalent values measured using a GPC (Gel Permeation Chromatography) apparatus (HLC-8120GPC manufactured by Tosoh Corporation) by GPC measurement (solvent: tetrahydrofuran, flow rate (sample injection amount): 10 μL, column: TSK gel Multipore HXL-M manufactured by Tosoh Corporation, column temperature: 40° C., flow rate: 1.0 mL/min, detector: differential refractive index detector (Refractive Index Detector)).

In this Specification, the acid dissociation constant (pKa) represents pKa in an aqueous solution, specifically, a value determined using the following Software package 1, on the basis of the Hammett's substituent constant and the database of values in publicly known documents, by calculation. All the values of pKa described in this Specification are values determined by calculation using this software package.

Software package 1: Advanced Chemistry Development (ACD/Labs) Software V8.14 for Solaris (1994-2007 ACD/Labs)

Alternatively, pKa can be determined by a molecular orbital calculation method. Specifically, this method may be a method of, on the basis of a thermodynamic cycle, calculating H⁺ dissociation free energy in a solvent to achieve the determination. (Note that, in this Specification, the solvent employed is ordinarily water; in the case where the use of water cannot determine pKa, DMSO (dimethyl sulfoxide) is used.)

As the calculation method for H⁺ dissociation free energy, for example, DFT (density function theory) can be performed for calculation; however, other various methods have been reported in documents and the like and the calculation method is not limited to DFT. Note that there are a plurality of pieces of software for performing DFT, such as Gaussian 16.

In this Specification, as described above, pKa refers to a value determined using Software package 1, on the basis of the Hammett's substituent constant and the database of values in publicly known documents, by calculation; however, when use of this method cannot determine pKa, a value determined on the basis of DFT (density functional theory) using Gaussian 16 is employed.

In this Specification, “solid content” means components forming the actinic ray-sensitive or radiation-sensitive film and does not include solvents. As long as a component forms the actinic ray-sensitive or radiation-sensitive film, even when the component has the form of liquid, it is regarded as the solid content.

### Actinic Ray-Sensitive or Radiation-Sensitive Resin Composition

Hereinafter, an actinic ray-sensitive or radiation-sensitive resin composition of the present invention will be described.

An actinic ray-sensitive or radiation-sensitive resin composition of the present invention (hereafter, also referred to as “composition of the present invention”) is typically a resist composition, and may be a positive resist composition or may be a negative resist composition. The resist composition may be a resist composition for alkali development or may be a resist composition for organic-solvent development. The resist composition may be a chemical amplification resist composition or may be a non-chemical amplification resist composition. A composition of the present invention is typically a chemical amplification resist composition.

A composition of the present invention contains a resin (A) having a repeating unit (i) represented by a formula (1) below and a repeating unit (ii) represented by a formula (2) below, and
an ionic compound (Y) having an anionic moiety represented by a formula (3) below in which a structure represented by “—SO₂—N⁻—” in the anionic moiety (hereafter, also referred to as “—SO₂—N⁻—” moiety) has a pKa of −3.00 or more.

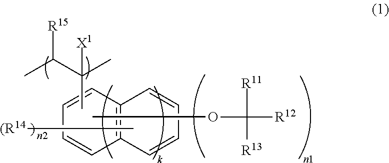

In the formula (1), X¹ represents a hydrogen atom, a halogen atom, a hydroxy group, or an organic group.

R¹¹ to R¹³ independently represent an alkyl group having 1 to 12 carbon atoms or a cycloalkyl group having 3 to 12 carbon atoms. Any two among R¹¹ to R¹³ may be bonded together to form a ring.

R¹⁴ represents a halogen atom, a hydroxy group, or an organic group.

R¹⁵ represents a hydrogen atom or an organic group. R⁵ may be bonded to R¹⁴ to form a ring.

k represents 0 or 1.

n1 represents an integer of 1 to 2k+5. n2 represents an integer of 0 to 2k+4.

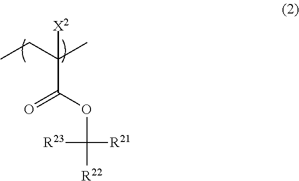

In the formula (2), X² represents a hydrogen atom, a halogen atom, a hydroxy group, or an organic group.

R²¹ to R²³ independently represent a hydrocarbon group having 1 to 12 carbon atoms. Any two among R²¹ to R²³ may be bonded together to form a ring. A part of alkylene groups in R²¹ to R²³ may be converted into an ether group, a thioether group, or a carbonyl group.

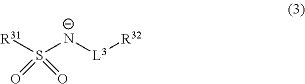

In the formula (3), R³¹ and R³² represent an organic group.

L³ represents a single bond or a divalent linking group.

Hereinafter, first, various components of the actinic ray-sensitive or radiation-sensitive resin composition will be described in detail.

### Resin (A)

A composition of the present invention includes a resin (A), which is a resin that is decomposed by the action of an acid to have increased polarity.

The resin (A) includes a group that is decomposed by the action of an acid to have increased polarity (hereafter, also referred to as “acid-decomposable group”) and has, as repeating units having an acid-decomposable group, a repeating unit (i) represented by a formula (1) below and a repeating unit (ii) represented by a formula (2) below.

The resin (A) is an acid-decomposable resin and, in a pattern forming method in this Specification, typically, in the case of employing a developer that is an alkali developer, a positive-type pattern is suitably formed or, in the case of employing a developer that is an organic-based developer, a negative-type pattern is suitably formed.

The acid-decomposable group refers to a group that is decomposed by the action of an acid to generate a polar group. The acid-decomposable group preferably has a structure in which the polar group is protected with a group (leaving group) that leaves by the action of an acid. Thus, the resin (A) has a repeating unit having a group that is decomposed by the action of an acid to generate a polar group. The resin having the repeating unit is subjected to the action of an acid to have increased polarity to have an increased degree of solubility in the alkali developer, but have a decreased degree of solubility in organic solvents. Repeating unit (i) represented by formula (1)

The resin (A) has a repeating unit (i) represented by the following formula (1).

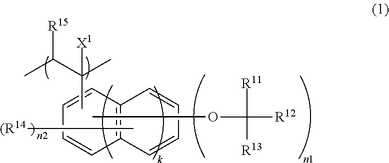

In the formula (1), X¹ represents a hydrogen atom, a halogen atom, a hydroxy group, or an organic group.

R¹¹ to R¹³ independently represent an alkyl group having 1 to 12 carbon atoms or a cycloalkyl group having 3 to 12 carbon atoms. Any two among R¹¹ to R¹³ may be bonded together to form a ring.

R¹⁴ represents a halogen atom, a hydroxy group, or an organic group.

R¹⁵ represents a hydrogen atom or an organic group. R¹⁵ may be bonded to R¹⁴ to form a ring.

k represents 0 or 1.

n1 represents an integer of 1 to 2k+5. n2 represents an integer of 0 to 2k+4.

In the formula (1), X¹ represents a hydrogen atom, a halogen atom, a hydroxy group, or an organic group.

For X¹, the halogen atom may be a fluorine atom, a chlorine atom, a bromine atom, or an iodine atom, and is preferably a fluorine atom.

For X¹, the organic group may be, for example, an alkyl group (preferably having 1 to 6 carbon atoms), an aryl group (preferably having 6 to 10 carbon atoms), an alkoxy group (preferably having 1 to 6 carbon atoms), or a carboxy group. The alkyl group, the aryl group, and the alkoxy group may have a substituent.

In a preferred example, the organic group represented by X¹ is preferably an alkyl group that may have a substituent, and may be, for example, a methyl group or a group represented by —CH₂—R₁₀₁. R₁₀₁ represents a halogen atom (such as a fluorine atom), a hydroxyl group, or a monovalent organic group, may be, for example, an alkyl group having 5 or less carbon atoms that may be substituted with a halogen atom, an acyl group having 5 or less carbon atoms that may be substituted with a halogen atom, or an alkoxy group having 5 or less carbon atoms that may be substituted with a halogen atom, is preferably an alkyl group having 3 or less carbon atoms, and more preferably a methyl group.

X¹ is preferably a hydrogen atom, a halogen atom, or a methyl group, and more preferably a hydrogen atom, a fluorine atom, or a methyl group.

In the formula (1), R¹¹ to R¹³ independently represent an alkyl group having 1 to 12 carbon atoms that may have a substituent, or a cycloalkyl group having 3 to 12 carbon atoms that may have a substituent. Any two among R¹¹ to R¹³ may be bonded together to form a ring.

Note that, when R¹¹ to R¹³ have a substituent, the number of carbon atoms including the number of carbon atoms included in the substituent is in the above-described range of the number of carbon atoms.

For R¹¹ to R¹³, the alkyl group may be a linear or branched alkyl group having 1 to 12 carbon atoms such as a methyl group, an ethyl group, an n-propyl group, an isopropyl group, an n-butyl group, an isobutyl group, a t-butyl group, an n-pentyl group, an n-hexyl group, an n-decyl group, or an n-dodecyl group, is preferably a linear or branched alkyl group having 1 to 5 carbon atoms, and more preferably a methyl group or an ethyl group.

For R¹¹ to R¹³, the cycloalkyl group may be a monocyclic cycloalkyl group such as a cyclopentyl group and a cyclohexyl group or a polycyclic cycloalkyl group such as a norbornyl group, a tetracyclodecanyl group, a tetracyclododecanyl group, or an adamantyl group, and is preferably a monocyclic cycloalkyl group having 5 to 6 carbon atoms.

The ring formed by bonding together two among R¹¹ to R¹³ is preferably a cycloalkyl group. The cycloalkyl group formed by bonding together two among R¹¹ to R¹³ may be a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group, and is more preferably a monocyclic cycloalkyl group having 5 to 6 carbon atoms.

In the cycloalkyl group formed by bonding together two among R¹¹ to R¹³, one of the methylene groups constituting the ring may be replaced by a heteroatom such as an oxygen atom, a group including a heteroatom such as a carbonyl group, or a vinylidene group. In the cycloalkyl group, one or more ethylene groups constituting the cycloalkane ring may be replaced by vinylene groups.

When n1 represents an integer of 2 or more, a plurality of R¹¹ may be the same or different, a plurality of R¹² may be the same or different, and a plurality of R¹³ may be the same or different.

In the formula (1), R¹⁴ represents a halogen atom, a hydroxy group, or an organic group.

For R¹⁴, the halogen atom may be a fluorine atom, a chlorine atom, a bromine atom, or an iodine atom, and is preferably a fluorine atom.

For R¹⁴, the organic group may be, for example, an alkyl group (preferably having 1 to 6 carbon atoms), an aryl group (preferably having 6 to 10 carbon atoms), an alkoxy group (preferably having 1 to 6 carbon atoms), or a carboxy group. The alkyl group, the aryl group, and the alkoxy group may have a substituent.

R¹⁴ is preferably a halogen atom or a hydroxy group, and more preferably a fluorine atom or a hydroxy group.

When n2 represents an integer of 2 or more, a plurality of R¹⁴ may be the same or different.

In the formula (1), R¹⁵ represents a hydrogen atom or an organic group. R¹⁵ may be bonded to R¹⁴ to form a ring.

For R¹⁵, the organic group may be, for example, the above-described organic group represented by X¹.

R¹⁵ is preferably a hydrogen atom.

When the above-described groups each have a substituent, examples of the substituent include alkyl groups (having 1 to 4 carbon atoms), halogen atoms, a hydroxyl group, alkoxy groups (having 1 to 4 carbon atoms), a carboxyl group, and alkoxycarbonyl groups (having 2 to 6 carbon atoms). The substituent preferably has 8 or less carbon atoms.

In the formula (1), k represents 0 or 1, and is preferably 0.

In the formula (1), n1 represents an integer of 1 to 2k+5, and is preferably 1 or 2.

In the formula (1), n2 represents an integer of 0 to 2k+4, and is preferably 0 or 1.

As will be described later, the inventors of the present invention have focused on the type of the ionic compound and the type of the resin contained in the composition in order to further suppress aggregation within the ionic compound.

First, a composition of the present invention was provided so as to contain a resin (A) having a repeating unit (i) represented by the formula (1) and serving as a repeating unit having an acid-decomposable group, and an ionic compound (Y) having a structure represented by “—SO₂—N⁻—” in the anionic moiety (hereafter, also simply referred to as —SO₂—N⁻—“moiety”); as a result, in formation of an ultrafine pattern, improved defect suppression performance was observed.

This is inferentially because, in the resin (A), the structure in which the aromatic ring and the carbon atom are bonded together via the oxygen atom in the formula (1) (for example, in the case of k=0, a phenol ether structure) and the “—SO₂—N⁻—” moiety in the anionic moiety in the ionic compound (Y) exhibit strong interaction during formation of an actinic ray-sensitive or radiation-sensitive film, so that the interaction within the ionic compound is further reduced and the ionic compound is more uniformly distributed in the actinic ray-sensitive or radiation-sensitive film.

The repeating unit represented by the formula (1) is preferably a repeating unit represented by the following formula (1A).

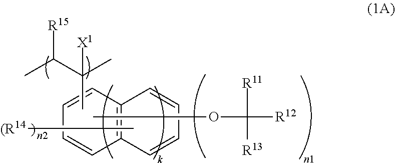

In the formula (1A), X¹ represents a hydrogen atom, a halogen atom, a hydroxy group, or an organic group.

R¹¹ to R¹³ independently represent an alkyl group having 1 to 12 carbon atoms or a cycloalkyl group having 3 to 12 carbon atoms. Any two among R¹¹ to R¹³ may be bonded together to form a ring.

R¹⁴ represents a halogen atom, a hydroxy group, or an organic group.

R¹⁵ represents a hydrogen atom or an organic group. R¹⁵ may be bonded to R¹⁴ to form a ring.

k represents 0 or 1.

n1 represents an integer of 1 to 2k+5. n2 represents an integer of 0 to 2k+4.

In the formula (1A), X¹, R¹¹ to R¹³, R¹⁴, R¹⁵, k, n1, and n2 respectively have the same definitions as X¹, R¹¹ to R¹³, R¹⁴, R¹⁵, k, n1, and n2 in the formula (1), and preferred examples thereof are also the same.

The repeating unit represented by the formula (1) is preferably a repeating unit represented by the following formula (1a).

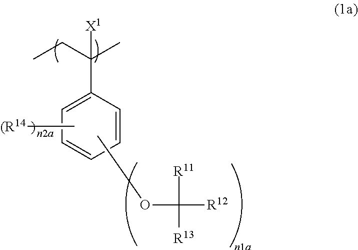

In the formula (1a), X¹ represents a hydrogen atom, a halogen atom, a hydroxy group, or an organic group.

R¹¹ to R¹³ independently represent an alkyl group having 1 to 12 carbon atoms or a cycloalkyl group having 3 to 12 carbon atoms. Any two among R¹¹ to R¹³ may be bonded together to form a ring.

R¹⁴ represents a halogen atom, a hydroxy group, or an organic group.

n1a represents an integer of 1 to 5. n2a represents an integer of 0 to 4.

X¹, R¹¹ to R¹³, and R¹⁴ in the formula (1a) respectively have the same definitions as X¹, R¹¹ to R¹³, and R¹⁴ in the formula (1), and preferred examples thereof are also the same.

In the formula (1a), n1a represents an integer of 1 to 5 and is preferably 1 or 2.

In the formula (1a), n2a represents an integer of 0 to 4 and is preferably 0 or 1.

The repeating unit represented by the formula (1a) is more preferably a repeating unit represented by the following formula (1b).

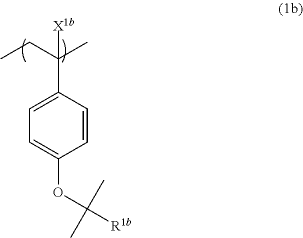

In the formula (1b), X^{1b} represents a hydrogen atom, a halogen atom, or a methyl group.

R^{1b} represents a methyl group or an ethyl group.

In the formula (1b), X^{1b} is preferably a hydrogen atom, a fluorine atom, or a methyl group.

The following are specific examples of the monomer corresponding to the repeating unit represented by the formula (1); however, the present invention is not limited thereto.

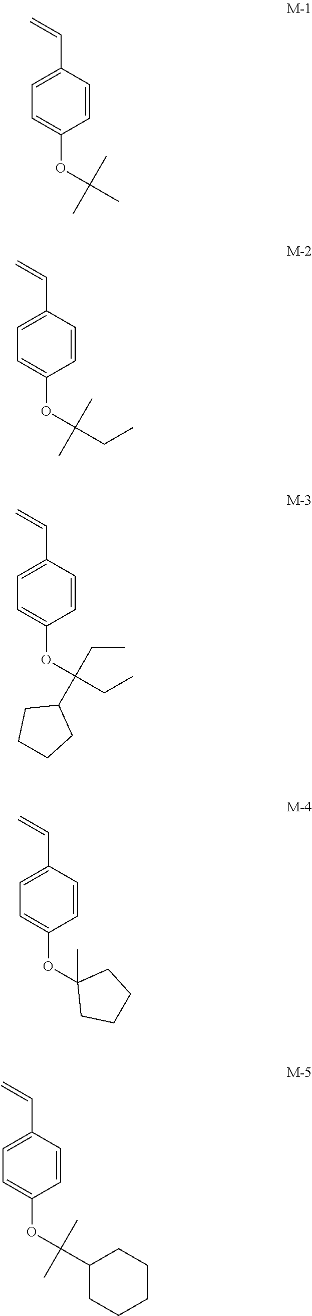

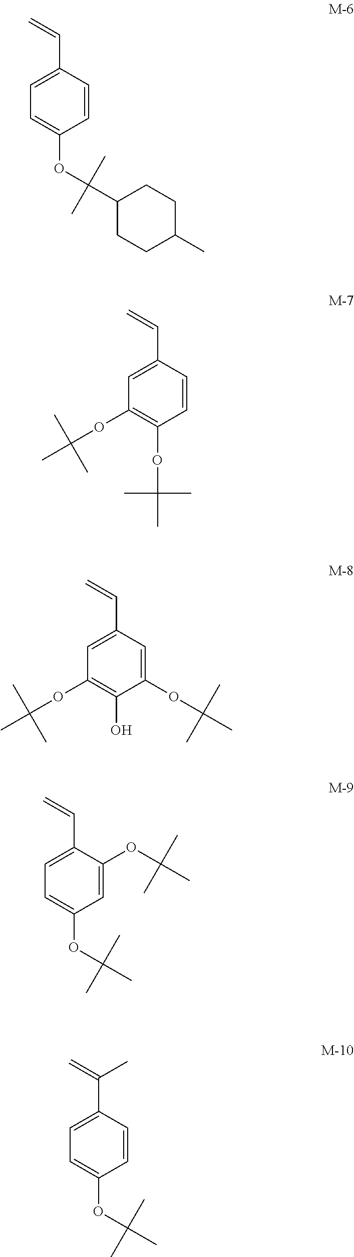

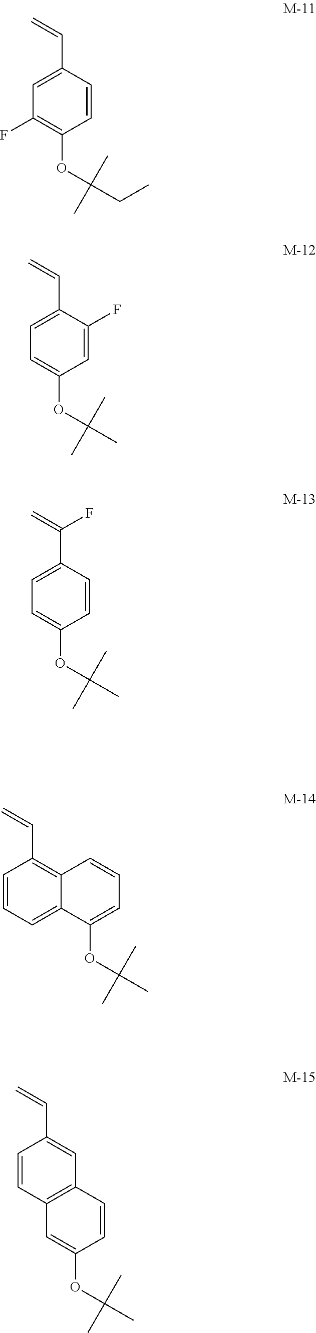

The content of the repeating unit (i) represented by the formula (1) is, relative to all the repeating units in the resin (A), preferably 5 mol % or more, more preferably 10 mol % or more, and still more preferably 15 mol % or more. The upper limit value relative to all the repeating units in the resin (A) is preferably 80 mol % or less, more preferably 70 mol % or less, still more preferably 60 mol % or less, and particularly preferably 50 mol % or less. Repeating unit (ii) represented by formula (2)

The resin (A) has a repeating unit (ii) represented by the following formula (2).

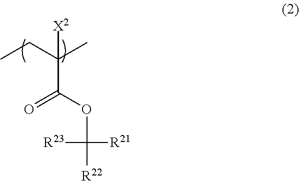

In the formula (2), X² represents a hydrogen atom, a halogen atom, a hydroxy group, or an organic group.

R²¹ to R²³ independently represent a hydrocarbon group having 1 to 12 carbon atoms. Any two among R²¹ to R²³ may be bonded together to form a ring. In R²¹ to R²³, a part of alkylene groups may be converted into an ether group, a thioether group, or a carbonyl group.

In the formula (2), X² represents a hydrogen atom, a halogen atom, a hydroxy group, or an organic group.

For X², the halogen atom may be a fluorine atom, a chlorine atom, a bromine atom, or an iodine atom, and is preferably a fluorine atom.

For X², the organic group may be, for example, an alkyl group (preferably having 1 to 6 carbon atoms), an aryl group (preferably having 6 to 10 carbon atoms), an alkoxy group (preferably having 1 to 6 carbon atoms), or a carboxy group. The alkyl group, the aryl group, and the alkoxy group may have a substituent.

In a preferred example, the organic group represented by X² is preferably an alkyl group that may have a substituent, and may be, for example, a methyl group or a group represented by —CH₂—R₁₀₁. R₁₀₁ represents a halogen atom (such as a fluorine atom), a hydroxyl group, or a monovalent organic group, may be, for example, an alkyl group having 5 or less carbon atoms that may be substituted with a halogen atom, an acyl group having 5 or less carbon atoms that may be substituted with a halogen atom, or an alkoxy group having 5 or less carbon atoms that may be substituted with a halogen atom, is preferably an alkyl group having 3 or less carbon atoms, and more preferably a methyl group.

X² is preferably a hydrogen atom, a halogen atom, or a methyl group, more preferably a hydrogen atom, a fluorine atom, or a methyl group, and still more preferably a methyl group.

In the formula (2), R²¹ to R²³ independently represent a hydrocarbon group that may have a substituent and has 1 to 12 carbon atoms.

Note that, when R²¹ to R²³ have a substituent, the number of carbon atoms including the number of carbon atoms included in the substituent is in the above-described range of the number of carbon atoms.

For R²¹ to R²³, the hydrocarbon group may be, for example, a linear or branched alkyl group, a monocyclic or polycyclic cycloalkyl group, an alkenyl group, a monocyclic or polycyclic cycloalkenyl group, an alkynyl group, or a monocyclic or polycyclic aryl group.

For R²¹ to R²³, the alkyl group is preferably an alkyl group having 1 to 4 carbon atoms such as a methyl group, an ethyl group, an n-propyl group, an isopropyl group, an n-butyl group, an isobutyl group, or a t-butyl group.

For R²¹ to R²³, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For R²¹ to R²³, the aryl group is preferably an aryl group having 6 to 10 carbon atoms, and may be, for example, a phenyl group or a naphthyl group.

For R²¹ to R²³, the alkenyl group is preferably a vinyl group.

For R²¹ to R²³, the alkynyl group is preferably an ethynyl group.

For R²¹ to R²³, the cycloalkenyl group is preferably a structure in which a monocyclic cycloalkyl group such as a cyclopentyl group or a cyclohexyl group partially includes a double bond.

The ring formed by bonding together two among R²¹ to R²³ is preferably a cycloalkyl group. The cycloalkyl group formed by bonding together two among R²¹ to R²³ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group. In particular, more preferred is a monocyclic cycloalkyl group having 5 to 6 carbon atoms.

When the groups have a substituent, examples of the substituent include an alkyl group (having 1 to 4 carbon atoms) that may be substituted with a halogen atom, a halogen atom, a hydroxyl group, an alkoxy group (having 1 to 4 carbon atoms), a carboxyl group, and an alkoxycarbonyl group (having 2 to 6 carbon atoms). The substituent preferably has 8 or less carbon atoms.

As described above, when the actinic ray-sensitive or radiation-sensitive resin composition contains the resin (A) having the repeating unit (i) represented by the formula (1) and the ionic compound (Y), the defect performance can be improved; however, in the case of the ultrafine pattern, such features still have room for further improvement in the roughness performance.

The reason for this was studied by the inventors of the present invention and they have inferred that the following is a cause: the repeating unit (i) represented by the formula (1) in the resin (A) tends to lower the difference in solubility in a developer between the exposed region and the unexposed region (hereafter, also simply referred to as “dissolution contrast”) in the formation of a pattern, and the dissolution contrast tends not to be sufficient particularly in the formation of the ultrafine pattern. In addition, they have inferred that the following is another cause: as described above, the structure in which the aromatic ring and the carbon atom are bonded together via the oxygen atom in the formula (1) (for example, in the case of k=0, a phenol ether structure) and the “—SO₂—N⁻—” moiety in the anionic moiety in the ionic compound (Y) interact with each other during formation of an actinic ray-sensitive or radiation-sensitive film, so that, from this viewpoint, the dissolution contrast tends to lower.

Accordingly, the inventors of the present invention performed thorough studies and, as a result, have provided a composition of the present invention in which the resin (A) further includes, as a repeating unit having an acid-decomposable group, a repeating unit (ii) represented by the formula (2), so that the composition exhibit, in addition to high defect suppression performance, high roughness performance.

This is inferentially because the repeating unit (ii) represented by the formula (2) contributes to improvement in dissolution contrast in pattern formation. In addition, in the exposed region, the carboxylic acid generated from the repeating unit represented by the formula (2) can appropriately reduce the interaction between the structure in which the aromatic ring and the carbon atom are bonded together via the oxygen atom in the formula (1) (for example, in the case of k=0, a phenol ether structure) and the “—SO₂—N⁻—” moiety in the anionic moiety in the ionic compound (Y) during the formation of the actinic ray-sensitive or radiation-sensitive film, which also contributes to the improvement in the dissolution contrast, inferentially.

The repeating unit represented by the formula (2) is preferably a repeating unit represented by the following formula (2a) or formula (2b).

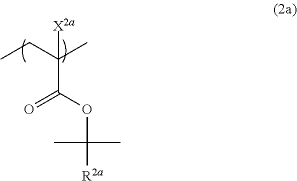

In the formula (2a), X^{2a} represents a hydrogen atom, a halogen atom, or a methyl group.

R^{2a} represents a methyl group, an ethyl group, a phenyl group, or an adamantyl group.

For X^{2a}, the halogen atom may be the above-described halogen atom represented by X², and preferred examples thereof are also the same.

X^{2a} is preferably a methyl group.

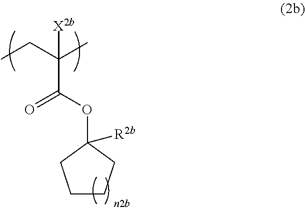

In the formula (2b), X^{2b} represents a hydrogen atom, a halogen atom, or a methyl group.

R^{2b} represents a hydrocarbon group having 6 or less carbon atoms.

n2b represents 1 or 2.

In the formula (2b), X^{2b} represents a hydrogen atom, a halogen atom, or a methyl group.

For X^{2b}, the halogen atom may be the above-described halogen atom represented by X², and preferred examples thereof are also the same.

X^{2b} is preferably a methyl group.

In the formula (2b), R^{2b} represents a hydrocarbon group having 6 or less carbon atoms.

For R^{2b}, the hydrocarbon group having 6 or less carbon atoms may be, for example, in the above-described examples of the hydrocarbon group for R²¹ to R²³, among the linear or branched alkyl groups, the monocyclic or polycyclic cycloalkyl groups, the alkenyl groups, the monocyclic or polycyclic cycloalkenyl groups, the alkynyl groups, and the monocyclic or polycyclic aryl groups, a group having 6 or less carbon atoms.

R^{2b} is preferably a linear or branched alkyl group having 6 or less carbon atoms, or a monocyclic aryl group.

In the formula (2b), n2b represents 1 or 2, and is preferably 1.

The repeating unit represented by the formula (2b) is preferably a repeating unit represented by the following formula (2c).

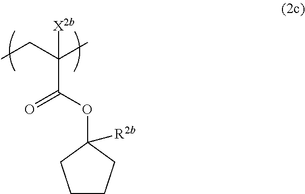

In the formula (2c), R^{2c} represents a methyl group, an ethyl group, an isopropyl group, a t-butyl group, or a phenyl group.

The following are specific examples of the monomer corresponding to the repeating unit represented by the formula (2); however, the present invention is not limited thereto.

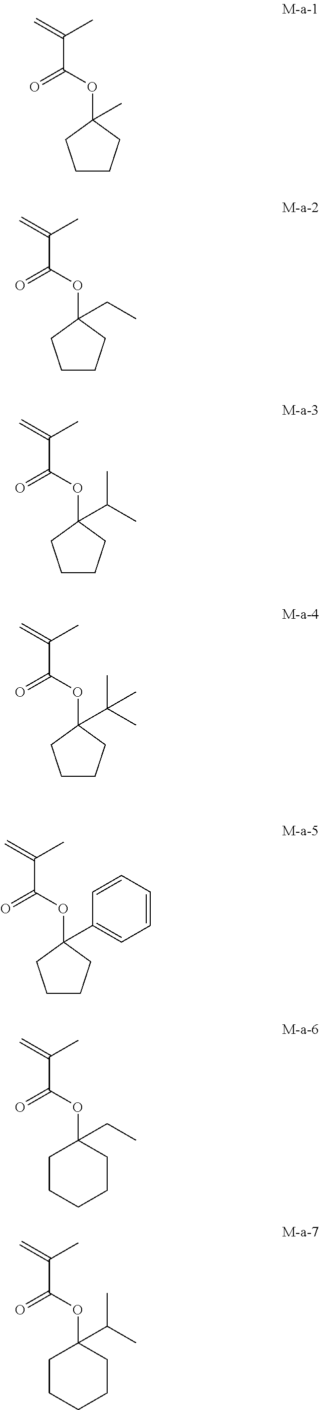

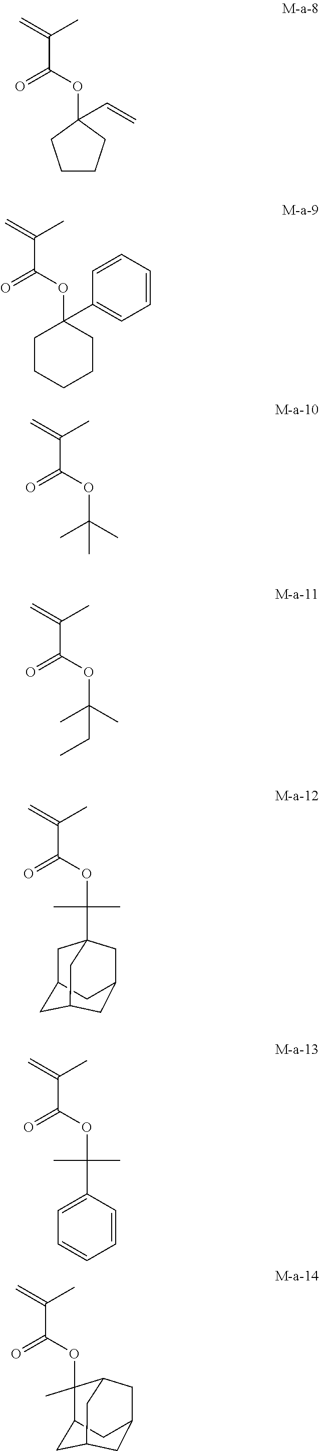

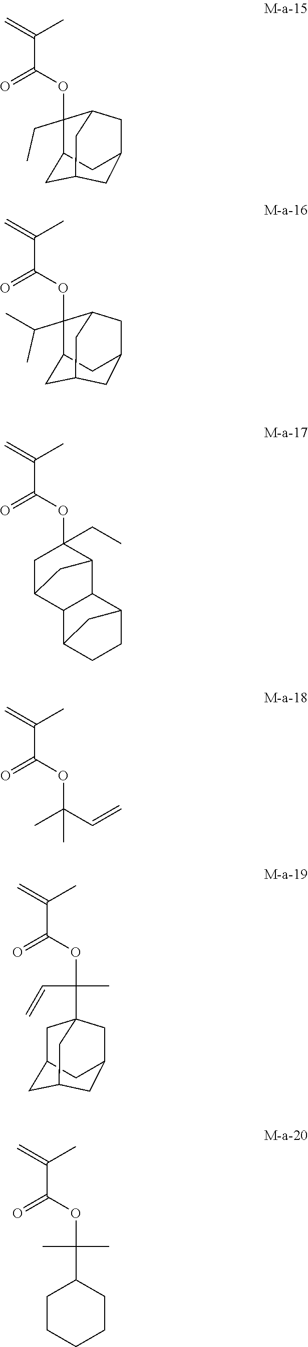

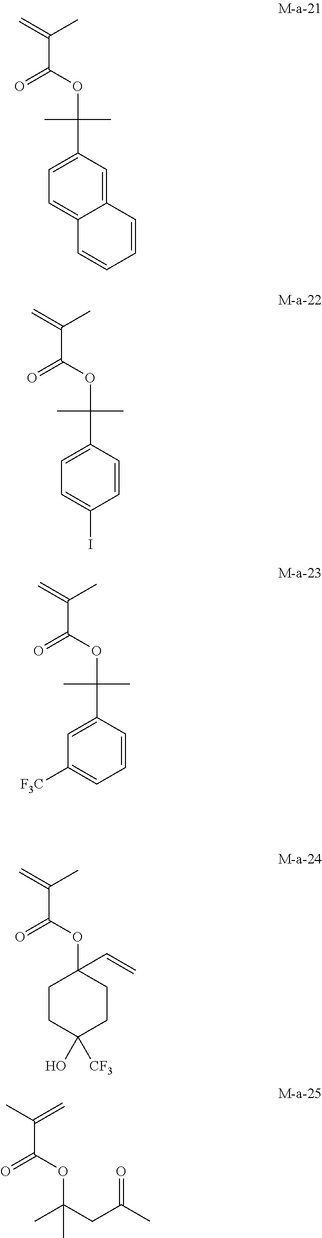

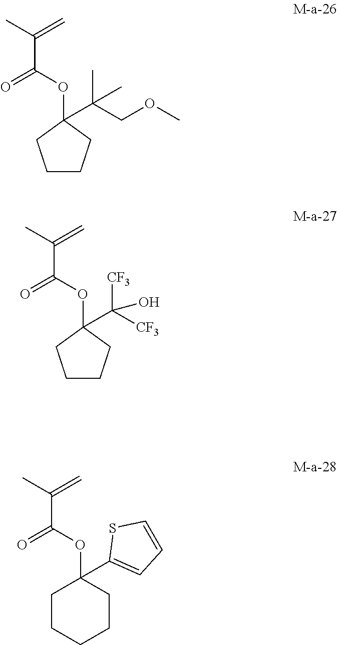

The content of the repeating unit (ii) represented by the formula (2) is, relative to all the repeating units in the resin (A), preferably 5 mol % or more, more preferably 10 mol % or more, and still more preferably 15 mol % or more. The upper limit value relative to all the repeating units in the resin (A) is preferably 80 mol % or less, more preferably 70 mol % or less, still more preferably 60 mol % or less, and particularly preferably 50 mol % or less. Other repeating unit having acid-decomposable group

The resin (A) may have, in addition to the above-described repeating units (i) and (ii), a repeating unit having an acid-decomposable group.

The acid-decomposable group preferably has a structure in which the polar group is protected with a group (leaving group) that leaves by the action of an acid. The polar group is preferably an alkali-soluble group; examples include acidic groups such as a carboxyl group, a phenolic hydroxyl group, fluorinated alcohol groups, a sulfonic acid group, a phosphoric acid group, a sulfonamide group, a sulfonylimide group, (alkylsulfonyl)(alkylcarbonyl)methylene groups, (alkylsulfonyl)(alkylcarbonyl)imide groups, bis(alkylcarbonyl)methylene groups, bis(alkylcarbonyl)imide groups, bis(alkylsulfonyl)methylene groups, bis(alkylsulfonyl)imide groups, tris(alkylcarbonyl)methylene groups, and tris(alkylsulfonyl)methylene groups, and an alcoholic hydroxyl group.

In particular, the polar group is preferably a carboxyl group, a phenolic hydroxyl group, a fluorinated alcohol group (preferably a hexafluoroisopropanol group), or a sulfonic acid group.

Examples of the group that leaves by the action of an acid include groups represented by formulas (Y1) to (Y4).

—C(Rx₁)(Rx₂)(Rx₃) formula (Y1):

—C(═O)OC(Rx₁)(Rx₂)(Rx₃) formula (Y2):

—C(R₃₆)(R₃₇)(OR₃₈) formula (Y3):

—C(Rn)(H)(Ar) formula (Y4):

In the formula (Y1) and the formula (Y2), Rx₁ to Rx₃ each independently represent an alkyl group (linear or branched), a cycloalkyl group (monocyclic or polycyclic), an alkenyl group (linear or branched), or an aryl group (monocyclic or polycyclic). Note that, when Rx₁ to Rx₃ are all alkyl groups (linear or branched), at least two among Rx₁ to Rx₃ are preferably methyl groups.

In particular, Rx₁ to Rx₃ preferably each independently represent a linear or branched alkyl group, and Rx₁ to Rx₃ more preferably each independently represent a linear alkyl group.

Two among Rx₁ to Rx₃ may be bonded together to form a monocycle or a polycycle.

When a composition of the present invention is, for example, an actinic ray-sensitive or radiation-sensitive resin composition for EUV exposure, the alkyl groups, cycloalkyl groups, alkenyl groups, and aryl groups represented by Rx₁ to Rx₃ and the ring formed by bonding together two among Rx₁ to Rx₃ also preferably further have, as a substituent, a fluorine atom or an iodine atom.

In the formula (Y3), R₃₆ to R₃₈ each independently represent a hydrogen atom or a monovalent organic group. R₃₇ and R₃₈ may be bonded together to form a ring.

Note that the alkyl group, the cycloalkyl group, the aryl group, and the aralkyl group may include a heteroatom such as an oxygen atom and/or a group including a heteroatom such as a carbonyl group.

R₃₈ and another substituent of the main chain of the repeating unit may be bonded together to form a ring.

When a composition of the present invention is, for example, an actinic ray-sensitive or radiation-sensitive resin composition for EUV exposure, the monovalent organic groups represented by R₃₆ to R₃₈ and the ring formed by bonding together R₃₇ and R₃₈ also preferably further have, as a substituent, a fluorine atom or an iodine atom.

The formula (Y3) is preferably a group represented by the following formula (Y3-1).

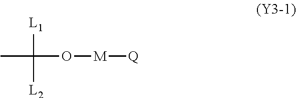

L₁ and L₂ each independently represent a hydrogen atom, an alkyl group, a cycloalkyl group, an aryl group, or a group that is a combination of the foregoing (for example, a group that is a combination of an alkyl group and an aryl group).

M represents a single bond or a divalent linking group.

Q represents an alkyl group that may include a heteroatom, a cycloalkyl group that may include a heteroatom, an aryl group that may include a heteroatom, an amino group, an ammonium group, a mercapto group, a cyano group, an aldehyde group, or a group that is a combination of the foregoing (for example, a group that is a combination of an alkyl group and a cycloalkyl group).

In the alkyl group and the cycloalkyl group, for example, one of methylene groups may be replaced by a heteroatom such as an oxygen atom or a group including a heteroatom such as a carbonyl group.

At least two among Q, M, and L₁ may be bonded together to form a ring (preferably a 5-membered or 6-membered ring).

From the viewpoint of forming finer patterns, L₂ is preferably a secondary or tertiary alkyl group, and more preferably a tertiary alkyl group. Examples of the secondary alkyl group include an isopropyl group, a cyclohexyl group, and a norbornyl group; examples of the tertiary alkyl group include a tert-butyl group and an adamantane group. In such examples, Tg (glass transition temperature) and activation energy are increased, so that film hardness is ensured and fogging can be suppressed.

When a composition of the present invention is, for example, an actinic ray-sensitive or radiation-sensitive resin composition for EUV exposure, the alkyl groups, cycloalkyl groups, aryl groups, and groups that are combinations of the foregoing represented by L₁ and L₂ also preferably further have, as a substituent, a fluorine atom or an iodine atom. The alkyl groups, the cycloalkyl groups, the aryl groups, and the aralkyl groups also preferably include, in addition to a fluorine atom and an iodine atom, a heteroatom such as an oxygen atom. Specifically, in the alkyl groups, the cycloalkyl groups, the aryl groups, and the aralkyl groups, for example, one of methylene groups may be replaced by a heteroatom such as an oxygen atom or a group including a heteroatom such as a carbonyl group.

When a composition of the present invention is, for example, an actinic ray-sensitive or radiation-sensitive resin composition for EUV exposure, in the alkyl group that may include a heteroatom, cycloalkyl group that may include a heteroatom, aryl group that may include a heteroatom, amino group, ammonium group, mercapto group, cyano group, aldehyde group, and group that is a combination of the foregoing represented by Q, such a heteroatom is also preferably a heteroatom selected from the group consisting of a fluorine atom, an iodine atom, and an oxygen atom.

In the formula (Y4), Ar represents an aromatic ring group. Rn represents an alkyl group, a cycloalkyl group, or an aryl group. Rn and Ar may be bonded together to form a non-aromatic ring. Ar is preferably an aryl group.

When a composition of the present invention is, for example, an actinic ray-sensitive or radiation-sensitive resin composition for EUV exposure, the aromatic ring group represented by Ar, and the alkyl group, the cycloalkyl group, and the aryl group represented by Rn also preferably have a fluorine atom or an iodine atom as a substituent.

From the viewpoint of providing a repeating unit having high acid-decomposability, in the leaving group protecting the polar group, when a non-aromatic ring is directly bonded to the polar group (or its residue), in the non-aromatic ring, a ring-member atom adjacent to a ring-member atom directly bonded to the polar group (or its residue) also preferably does not have, as a substituent, a halogen atom such as a fluorine atom.

Alternatively, the group that leaves by the action of an acid may be a 2-cyclopentenyl group having a substituent (such as an alkyl group) such as a 3-methyl-2-cyclopentenyl group, or a cyclohexyl group having a substituent (such as an alkyl group) such as a 1,1,4,4-tetramethylcyclohexyl group.

The repeating unit having an acid-decomposable group is also preferably a repeating unit represented by a formula (A).

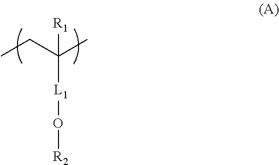

L₁ represents a divalent linking group that may have a fluorine atom or an iodine atom; R₁ represents a hydrogen atom, a fluorine atom, an iodine atom, or an alkyl group that may have a fluorine atom or an iodine atom, or an aryl group that may have a fluorine atom or an iodine atom; R₂ represents a leaving group that leaves by the action of an acid and that may have a fluorine atom or an iodine atom. Note that at least one of L₁, R₁, or R₂ has a fluorine atom or an iodine atom.

Examples of the divalent linking group that is represented by L₁ and may have a fluorine atom or an iodine atom include —CO—, —O—, —S—, —SO—, —SO₂—, hydrocarbon groups that may have a fluorine atom or an iodine atom (for example, alkylene groups, cycloalkylene groups, alkenylene groups, and arylene groups), and linking groups in which a plurality of the foregoing are linked together.

The alkyl group represented by R₁ may be linear or may be branched. The number of carbon atoms of the alkyl group is not particularly limited, but is preferably 1 to 10, and more preferably 1 to 3.

In the alkyl group represented by R₁ and having a fluorine atom or an iodine atom, the total number of fluorine atoms and iodine atoms is not particularly limited, but is preferably 1 or more, more preferably 1 to 5, and still more preferably 1 to 3.

The alkyl group represented by R₁ may include a heteroatom other than halogen atoms, such as an oxygen atom.

Examples of the leaving group that is represented by R₂ and may have a fluorine atom or an iodine atom include leaving groups that are represented by the above-described formulas (Y1) to (Y4) and that have a fluorine atom or an iodine atom.

The repeating unit having an acid-decomposable group is also preferably a repeating unit represented by a formula (AI).

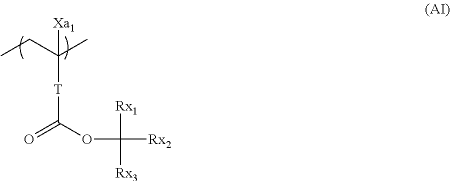

In the formula (AI), Xa₁ represents a hydrogen atom or an alkyl group that may have a substituent. T represents a single bond or a divalent linking group. Rx₁ to Rx₃ each independently represent an alkyl group (linear or branched), a cycloalkyl group (monocyclic or polycyclic), an alkenyl group (linear or branched), or an aryl (monocyclic or polycyclic) group. Note that, when Rx₁ to Rx₃ are all alkyl groups (linear or branched), at least two among Rx₁ to Rx₃ are preferably methyl groups.

Two among Rx₁ to Rx₃ may be bonded together to form a monocycle or polycycle (such as a monocyclic or polycyclic cycloalkyl group).

The alkyl group that is represented by Xa₁ and may have a substituent may be, for example, a methyl group or a group represented by —CH₂—R₁₁. R₁₁ represents a halogen atom (such as a fluorine atom), a hydroxy group, or a monovalent organic group.

For T, the divalent linking group may be an alkylene group, an aromatic ring group, a —COO-Rt- group, or an —O-Rt- group. In the formulas, Rt represent an alkylene group or a cycloalkylene group.

The repeating unit represented by the formula (AI) is preferably an acid-decomposable (meth)acrylic acid tertiary alkyl ester-based repeating unit (repeating unit in which Xa₁ represents a hydrogen atom or a methyl group and T represents a single bond).

The resin (A) may have, as a repeating unit having an acid-decomposable group, a repeating unit having an acid-decomposable group including an unsaturated bond. The repeating unit having an acid-decomposable group including an unsaturated bond is preferably a repeating unit represented by a formula (B).

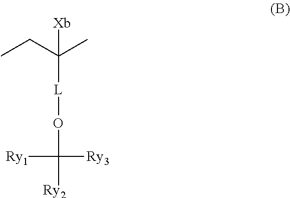

In the formula (B), Xb represents a hydrogen atom, a halogen atom, or an alkyl group that may have a substituent. L represents a single bond or a divalent linking group that may have a substituent. Ry₁ to Ry₃ each independently represent a linear or branched alkyl group, a monocyclic or polycyclic cycloalkyl group, an alkenyl group, an alkynyl group, or a monocyclic or polycyclic aryl group. Note that at least one of Ry₁ to Ry₃ represents an alkenyl group, an alkynyl group, a monocyclic or polycyclic cycloalkenyl group, or a monocyclic or polycyclic aryl group.

Two among Ry₁ to Ry₃ may be bonded together to form a monocycle or polycycle (such as a monocyclic or polycyclic cycloalkyl group or cycloalkenyl group).

The repeating unit represented by the formula (B) is preferably an acid-decomposable (meth)acrylic acid tertiary ester-based repeating unit (the repeating unit where Xb represents a hydrogen atom or a methyl group, and L represents a —CO— group), an acid-decomposable hydroxystyrene tertiary alkyl ether-based repeating unit (the repeating unit where Xb represents a hydrogen atom or a methyl group, and L represents a phenyl group), or an acid-decomposable styrenecarboxylic acid tertiary ester-based repeating unit (the repeating unit where Xb represents a hydrogen atom or a methyl group, and L represents an -Rt-CO— group (where Rt is an aromatic group)).

When the resin (A) includes another repeating unit having an acid-decomposable group, the content of the other repeating unit having an acid-decomposable group is, relative to all the repeating units in the resin (A), preferably 5 mol % or more, more preferably 10 mol % or more, and still more preferably 15 mol % or more. The upper limit value relative to all the repeating units in the resin (A) is preferably 90 mol % or less, more preferably 80 mol % or less, still more preferably 70 mol % or less, and particularly preferably 60 mol % or less.

Repeating Unit (iii) Having Phenolic Hydroxyl Group

The resin (A) preferably contains a repeating unit (iii) having a phenolic hydroxyl group. When the resin (A) contains the repeating unit (iii) having a phenolic hydroxyl group, the composition of the present invention can provide an actinic ray-sensitive or radiation-sensitive film having increased Tg. The higher the Tg of the actinic ray-sensitive or radiation-sensitive film, the further diffusion of the acid can be suppressed, so that defects during formation of an ultrafine pattern can be suppressed and the roughness performance is also improved, inferentially.

A composition of the present invention preferably contains a photoacid generator; the repeating unit (iii) has a phenolic hydroxyl group and hence has high compatibility with the photoacid generator. Therefore, in particular, when a composition of the present invention contains a photoacid generator, defects during formation of an ultrafine pattern can be further suppressed, and the LWR performance is also further improved, inferentially. Furthermore, the phenolic hydroxyl group of the repeating unit (iii) serves as a proton source and has hydrophilicity, to thereby increase the leaving reactivity of the acid-decomposable group, inferentially. The high leaving reactivity of the acid-decomposable group results in suppression of generation of defects and further improvement in the roughness performance, inferentially.

Note that the repeating unit (iii) having a phenolic hydroxyl group may be a repeating unit different from the above-described repeating units (i) and (ii), and the repeating units (i) and (ii) may have a phenolic hydroxyl group.

The repeating unit having a phenolic hydroxyl group is not particularly limited, but is preferably a repeating unit represented by the following formula (1).

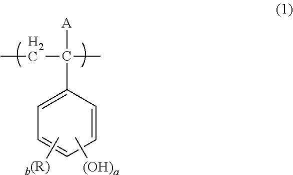

In the formula (1), A represents a hydrogen atom, an alkyl group, a cycloalkyl group, a halogen atom, or a cyano group. R represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group; when there are a plurality of R's, they may be the same or different. When there are a plurality of R's, they may together form a ring. R is preferably a hydrogen atom. a represents an integer of 1 to 3. b represents an integer of 0 to (5-a).

Examples of the repeating unit having a phenolic hydroxyl group are as follows. In the formulas, a represent an integer of 1 to 3.

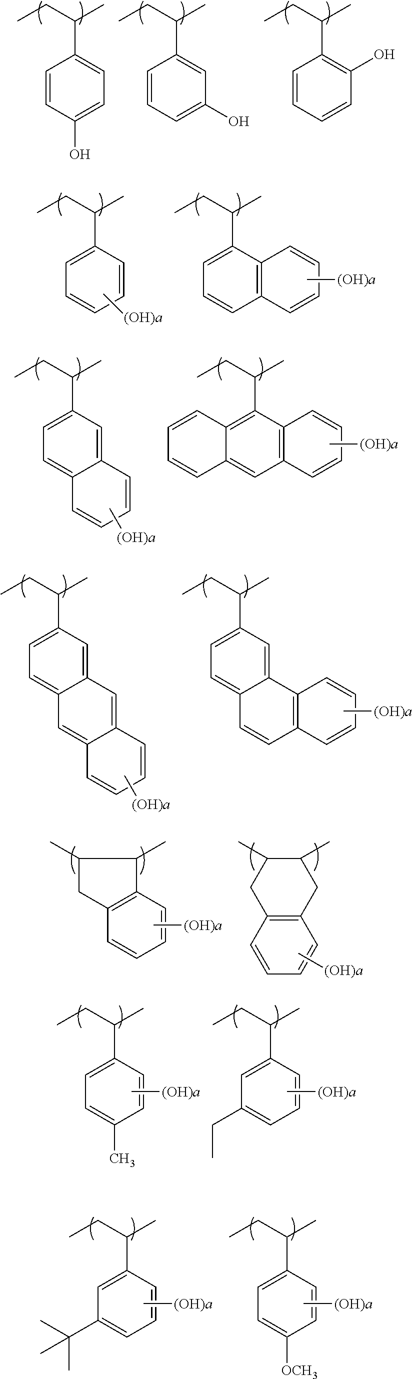

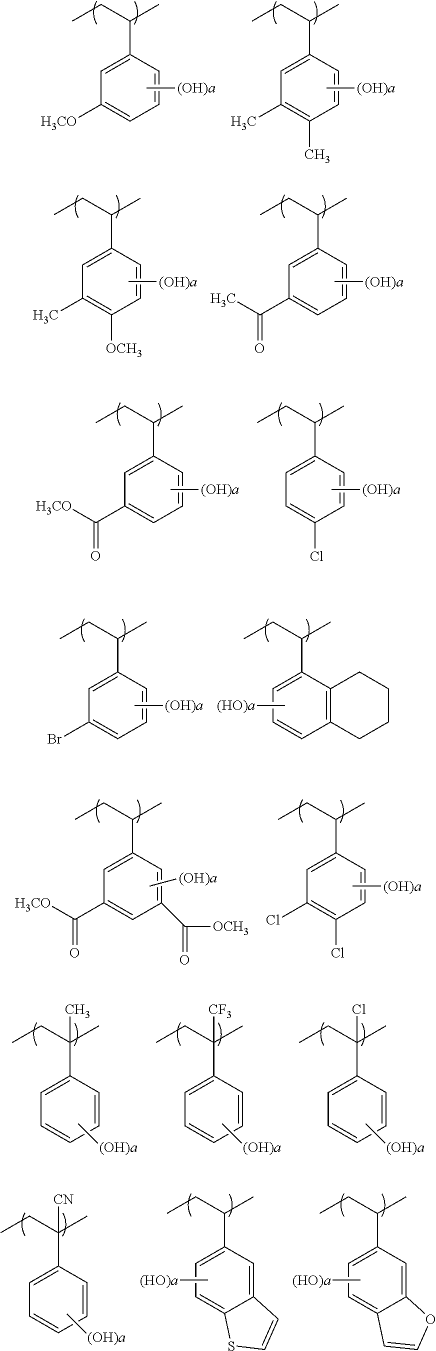

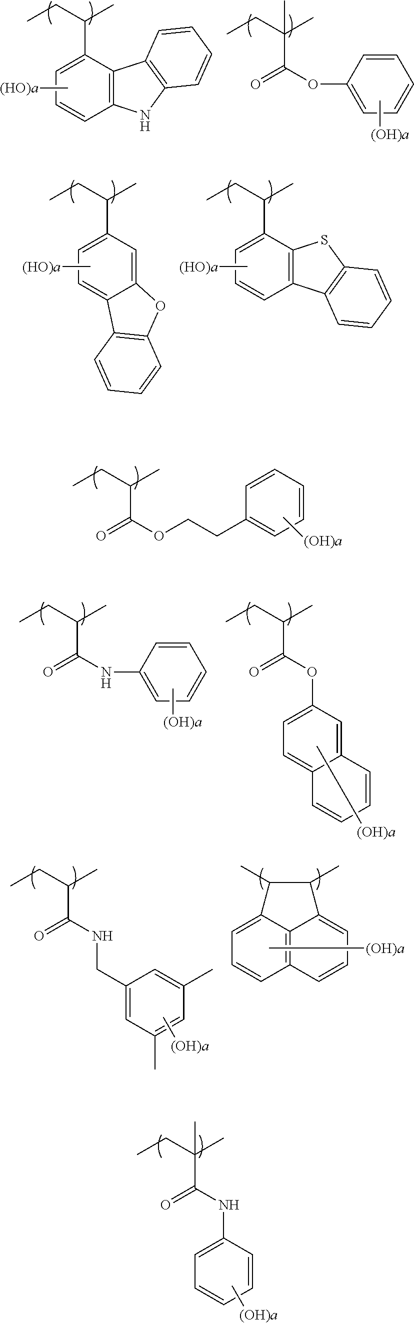

The following are examples described as monomer structures corresponding to the repeating unit having a phenolic hydroxyl group.

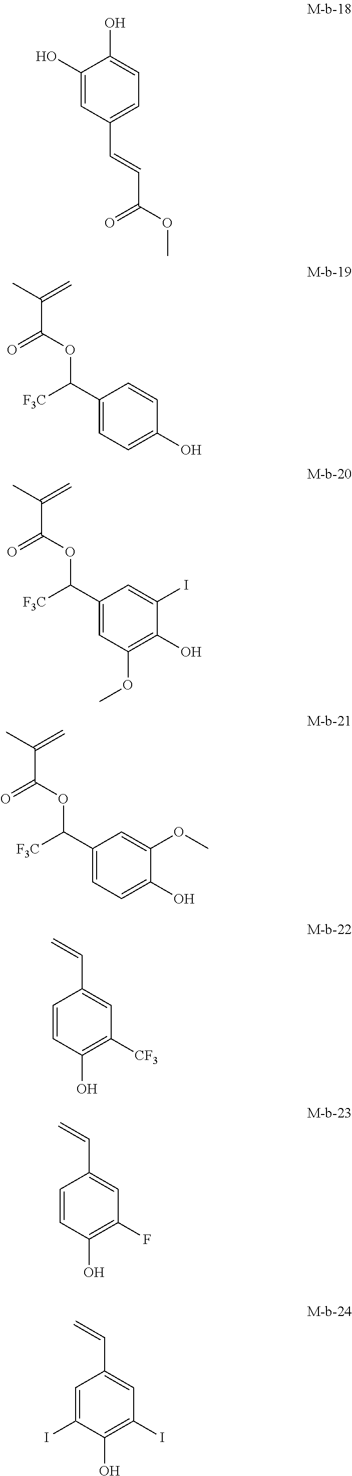

Note that, of the above-described repeating units, preferred are the following specific repeating units. In the formulas, R represent a hydrogen atom or a methyl group, and a represent an integer of 1 to 3.

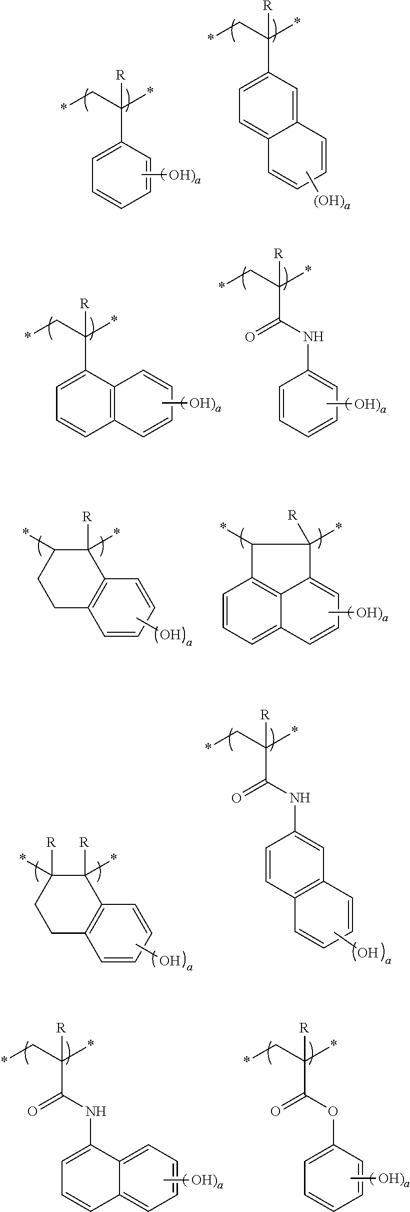

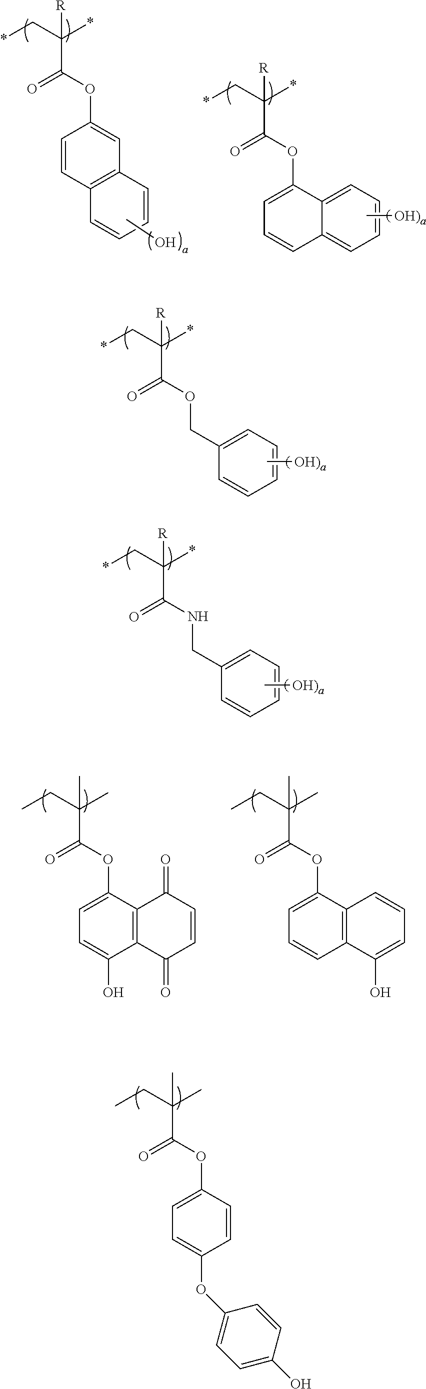

When the resin (A) includes a repeating unit having a phenolic hydroxyl group, the content of the repeating unit having a phenolic hydroxyl group is, relative to all the repeating units in the resin (A), preferably 5 mol % or more, and more preferably 10 mol % or more. The upper limit value relative to all the repeating units in the resin (A) is preferably 70 mol % or less, more preferably 65 mol % or less, and still more preferably 60 mol % or less.

The resin (A) may include at least one repeating unit species selected from the group consisting of the following Group A and/or at least one repeating unit species selected from the group consisting of the following Group B.

Group A: a group consisting of the following repeating units (20) to (24):
(20) a repeating unit (described later) having an acid group;
(21) a repeating unit (described later) not having an acid-decomposable group or an acid group, but having a fluorine atom, a bromine atom, or an iodine atom;
(22) a repeating unit (described later) having a lactone group, a sultone group, or a carbonate group;
(23) a repeating unit (described later) having a photoacid generation group; and
(24) a repeating unit (described later) represented by a formula (V-1) or a formula (V-2) below.

Group B: a group consisting of the following repeating units (30) to (32):
(30) a repeating unit (described later) having at least one group species selected from the group consisting of a lactone group, a sultone group, a carbonate group, a hydroxy group, a cyano group, and an alkali-soluble group;
(31) a repeating unit (described later) having an alicyclic hydrocarbon structure and not exhibiting acid-decomposability; and
(32) a repeating unit (described later) not having a hydroxy group or a cyano group and represented by a formula (III).

The resin (A) may have, in addition to the phenolic hydroxyl group, an acid group and, as described later, preferably includes a repeating unit having an acid group. Note that the definition of the acid group will be described in a later part together with preferred examples of the repeating unit having an acid group. When the resin (A) has an acid group, a better interaction between the resin (A) and the acid generated from the photoacid generator is provided. This results in further suppression of diffusion of the acid, so that a pattern having a more square profile can be formed.

The resin (A) may have at least one repeating unit species selected from the group consisting of Group A above. When a composition of the present invention is used as an actinic ray-sensitive or radiation-sensitive resin composition used for EUV exposure, the resin (A) preferably has at least one repeating unit species selected from the group consisting of Group A above.

The resin (A) may include at least one of a fluorine atom or an iodine atom. When a composition of the present invention is used as an actinic ray-sensitive or radiation-sensitive resin composition for EUV exposure, the resin (A) preferably includes at least one of a fluorine atom or an iodine atom. When the resin (A) includes both of a fluorine atom and an iodine atom, the resin (A) may have a repeating unit including both of a fluorine atom and an iodine atom, or the resin (A) may include two species that are a repeating unit having a fluorine atom and a repeating unit including an iodine atom.

The resin (A) may have a repeating unit having an aromatic group. When a composition of the present invention is used as an actinic ray-sensitive or radiation-sensitive resin composition for EUV exposure, the resin (A) also preferably has a repeating unit having an aromatic group.

### Repeating Unit Having Acid Group

The resin (A) may have a repeating unit having an acid group.

The acid group is preferably an acid group having a pKa of 13 or less. The acid group preferably has an acid dissociation constant of 13 or less, more preferably 3 to 13, and still more preferably 5 to 10.

When the resin (A) has an acid group having a pKa of 13 or less, the content of the acid group in the resin (A) is not particularly limited, but is often 0.2 to 6.0 mmol/g. In particular, preferred is 0.8 to 6.0 mmol/g, more preferred is 1.2 to 5.0 mmol/g, and still more preferred is 1.6 to 4.0 mmol/g. When the content of the acid group is within such a range, development suitably proceeds to form a pattern having a good profile at high resolution. The acid group is, for example, preferably a carboxyl group, a fluorinated alcohol group (preferably a hexafluoroisopropanol group), a sulfonic acid group, a sulfonamide group, or an isopropanol group.

In the hexafluoroisopropanol group, one or more (preferably one to two) of the fluorine atoms may be substituted with groups other than fluorine atoms (such as alkoxycarbonyl groups).

The acid group is also preferably —C(CF₃)(OH)—CF₂— formed in this manner. Alternatively, one or more of the fluorine atoms may be substituted with groups other than fluorine atoms, to form a ring including —C(CF₃)(OH)—CF₂—.

The repeating unit having an acid group is preferably a repeating unit different from the above-described repeating unit having a structure in which a polar group is protected with a group that leaves by the action of an acid and repeating units described later and having a lactone group, a sultone group, or a carbonate group.

The repeating unit having an acid group may have a fluorine atom or an iodine atom.

The content of the repeating unit having an acid group relative to all the repeating units in the resin (A) is preferably 10 mol % or more, and more preferably 15 mol % or more. The upper limit value relative to all the repeating units in the resin (A) is preferably 70 mol % or less, more preferably 65 mol % or less, and still more preferably 60 mol % or less. Repeating unit not having acid-decomposable group or acid group, but having fluorine atom, bromine atom, or iodine atom

The resin (A) may have, in addition to the above-described <repeating unit having an acid-decomposable group> and <repeating unit having an acid group>, a repeating unit not having an acid-decomposable group or an acid group, but having a fluorine atom, a bromine atom, or an iodine atom (hereafter, also referred to as unit X). This <repeating unit not having an acid-decomposable group or an acid group, but having a fluorine atom, a bromine atom, or an iodine atom> is preferably different from other repeating unit species belonging to Group A such as the <repeating unit having a lactone group, a sultone group, or a carbonate group> and the <repeating unit having a photoacid generation group> described later.

The unit X is preferably a repeating unit represented by a formula (C).

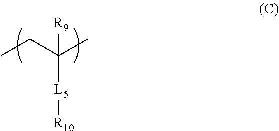

L₅ represents a single bond or an ester group. R₉ represents a hydrogen atom or an alkyl group that may have a fluorine atom or an iodine atom. R₁₀ represents a hydrogen atom, an alkyl group that may have a fluorine atom or an iodine atom, a cycloalkyl group that may have a fluorine atom or an iodine atom, an aryl group that may have a fluorine atom or an iodine atom, or a group that is a combination of the foregoing.

The unit X content relative to all the repeating units in the resin (A) is preferably 0 mol % or more, more preferably 5 mol % or more, and still more preferably 10 mol % or more. The upper limit value relative to all the repeating units in the resin (A) is preferably 50 mol % or less, more preferably 45 mol % or less, and still more preferably 40 mol % or less.

Of the repeating units of the resin (A), the total content of the repeating unit including at least one of a fluorine atom, a bromine atom, or an iodine atom relative to all the repeating units of the resin (A) is preferably 10 mol % or more, more preferably 20 mol % or more, still more preferably 30 mol % or more, and particularly preferably 40 mol % or more. The upper limit value is not particularly limited, but is, for example, relative to all the repeating units of the resin (A), 100 mol % or less.

Note that examples of the repeating unit including at least one of a fluorine atom, a bromine atom, or an iodine atom include a repeating unit having a fluorine atom, a bromine atom, or an iodine atom and having an acid-decomposable group, a repeating unit having a fluorine atom, a bromine atom, or an iodine atom and having an acid group, and a repeating unit having a fluorine atom, a bromine atom, or an iodine atom.

### Repeating Unit Having Lactone Group, Sultone Group, or Carbonate Group

The resin (A) may have a repeating unit having at least one species selected from the group consisting of a lactone group, a sultone group, and a carbonate group (hereafter, also referred to as “unit Y”).

The unit Y also preferably does not have acid groups such as a hydroxy group and a hexafluoropropanol group.

The lactone group or the sultone group has a lactone structure or a sultone structure. The lactone structure or the sultone structure is preferably a 5- to 7-membered lactone structure or a 5- to 7-membered sultone structure. In particular, more preferred is a 5- to 7-membered lactone structure to which another ring structure is fused so as to form a bicyclo structure or a spiro structure, or a 5- to 7-membered sultone structure to which another ring structure is fused so as to form a bicyclo structure or a spiro structure.

The resin (A) preferably has a repeating unit having a lactone group or a sultone group provided by withdrawing, from ring-member atoms of the lactone structure represented by any one of formulas (LC1-1) to (LC1-21) below or the sultone structure represented by any one of formulas (SL1-1) to (SL1-3) below, one or more hydrogen atoms, and a lactone group or a sultone group may be directly bonded to the main chain. For example, ring-member atoms of a lactone group or a sultone group may constitute the main chain of the resin (A).

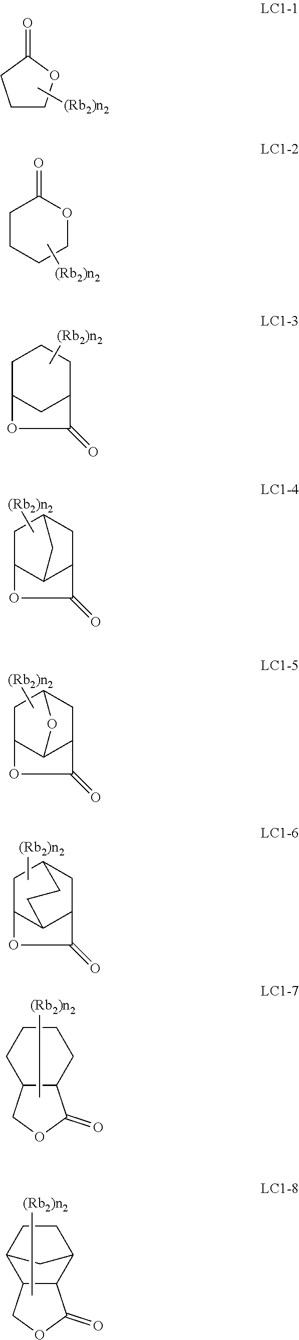

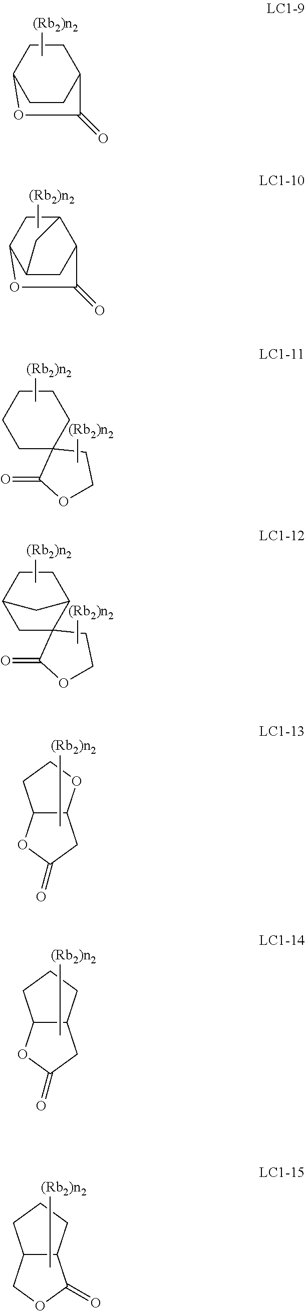

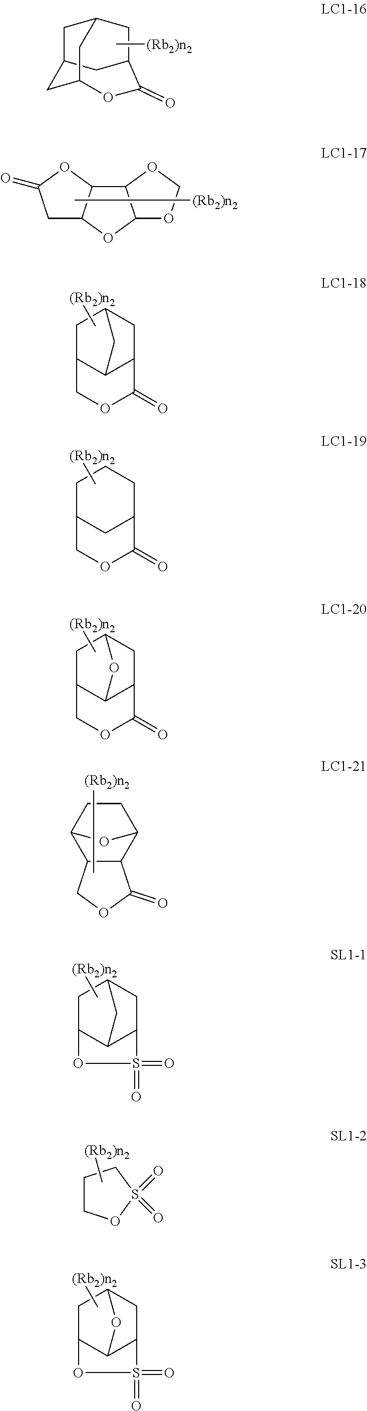

The lactone structure or the sultone structure may have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a cyano group, and an acid-decomposable group. n₂ represents an integer of 0 to 4. When n₂ is 2 or more, the plurality of Rb₂′s present may be different, and the plurality of Rb₂′s present may be bonded together to form a ring.

The repeating unit having a group including the lactone structure represented by any one of the formulas (LC1-1) to (LC1-21) or the sultone structure represented by any one of the formulas (SL1-1) to (SL1-3) may be, for example, a repeating unit represented by the following formula (AI).

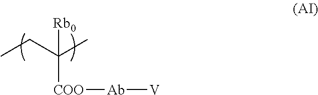

In the formula (AI), Rb₀ represents a hydrogen atom, a halogen atom, or an alkyl group having 1 to 4 carbon atoms. Preferred examples of the substituent that the alkyl group of Rb₀ may have include a hydroxy group and a halogen atom.

Examples of the halogen atom of Rb₀ include a fluorine atom, a chlorine atom, a bromine atom, and an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent linking group that is a combination of the foregoing. In particular, Ab is preferably a single bond or a linking group represented by -Ab₁—CO₂—. Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group formed by withdrawing, from a ring-member atom of the lactone structure represented by any one of the formulas (LC1-1) to (LC1-21), a single hydrogen atom, or a group formed by withdrawing, from a ring-member atom of the sultone structure represented by any one of the formulas (SL1-1) to (SL1-3), a single hydrogen atom.

When the repeating unit having a lactone group or a sultone group has an optical isomer, any optical isomer may be used. A single optical isomer may be used alone, or a plurality of optical isomers may be used in combination. In the case of mainly using one of the optical isomers, its optical purity (ee) is preferably 90 or more, and more preferably 95 or more.

The carbonate group is preferably a cyclic carbonic acid ester group.

The repeating unit having a cyclic carbonic acid ester group is preferably a repeating unit represented by the following formula (A-1).

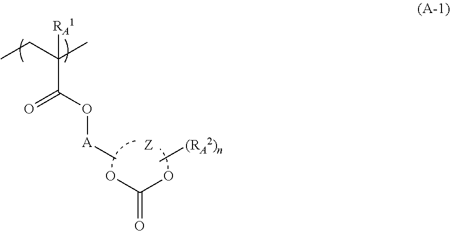

In the formula (A-1), R_{A}¹ represents a hydrogen atom, a halogen atom, or a monovalent organic group (preferably a methyl group). n represents an integer of 0 or more. R_{A}² represents a substituent. When n is 2 or more, the plurality of R_{A}^{2′}s present may be the same or different. A represents a single bond or a divalent linking group. The divalent linking group is preferably an alkylene group, a divalent linking group having a monocyclic or polycyclic alicyclic hydrocarbon structure, an ether group, an ester group, a carbonyl group, a carboxyl group, or a divalent linking group that is a combination of the foregoing. Z represents an atomic group that forms, together with the group represented by —O—CO—O— in the formula, a monocycle or a polycycle.

The unit Y content relative to all the repeating units in the resin (A) is preferably 1 mol % or more, and more preferably 10 mol % or more. The upper limit value relative to all the repeating units in the resin (A) is preferably 85 mol % or less, more preferably 80 mol % or less, still more preferably 70 mol % or less, and particularly preferably 60 mol % or less.

### Repeating Unit Having Photoacid Generation Group

The resin (A) may have, as a repeating unit other than the above-described repeating units, a repeating unit having a group that generates an acid upon irradiation with an actinic ray or a radiation (hereafter, also referred to as “photoacid generation group”). The repeating unit having a photoacid generation group may be a repeating unit represented by a formula (4).

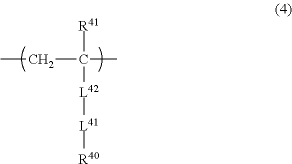

R⁴¹ represents a hydrogen atom or a methyl group. L⁴¹ represents a single bond or a divalent linking group. L⁴² represents a divalent linking group. R⁴⁰ represents a structural moiety that is decomposed upon irradiation with an actinic ray or a radiation to generate an acid in the side chain.

Examples of the repeating unit having a photoacid generation group are as follows.

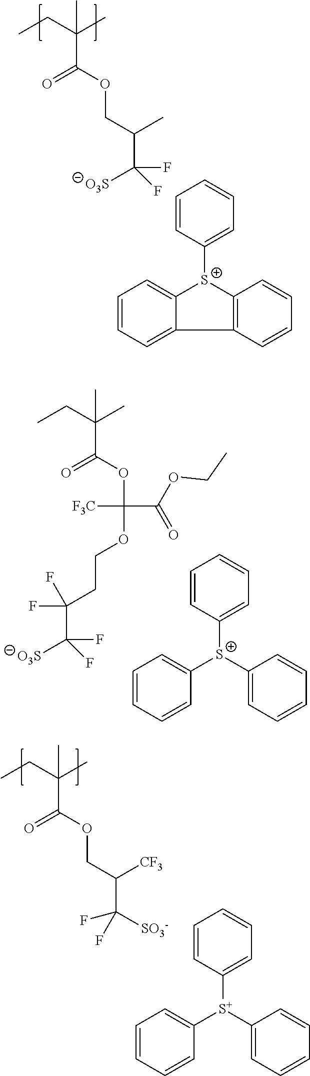

Other examples of the repeating unit represented by the formula (4) include the repeating units described in Paragraphs [0094] to [0105] of JP2014-041327A and the repeating units described in Paragraph [0094] of WO2018/193954A.

When the resin (A) has a repeating unit having a photoacid generation group, the resin (A) can also function as a photoacid generator.

The repeating unit having a photoacid generation group may have or may not have a “—SO₂—N⁻—” moiety. The pKa of the “—SO₂—N⁻—” moiety is measured for the “—SO₂—N⁻—” moiety in the monomer corresponding to the repeating unit having a photoacid generation group.

The pKa of the “—SO₂—N⁻—” moiety is not particularly limited, but may be less than −3.00 or may be −3.00 or more.

The pKa of the “—SO₂—N⁻—” moiety can be measured by a method described later in Ionic compound (Y).

The content of the repeating unit having a photoacid generation group relative to all the repeating units in the resin (A) is preferably 1 mol % or more, and more preferably 5 mol % or more. The upper limit value relative to all the repeating units in the resin (A) is preferably 40 mol % or less, more preferably 35 mol % or less, and still more preferably 30 mol % or less.

### Repeating Unit Represented by Formula (V-1) or Formula (V-2) Below

The resin (A) may have a repeating unit represented by a formula (V-1) below or a formula (V-2) below.

The repeating unit represented by the formula (V-1) below or the formula (V-2) below is preferably a repeating unit different from the above-described repeating units.

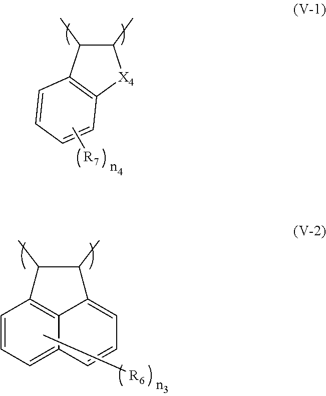

In the formulas,

R₆ and R₇ each independently represent a hydrogen atom, a hydroxyl group, an alkyl group, an alkoxy group, an acyloxy group, a cyano group, a nitro group, an amino group, a halogen atom, an ester group (—OCOR or —COOR: R is an alkyl group or fluorinated alkyl group having 1 to 6 carbon atoms), or a carboxyl group. The alkyl group is preferably a linear, branched, or cyclic alkyl group having 1 to 10 carbon atoms.

n₃ represents an integer of 0 to 6.

n₄ represents an integer of 0 to 4.

X₄ is a methylene group, an oxygen atom, or a sulfur atom.

Examples of the repeating unit represented by the formula (V-1) or (V-2) are as follows.

Examples of the repeating unit represented by the formula (V-1) or (V-2) include the repeating units described in Paragraph [0100] of WO2018/193954A.

Repeating Unit Having at Least One Group Species Selected from the Group Consisting of Lactone Group, Sultone Group, Carbonate Group, Hydroxy Group, Cyano Group, and Alkali-Soluble Group

The resin (A) may have a repeating unit having at least one group species selected from the group consisting of a lactone group, a sultone group, a carbonate group, a hydroxy group, a cyano group, and an alkali-soluble group.

In the resin (A), the repeating unit having a lactone group, a sultone group, or a carbonate group may be the repeating unit having been described above in <Repeating unit having lactone group, sultone group, or carbonate group>. Preferred contents are also the same as those having been described in <Repeating unit having lactone group, sultone group, or carbonate group>.

The resin (A) may have a repeating unit having a hydroxy group or a cyano group. This results in improvement in adhesiveness to the substrate and affinity for the developer.

The repeating unit having a hydroxy group or a cyano group is preferably a repeating unit having an alicyclic hydrocarbon structure substituted with a hydroxy group or a cyano group.

The repeating unit having a hydroxy group or a cyano group preferably does not have an acid-decomposable group. Examples of the repeating unit having a hydroxy group or a cyano group include those described in Paragraphs [0081] to [0084] of JP2014-098921A.

The resin (A) may have a repeating unit having an alkali-soluble group.

The alkali-soluble group may be a carboxyl group, a sulfonamide group, a sulfonylimide group, a bissulfonylimide group, or an aliphatic alcohol group substituted, at the α position, with an electron-withdrawing group (for example, a hexafluoroisopropanol group), and is preferably a carboxyl group. When the resin (A) includes the repeating unit having an alkali-soluble group, increased resolution is provided in the contact hole application. Examples of the repeating unit having an alkali-soluble group include those described in Paragraphs [0085] and [0086] of JP2014-098921A.

### Repeating Unit Having Alicyclic Hydrocarbon Structure and not Exhibiting Acid-Decomposability

The resin (A) may have a repeating unit having an alicyclic hydrocarbon structure and not exhibiting acid-decomposability. This can result in, during liquid immersion exposure, a reduction in leaching of, from the resist film to the immersion liquid, low-molecular-weight components. Examples of the repeating unit having an alicyclic hydrocarbon structure and not exhibiting acid-decomposability include a repeating unit derived from 1-adamantyl (meth)acrylate, diamantyl (meth)acrylate, tricyclodecanyl (meth)acrylate, or cyclohexyl (meth)acrylate.

### Repeating Unit not Having Hydroxy Group or Cyano Group and Represented by Formula (III)

The resin (A) may have a repeating unit not having a hydroxy group or a cyano group and represented by a formula (III).

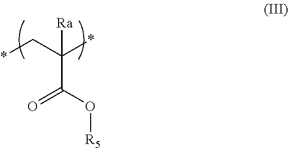

In the formula (III), R₅ represents a hydrocarbon group having at least one ring structure and not having a hydroxy group or a cyano group.

Ra represents a hydrogen atom, an alkyl group, or a —CH₂—O—Ra₂ group. In the formula, Ra₂ represents a hydrogen atom, an alkyl group, or an acyl group.

Examples of the repeating unit not having a hydroxy group or a cyano group and represented by the formula (III) include those described in Paragraphs [0087] to [0094] of JP2014-098921A.

### Other Repeating Unit

Furthermore, the resin (A) may have another repeating unit other than the above-described repeating units.

For example, the resin (A) may have a repeating unit selected from the group consisting of a repeating unit having an oxathiane ring group, a repeating unit having an oxazolone ring group, a repeating unit having a dioxane ring group, and a repeating unit having a hydantoin ring group.

The resin (A) may have, in addition to such repeating structure units, for the purpose of adjusting, for example, dry etching resistance, standard developer suitability, substrate adhesiveness, resist profile, resolution, heat resistance, and sensitivity, various repeating structure units.

For the resin (A), particularly when a composition of the present invention is used as an actinic ray-sensitive or radiation-sensitive resin composition for ArF, all the repeating units are preferably constituted by a repeating unit derived from a compound having an ethylenically unsaturated bond. In particular, all the repeating units are also preferably constituted by a (meth)acrylate-based repeating unit. When all the repeating units are constituted by a (meth)acrylate-based repeating unit, all the repeating units can be a methacrylate-based repeating unit, all the repeating units can be an acrylate-based repeating unit, or all the repeating units can be a methacrylate-based repeating unit and an acrylate-based repeating unit; the acrylate-based repeating unit content relative to all the repeating units is preferably 50 mol % or less.

The resin (A) can be synthesized by standard procedures (for example, radical polymerization).

The resin (A) has a weight-average molecular weight of, as a polystyrene-equivalent value determined by GPC method, preferably 30,000 or less, more preferably 1,000 to 30,000, still more preferably 3,000 to 30,000, and particularly preferably 5,000 to 15,000.

The resin (A) has a dispersity (molecular weight distribution) of preferably 1 to 5, more preferably 1 to 3, still more preferably 1.2 to 3.0, and particularly preferably 1.2 to 2.0. As the dispersity lowers, the resolution becomes higher, the resist profile becomes better, the sidewalls of the resist pattern become smoother, and the roughness performance becomes higher.

In a composition of the present invention, the content of the resin (A) is, relative to the total solid content of the composition, preferably 20.0 to 99.9 mass %, and more preferably 30.0 to 90.0 mass %.

Such resins (A) may be used alone or in combination of two or more thereof. Ionic compound (Y) having anionic moiety represented by formula (3) in which structure represented by “—SO₂—N⁻—” in anionic moiety has pKa of −3.00 or more

A composition of the present invention contains an ionic compound (Y) (hereafter, also referred to as “ionic compound (Y)” or “compound (Y)”) that has an anionic moiety represented by a formula (3) below in which a structure represented by “—SO₂—N⁻—” in the anionic moiety (“—SO₂—N⁻—” moiety) has a pKa of −3.00 or more. The ionic compound (Y) is a compound having an anionic moiety represented by the formula (3) and a cationic moiety.

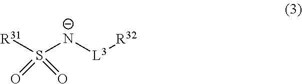

In the formula (3), R³¹ and R³² represent an organic group.

L³ represents a single bond or a divalent linking group.

For R³¹ and R³², the organic group is not particularly limited, but is preferably a hydrocarbon group that may have a substituent, and more preferably an alkyl group, cycloalkyl group, or aryl group that may have a substituent.

When such a group has a substituent, examples of the substituent include the substituents T, and the substituent may have an anionic moiety.

For example, the organic groups represented by R³¹ and R³² may be a group corresponding to “M₁₁⁺A₁₁⁻-L₁-” in a compound represented by a formula (Ia-I) described later.

For example, the organic groups represented by the R³¹ and R³² may be respectively groups corresponding to Rf and R⁵² in a formula (d1-3) described later.

For example, the organic groups represented by R³¹ and R³² may be respectively groups corresponding to R⁵³ and R¹⁴ in a formula (d1-4) described later.

When L³ represents a divalent linking group, examples of the linking group include a carbonyl group, a sulfonyl group, an alkylene group, a cycloalkylene group, and an arylene group.

L³ is preferably a carbonyl group or a sulfonyl group, and more preferably a carbonyl group.

The anionic moiety represented by the formula (3) is preferably an anionic moiety represented by the following formula (3-1).

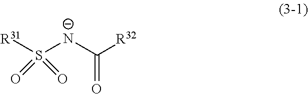

In the formula (3-1), R³¹ and R³² represent an organic group.

R³¹ and R³² in the formula (3-1) have the same definitions as R³¹ and R³² in the formula (3), and preferred examples thereof are also the same.

The anionic moiety represented by the formula (3-1) is preferably an anionic moiety represented by the following formula (3-2).

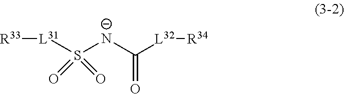

In the formula (3-2),

L³¹ represents an alkylene group.

R³³ represents a halogen atom, a group having an alicyclic structure, or a group including a monovalent anionic functional group.

L³² represents an alkylene group, a cycloalkylene group, or an arylene group.

R³⁴ represents a hydrogen atom, a halogen atom, a group having an alicyclic structure, a group having an aromatic ring structure, or a group including a monovalent anionic functional group.

In the formula (3-2), L³¹ represents an alkylene group.

L³¹ is preferably a linear or branched alkylene group having 1 to 12 carbon atoms that may have a halogen atom, and more preferably a linear or branched alkylene group having 1 to 3 carbon atoms that may have a fluorine atom.

In the formula (3-2), R³³ represents a halogen atom, a group having an alicyclic structure, or a group including a monovalent anionic functional group.

For R³³, the halogen atom is preferably a fluorine atom.

For R³³, the group having an alicyclic structure is preferably a group represented by -L^{33a}-R^{33a} (where L^{33a} represents a single bond, an alkylene group, —O—, —C(═O)—, or a group that is a combination of the foregoing; R^{33a} represents an alicyclic group).

For R³³, the group including a monovalent anionic functional group is preferably, for example, a group including a monovalent anionic functional group represented by any one of formulas (AX-1) to (AX-3) described later, and is more preferably -L^{33b}-R^{33b} (where L^{33b} represents a single bond, an alkylene group that may have a halogen atom, a cycloalkylene group that may have a halogen atom, —O—, —C(═O)—, —S(═O)₂—, or a divalent linking group that is a combination of the foregoing; R^{33b} represents a monovalent anionic functional group represented by any one of formulas (AX-1) to (AX-3) described later).

In the formula (3-2), L³² represents an alkylene group, a cycloalkylene group, or an arylene group.

For L³², the alkylene group is preferably an alkylene group having 1 to 12 carbon atoms.

For L³², the cycloalkylene group is preferably a monocyclic or polycyclic cycloalkylene group having 6 to 15 carbon atoms.

For L³², the arylene group is preferably an arylene group having 6 to 10 carbon atoms, and is preferably a phenylene group.

When L³² has a substituent, the substituent may be a halogen atom (for example, a fluorine atom or an iodine atom), an alkyl group, a cycloalkyl group, —O—, —C(═O)—, or a group that is a combination of the foregoing.

In the formula (3-2), R³⁴ represents a hydrogen atom, a halogen atom, a group having an aromatic ring structure, a group having an alicyclic structure, or a group including a monovalent anionic functional group.

For R³⁴, the halogen atom may be a fluorine atom or an iodine atom.

For R³⁴, the group having an alicyclic structure is preferably a group represented by -L^{34a}-R^{34a} (where L^{34a} represents a single bond, an alkylene group, —O—, —C(═O)—, or a group that is a combination of the foregoing; R^{34a} represents an alicyclic group).

The alicyclic group may be monocyclic or may be polycyclic. Examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. The alicyclic group may further have a substituent, and a part of methylene groups in the alicyclic structure may be substituted with a carbonyl group.

For R³⁴, the group having an aromatic ring structure is, for example, preferably a group represented by -L^{35a}-R^{35a} (where L^{35a} represents a single bond, an alkylene group, —O—, —C(═O)—, or a group that is a combination of the foregoing; R^{35a} represents an aromatic ring group).

The aromatic ring group may be monocyclic or may be polycyclic. The aromatic ring group is not particularly limited, but may be, for example, an aromatic ring group having 6 to 20 carbon atom, and may be a phenyl group, a naphthyl group, an anthryl group, or the like. The aromatic ring group may further have a substituent.

For R³⁴, the group including a monovalent anionic functional group is, for example, preferably a group including a monovalent anionic functional group represented by any one of formulas (AX-1) to (AX-3) described later, and more preferably a group represented by -L^{34b}-R^{34b} (where L^{34b} represents a single bond, an alkylene group that may have a halogen atom, a cycloalkylene group that may have a halogen atom, —O—, —C(═O)—, —S(═O)₂—, or a divalent linking group that is a combination of the foregoing; R^{34b} represents a monovalent anionic functional group represented by any one of formulas (AX-1) to (AX-3) described later).

The cationic moiety in the ionic compound (Y) is preferably an organic cation. For the valence, the organic cation may be mono-, di-, or higher valent. The organic cation is not particularly limited, and may be M⁺ described later.

The ionic compound (Y) is typically an onium salt, and examples thereof include a sulfonium salt and an iodonium salt.

In the ionic compound (Y), the acid dissociation constant (pKa) is a value determined by calculation using the above-described software package 1.

The anionic moiety represented by the formula (3) has a “—SO₂—N⁻—” moiety. In other words, the ionic compound (Y) is constituted by the anionic moiety “—SO₂—N⁻—” and the cationic moiety M_{Y1}⁺, and has a structural moiety Y1 that forms a first acidic moiety represented by “—SO₂—NH—” upon irradiation with an actinic ray or a radiation. The “—SO₂—N—” moiety has a pKa of −3.00 or more. In this Specification, the “—SO₂—N⁻—” moiety has a pKa of −3.00 or more, which means that the acid dissociation constant derived from the first acidic moiety represented by the “—SO₂—NH—” is −3.00 or more.

The ionic compound (Y) has at least one structural moiety Y1, and may have two or more structural moieties Y1.

The anionic moiety represented by the formula (3) may have one or more anionic moieties other than the anionic moiety represented by “—SO₂—N⁻—” and having a pKa of −3.00 or more.

In other words, the ionic compound (Y) may have, in addition to the structural moiety Y1, structural moieties Y2, Y3, . . . , Yn that are constituted by an anionic moiety and a cationic moiety and form second, third, . . . , n-th acidic moieties upon irradiation with an actinic ray or a radiation.

In this Specification, the pKa of the ionic compound (Y) is specifically determined in the following manner.

In a compound PY in which all the cationic moieties in the structural moieties Y1, Y2, . . . , Yn in the ionic compound (Y) are replaced by H⁺, acid dissociation constants are sequentially determined from pKa1, which is the acid dissociation constant during withdrawal of H⁺ from the acidic moiety having the highest acid strength, subsequently pKa2, which is the acid dissociation constant during withdrawal of H⁺ from the acidic moiety having the second highest acid strength, . . . . The pKa of the “—SO₂—N⁻—” moiety can be determined as an acid dissociation constant during withdrawal of H⁺ from the first acidic moiety represented by “—SO₂—NH—” in the compound in the above-described step.

The “—SO₂—N⁻—” moiety has a pKa of −3.00 or more, preferably −2.00 or more, and more preferably −1.00 or more. The upper limit of the pKa is preferably 8.00 or less, and more preferably 5.00 or less.

In the formation of a pattern using an actinic ray-sensitive or radiation-sensitive film, there has been a demand for reduction in the pattern sizes; however, the inventors of the present invention have found that, particularly in the formation of the most advanced ultrafine patterns (for example, a line-and-space pattern having a line width or space width of 35 nm or less, and a hole pattern having a hole diameter of 30 nm or less), problems of pattern defects, which have been less likely to be regarded as problems in the formation of related-art pattern sizes, are likely to become noticeable.

Thus, the inventors of the present invention first presumed that the defect suppression performance is considerably related to aggregation of ionic compounds that have been suitably included in actinic ray-sensitive or radiation-sensitive compositions (the aggregation used herein refers to, not aggregation having a large size, but aggregation having a small size of about several molecules).

More specifically, such an ionic compound has high hydrophilicity and hence interaction and the resultant aggregation within the ionic compound tend to occur during formation of an actinic ray-sensitive or radiation-sensitive film from an actinic ray-sensitive or radiation-sensitive resin composition. In the formation of a pattern having a related-art size, even formation of a small aggregate of about several molecules within the ionic compound does not considerably affect the performance of the pattern (the problems of defect performance are unlikely to occur); however, in the formation of the above-described ultrafine pattern, even when an aggregate within the ionic compound is small, fluctuation, derived from the aggregate, in the concentration of the acid generated in the exposed region can significantly affect the defect performance presumably.

Thus, the inventors of the present invention focused on the type of the ionic compound and the type of the resin contained in the composition in order to further suppress the aggregation within the ionic compound.

When the “—SO₂—N⁻—” moiety has a pKa of less than −3.00, the interaction between anionic moieties of the ionic compound becomes excessively strong and, even with the resin (A) containing the repeating unit (i) represented by the formula (1), the defect suppression performance tends to degrade due to aggregation within the ionic compound; for this reason, in the present invention, in order to exhibit the defect suppression performance, the pKa of the “—SO₂—N⁻—” moiety is set to −3.00 or more.

In a preferred embodiment, the ionic compound (Y) is, in Photoacid generator described later, a compound that has an anionic moiety represented by the formula (3) in which the “—SO₂—N⁻—” moiety in the anionic moiety has a pKa of −3.00 or more.

In another preferred embodiment, the ionic compound (Y) is, in Acid diffusion control agent described later, a compound that has an anionic moiety represented by the formula (3) in which the “—SO₂—N⁻—” moiety in the anionic moiety has a pKa of −3.00 or more.

When the ionic compound (Y) is used as an acid diffusion control agent, it is preferably used in combination with a photoacid generator that generates an acid necessary for the reaction of the resin in the exposed region such that the acid generated from the photoacid generator becomes a strong acid relative to the acid generated from the ionic compound (Y).

The ionic compound (Y) can be synthesized with reference to a publicly known method. Specific synthesis examples will be described later in EXAMPLES.

The content of the ionic compound (Y) is, relative to the total solid content of the composition, preferably 1.0 mass % or more, more preferably 10.0 mass % or more, and still more preferably 15.0 mass % or more.

The upper limit value of the content of the ionic compound (Y) is not particularly limited, but is, relative to the total solid content of the composition, ordinarily 80.0 mass % or less, preferably 70.0 mass % or less, and more preferably 60.0 mass % or less.

Such ionic compounds (Y) may be used alone or in combination of two or more thereof.

### Photoacid Generator

A composition of the present invention preferably includes a compound that generates an acid upon irradiation with an actinic ray or a radiation (hereafter, also referred to as a photoacid generator).

The photoacid generator may be the above-described ionic compound (Y) or may not be the ionic compound (Y).

The acid generated from the photoacid generator ordinarily reacts with the acid-decomposable group in the resin (A).

The photoacid generator may have the form of a low-molecular-weight compound, or may have the form of being incorporated into a portion of a polymer (for example, the above-described resin (A)). Alternatively, the form of a low-molecular-weight compound and the form of being incorporated into a portion of a polymer (for example, the above-described resin (A)) may be used in combination.

When the photoacid generator has the form of a low-molecular-weight compound, the photoacid generator preferably has a molecular weight of 3000 or less, more preferably 2000 or less, and still more preferably 1,000 or less. The lower limit is not particularly limited, but is preferably 100 or more.

When the photoacid generator has the form of being incorporated into a portion of a polymer, it may be incorporated into a portion of the resin (A) or may be incorporated into a resin different from the resin (A).

In this Specification, the photoacid generator preferably has the form of a low-molecular-weight compound.

The photoacid generator may be, for example, a compound (onium salt) represented by “M⁺X⁻”, and is preferably a compound that generates an organic acid upon exposure.

Examples of the organic acid include sulfonic acids (such as aliphatic sulfonic acids, aromatic sulfonic acids, and camphorsulfonic acid), carboxylic acids (such as aliphatic carboxylic acids, aromatic carboxylic acids, and aralkyl carboxylic acids), carbonylsulfonylimidic acid, bis(alkylsulfonyl)imidic acids, and tris(alkylsulfonyl)methide acids.

In the compound represented by “M⁺X⁻”, M⁺ represents an organic cation.

The organic cation is not particularly limited. For the valence, the organic cation may be mono-, di-, or higher valent.

The organic cation is preferably a sulfonium cation or an iodonium cation.

In particular, the organic cation is preferably a cation represented by a formula (ZaI) (hereafter, also referred to as “cation (ZaI)”) or a cation represented by a formula (ZaII) (hereafter, also referred to as “cation (ZaII)”).

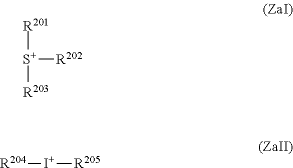

In the above-described formula (ZaI), R²⁰¹, R²⁰², and R²⁰³ each independently represent an organic group.

For R²⁰¹, R²⁰², and R²⁰³, the organic group preferably has 1 to 30 carbon atoms, and more preferably 1 to 20 carbon atoms. Among R²⁰¹ to R²⁰³, two may be bonded together to form a ring structure and the ring may include an oxygen atom, a sulfur atom, an ester group, an amide group, or a carbonyl group. Examples of the group formed by bonding together two among R²⁰¹ to R²⁰³ include alkylene groups (such as a butylene group and a pentylene group), and —CH₂—CH₂—O—CH₂—CH₂—.

Preferred examples of the organic cation in the formula (ZaI) include a cation (ZaI-1), a cation (ZaI-2), a cation (ZaI-3b), and a cation (ZaI-4b) described later.

First, the cation (ZaI-1) will be described.

The cation (ZaI-1) is an aryl sulfonium cation represented by the above-described formula (ZaI) where at least one of R²⁰¹ to R²⁰³ is an aryl group.

In the aryl sulfonium cation, all of R²⁰¹ to R²⁰³ may be aryl groups, or a part of R²⁰¹ to R²⁰³ may be an aryl group and the other may be an alkyl group or a cycloalkyl group.

Alternatively, one among R²⁰¹ to R²⁰³ may be an aryl group and the other two among R²⁰¹ to R²⁰³ may be bonded together to form a ring structure in which the ring may include an oxygen atom, a sulfur atom, an ester group, an amide group, or a carbonyl group. Examples of the group formed by bonding together two among R²⁰¹ to R²⁰³ include alkylene groups in which one or more methylene groups may be substituted with an oxygen atom, a sulfur atom, an ester group, an amide group, and/or a carbonyl group (such as a butylene group, a pentylene group, and —CH₂—CH₂—O—CH₂—CH₂—).

Examples of the aryl sulfonium cation include triaryl sulfonium cations, diaryl alkyl sulfonium cations, aryl dialkyl sulfonium cations, diaryl cycloalkyl sulfonium cations, and aryl dicycloalkyl sulfonium cations.

For R²⁰¹ to R²⁰³, a substituent that the aryl group, the alkyl group, and the cycloalkyl group may have is preferably an alkyl group (having, for example, 1 to 15 carbon atoms), a cycloalkyl group (having, for example, 3 to 15 carbon atoms), an aryl group (having, for example, 6 to 14 carbon atoms), an alkoxy group (having, for example, 1 to 15 carbon atoms), a cycloalkylalkoxy group (having, for example, 1 to 15 carbon atoms), a halogen atom (for example, fluorine or iodine), a hydroxyl group, a carboxyl group, an ester group, a sulfinyl group, a sulfonyl group, an alkylthio group, or a phenylthio group.

The substituent may further have, when possible, a substituent; the alkyl group also preferably has, as a substituent, a halogen atom to serve as an alkyl halide group such as a trifluoromethyl group.

Such substituents are also preferably combined appropriately to form an acid-decomposable group.

Note that the acid-decomposable group means a group that is decomposed by the action of an acid to generate a polar group, and preferably has a structure in which a group that leaves by the action of an acid protects the polar group. The polar group and the leaving group are as described above.

Hereinafter, the cation (ZaI-2) will be described.

The cation (ZaI-2) is a cation represented by the formula (ZaI) where R²⁰¹ to R²⁰³ each independently represent an organic group not having an aromatic ring. The aromatic ring also encompasses aromatic rings including a heteroatom.

For R²⁰¹ to R²⁰³, the organic group not having an aromatic ring preferably has 1 to 30 carbon atoms and more preferably 1 to 20 carbon atoms.

R²⁰¹ to R²⁰³ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably a linear or branched 2-oxoalkyl group.

Hereinafter, the cation (ZaI-3b) will be described.

The cation (ZaI-3b) is a cation represented by the following formula (ZaI-3b).

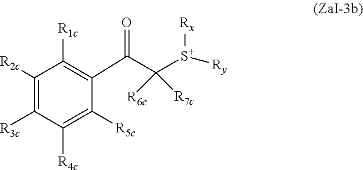

In the formula (ZaI-3b), R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxy group, a nitro group, an alkylthio group, or an arylthio group.

R_{6c} and R_{7c} each independently represent a hydrogen atom, an alkyl group (for example, a t-butyl group), a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

For R_{1c} to R₇, and Rₓ and R_{y}, such substituents are also preferably provided independently as appropriate combinations of substituents to form acid-decomposable groups.

Any two or more among R_{1c} to R_{5c}, R_{5c} and R_{6c}, R_{6c} and R_{7c}, R_{5c} and Rₓ, and Rₓ and R_{y} may be individually bonded together to form rings; these rings may each independently include an oxygen atom, a sulfur atom, a ketone group, an ester bond, or an amide bond.

Such a ring may be an aromatic or non-aromatic hydrocarbon ring, an aromatic or non-aromatic heterocycle, or a polycyclic fused ring formed as a combination of two or more of these rings. The ring may be a 3- to 10-membered ring, and is preferably a 4- to 8-membered ring, and more preferably a 5- or 6-membered ring.

R_{1c} to R_{5c}, R_{6c}, R_{7c}, Rₓ, R_{y}, and the rings formed by individually bonding together any two or more among R_{1c} to R_{5c}, R_{5c} and R_{6c}, R_{6c} and R_{7c}, R_{5c} and Rₓ, and Rₓ and R_{y} may have a substituent.

Hereinafter, the cation (ZaI-4b) will be described.

The cation (ZaI-4b) is a cation represented by the following formula (ZaI-4b).

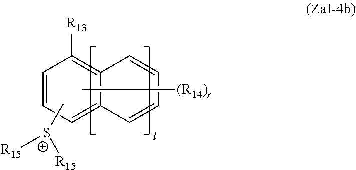

In the formula (ZaI-4b), 1 represents an integer of 0 to 2, and r represents an integer of 0 to 8.

R₁₃ represents a hydrogen atom, a halogen atom (for example, a fluorine atom or an iodine atom), a hydroxyl group, an alkyl group, a halogenated alkyl group, an alkoxy group, a carboxyl group, an alkoxycarbonyl group, or a group including a cycloalkyl group (that may be the cycloalkyl group itself or may be a group including the cycloalkyl group in a part thereof).

These groups may have a substituent.

R₁₄ represents a hydroxyl group, a halogen atom (for example, a fluorine atom or an iodine atom), an alkyl group, a halogenated alkyl group, an alkoxy group, an alkoxycarbonyl group, an alkylcarbonyl group, an alkylsulfonyl group, a cycloalkylsulfonyl group, or a group including a cycloalkyl group (that may be the cycloalkyl group itself or may be a group including a cycloalkyl group in a part thereof).

These groups may have a substituent. When a plurality of R₁₄′s are present, R₁₄′s each independently represent such a group, for example, a hydroxyl group.

R₁₅′s each independently represent an alkyl group, a cycloalkyl group, or a naphthyl group. Two R₁₅′s may be bonded together to form a ring. When two R₁₅′s are bonded together to form a ring, the ring skeleton may include a heteroatom such as an oxygen atom or a nitrogen atom.

In an example, two R₁₅′s are preferably alkylene groups and bonded together to form a ring structure. Note that the alkyl group, the cycloalkyl group, the naphthyl group, and the ring formed by bonding together two R₁₅′s may have a substituent.

Hereinafter, the formula (ZaII) will be described.

In the formula (ZaII), R²⁰⁴ and R²⁰⁵ each independently represent an aryl group, an alkyl group, or a cycloalkyl group.

For R²⁰⁴ and R²⁰⁵, the aryl group, the alkyl group, and the cycloalkyl group may each independently have a substituent. For R²⁰⁴ and R²⁰⁵, examples of the substituent that the aryl group, the alkyl group, and the cycloalkyl group may have include alkyl groups (having, for example, 1 to 15 carbon atoms), cycloalkyl groups (having, for example, 3 to 15 carbon atoms), aryl groups (having, for example, 6 to 15 carbon atoms), alkoxy groups (having, for example, 1 to 15 carbon atoms), halogen atoms, a hydroxy group, and a phenylthio group. For R²⁰⁴ and R²⁰⁵, substituents are also preferably provided independently as appropriate combinations of substituents to form acid-decomposable groups.

In the compound represented by “M⁺X⁻”, X⁻ represents an organic anion.

The organic anion is not particularly limited, but may be a mono-, di-, or higher valent organic anion.

The organic anion is preferably an anion that has a very low capability of causing a nucleophilic reaction, and more preferably a non-nucleophilic anion.

The organic anion may or may not be an anion that is represented by the above-described formula (3) in which the “—SO₂—N⁻—” moiety has a pKa of −3.00 or more.

Examples of the non-nucleophilic anion include sulfonate anions (such as aliphatic sulfonate anions, aromatic sulfonate anions, and a camphorsulfonate anion), carboxylate anions (such as aliphatic carboxylate anions, aromatic carboxylate anions, and aralkyl carboxylate anions), a sulfonylimide anion, bis(alkylsulfonyl)imide anions, and tris(alkylsulfonyl)methide anions.

In such an aliphatic sulfonate anion or aliphatic carboxylate anion, the aliphatic moiety may be a linear or branched alkyl group or may be a cycloalkyl group, and is preferably a linear or branched alkyl group having 1 to 30 carbon atoms, or a cycloalkyl group having 3 to 30 carbon atoms.

The alkyl group may be, for example, a fluoroalkyl group (that may have a substituent other than a fluorine atom, or may be a perfluoroalkyl group).

In such an aromatic sulfonate anion or aromatic carboxylate anion, the aryl group is preferably an aryl group having 6 to 14 carbon atoms, and may be, for example, a phenyl group, a tolyl group, or a naphthyl group.

The above-described alkyl group, cycloalkyl group, and aryl group may have a substituent. The substituent is not particularly limited; examples include a nitro group, halogen atoms such as a fluorine atom and a chlorine atom, a carboxyl group, a hydroxyl group, an amino group, a cyano group, alkoxy groups (preferably having 1 to 15 carbon atoms), alkyl groups (preferably having 1 to 10 carbon atoms), cycloalkyl groups (preferably having 3 to 15 carbon atoms), aryl groups (preferably having 6 to 14 carbon atoms), alkoxycarbonyl groups (preferably having 2 to 7 carbon atoms), acyl groups (preferably having 2 to 12 carbon atoms), alkoxycarbonyloxy groups (preferably having 2 to 7 carbon atoms), alkylthio groups (preferably having 1 to 15 carbon atoms), alkylsulfonyl groups (preferably having 1 to 15 carbon atoms), alkyliminosulfonyl groups (preferably having 1 to 15 carbon atoms), and aryloxysulfonyl groups (preferably having 6 to 20 carbon atoms).

In such an aralkyl carboxylate anion, the aralkyl group is preferably an aralkyl group having 7 to 14 carbon atoms.

Examples of the aralkyl group having 7 to 14 carbon atoms include a benzyl group, a phenethyl group, a naphthylmethyl group, a naphthylethyl group, and a naphthylbutyl group.

The sulfonylimide anion may be, for example, a saccharin anion.

In such a bis(alkylsulfonyl)imide anion or a tris(alkylsulfonyl)methide anion, the alkyl groups are preferably an alkyl group having 1 to 5 carbon atoms. In the alkyl group, a substituent may be a halogen atom, an alkyl group substituted with a halogen atom, an alkoxy group, an alkylthio group, an alkyloxysulfonyl group, an aryloxysulfonyl group, or a cycloalkylaryloxysulfonyl group, and is preferably a fluorine atom or an alkyl group substituted with a fluorine atom.

In the bis(alkylsulfonyl)imide anion, the alkyl groups may be bonded together to form a ring structure. This results in an increase in the acid strength.

Other examples of the non-nucleophilic anion include phosphorus fluoride (for example, PF₆⁻), boron fluoride (for example, BF₄⁻), and antimony fluoride (for example, SbF₆⁻).

The non-nucleophilic anion is preferably an aliphatic sulfonate anion in which at least the α position of sulfonic acid is substituted with a fluorine atom, an aromatic sulfonate anion substituted with a fluorine atom or a group having a fluorine atom, a bis(alkylsulfonyl)imide anion in which the alkyl groups are substituted with fluorine atoms, or a tris(alkylsulfonyl)methide anion in which the alkyl groups are substituted with fluorine atoms. In particular, the anion is more preferably a perfluoroaliphatic sulfonate anion (preferably having 4 to 8 carbon atoms) or a benzenesulfonate anion having a fluorine atom, and still more preferably a nonafluorobutanesulfonate anion, a perfluorooctanesulfonate anion, a pentafluorobenzenesulfonate anion, or a 3,5-bis(trifluoromethyl)benzenesulfonate anion.

The non-nucleophilic anion is also preferably an anion represented by the following formula (AN1).

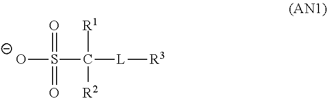

In the formula (AN1), R¹ and R² each independently represent a hydrogen atom or a substituent.

The substituent is not particularly limited, but is preferably a group that is not electron-withdrawing groups. Examples of the group that is not electron-withdrawing groups include hydrocarbon groups, a hydroxy group, oxyhydrocarbon groups, oxycarbonylhydrocarbon groups, an amino group, hydrocarbon-substituted amino groups, and hydrocarbon-substituted amide groups.

Such groups that are not electron-withdrawing groups are each independently preferably —R′, —OH, —OR′, —OCOR′, —NH₂, —NR′₂, —NHR′, or —NHCOR′. R′ are monovalent hydrocarbon groups.

Examples of the monovalent hydrocarbon groups represented by R′ above include monovalent linear or branched hydrocarbon groups such as alkyl groups such as a methyl group, an ethyl group, a propyl group, and a butyl group; alkenyl groups such as an ethenyl group, a propenyl group, and a butenyl group; and alkynyl groups such as an ethynyl group, a propynyl group, and a butynyl group; monovalent alicyclic hydrocarbon groups such as cycloalkyl groups such as a cyclopropyl group, a cyclobutyl group, a cyclopentyl group, a cyclohexyl group, a norbornyl group, and an adamantyl group; and cycloalkenyl groups such as a cyclopropenyl group, a cyclobutenyl group, a cyclopentenyl group, and a norbornenyl group; and monovalent aromatic hydrocarbon groups such as aryl groups such as a phenyl group, a tolyl group, a xylyl group, a mesityl group, a naphthyl group, a methylnaphthyl group, an anthryl group, and methylanthryl group; and aralkyl groups such as a benzyl group, a phenethyl group, a phenylpropyl group, a naphthylmethyl group, and an anthrylmethyl group.

In particular, R¹ and R² are each independently preferably a hydrocarbon group (preferably a cycloalkyl group) or a hydrogen atom.

L represents a divalent linking group.

When a plurality of L's are present, L's may be the same or different.

The divalent linking group may be, for example, —O—CO—O—, —COO—, —CONH—, —CO—, —O—, —S—, —SO—, —SO₂—, an alkylene group (preferably having 1 to 6 carbon atoms), a cycloalkylene group (preferably having 3 to 15 carbon atoms), an alkenylene group (preferably having 2 to 6 carbon atoms), or a divalent linking group that is a combination of a plurality of the foregoing. In particular, the divalent linking group is preferably —O—CO—O—, —COO—, —CONH—, —CO—, —O—, —SO₂—, —O—CO—O-alkylene group-, —COO-alkylene group-, or —CONH-alkylene group-, and more preferably —O—CO—O—, —O—CO—O-alkylene group-, —COO—, —CONH—, —SO₂—, or —COO-alkylene group-.

L is preferably, for example, a group represented by the following formula (AN1-1).

*^{a}—(CR^{2a}₂)_{X}-Q-(CR^{2b}₂)^{Y}—*^{b} (AN1-1)

In the formula (AN1-1), *^{a} represents the bonding site to R³ in the formula (AN1).

*^{b} represents the bonding site to —C(R¹)(R²)— in the formula (AN1).

X and Y each independently represent an integer of 0 to 10, and is preferably an integer of 0 to 3.

R^{2a} and R^{2b} each independently represent a hydrogen atom or a substituent.

When a plurality of R^{2a′}s and a plurality of R^{2b′}s are present, the plurality of R^{2a′}s and the plurality of R^{2b′}s present may be individually the same or different.

Note that, when Y is 1 or more, in the formula (AN1), in CR^{2b}₂ directly bonded to —C(R₁)(R²)—, R^{2b′}s are not fluorine atoms.

Q represents *^{A}—O—CO—O—*^{B}, *^{A}—CO—*^{B}, *^{A}—CO—O—*^{B}, *^{A}—O—CO—*^{B}, *^{A}—O—*^{B}, *^{A}—S—*^{B}, or *^{A}—SO₂—*^{B}.

Note that, when X+Y in the formula (AN1-1) is 1 or more, and R^{2a′}s and R^{2b′}s in the formula (AN1-1) are all hydrogen atoms, Q represents *^{A}—O—CO—O—*^{B}, *^{A}—CO—*^{B}, *^{A}—O—CO—*^{B}, *^{A}—O—*^{B}, *^{A}—S*^{B}, or *^{A}—S₂—*^{B}.

*^{A} represent a bonding site on the R³ side in the formula (AN1) and *^{B} represent a bonding site on the —SO₃⁻ side in the formula (AN1).

In the formula (AN1), R³ represents an organic group.

The organic group is not particularly limited as long as it has 1 or more carbon atoms, and may be a linear group (for example, a linear alkyl group) or a branched group (for example, a branched alkyl group such as a t-butyl group), or may be a cyclic group. The organic group may have or may not have a substituent. The organic group may have or may not have a heteroatom (such as an oxygen atom, a sulfur atom, and/or a nitrogen atom).

In particular, R³ is preferably an organic group having a ring structure. The ring structure may be monocyclic or polycyclic, and may have a substituent. In the organic group including a ring structure, the ring is preferably directly bonded to L in the formula (AN1). The organic group having a ring structure, for example, may have or may not have a heteroatom (such as an oxygen atom, a sulfur atom, and/or a nitrogen atom). The heteroatom may substitute one or more carbon atoms forming the ring structure.

The organic group having a ring structure is preferably, for example, a hydrocarbon group having a ring structure, a lactone ring group, or a sultone ring group. In particular, the organic group having a ring structure is preferably a hydrocarbon group having a ring structure.

The hydrocarbon group having a ring structure is preferably a monocyclic or polycyclic cycloalkyl group. Such groups may have a substituent.

The cycloalkyl group may be monocyclic (such as a cyclohexyl group) or polycyclic (such as an adamantyl group), and preferably has 5 to 12 carbon atoms.

The lactone group and the sultone group are, for example, preferably a group provided by removing, in any one of the above-described structures represented by the formulas (LC1-1) to (LC1-21) and the above-described structures represented by the formulas (SL1-1) to (SL1-3), a single hydrogen atom from a ring-member atom constituting the lactone structure or the sultone structure.

The non-nucleophilic anion may be a benzenesulfonate anion, and is preferably a benzenesulfonate anion substituted with a branched alkyl group or a cycloalkyl group.

The non-nucleophilic anion is also preferably an anion represented by the following formula (AN2).

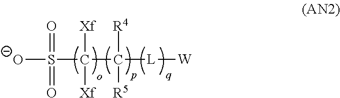

In the formula (AN2), o represents an integer of 1 to 3. p represents an integer of 0 to 10. q represents an integer of 0 to 10.

Xf's represent a hydrogen atom, a fluorine atom, an alkyl group substituted with at least one fluorine atom, or an organic group not having fluorine atoms. The alkyl group preferably has 1 to 10 carbon atoms, and more preferably 1 to 4 carbon atoms. The alkyl group substituted with at least one fluorine atom is preferably a perfluoroalkyl group.

Xf's are preferably a fluorine atom or a perfluoroalkyl group having 1 to 4 carbon atoms, and more preferably a fluorine atom or CF₃; still more preferably, both of Xf's are fluorine atoms.

R⁴ and R⁵ each independently represent a hydrogen atom, a fluorine atom, an alkyl group, or an alkyl group substituted with at least one fluorine atom. When a plurality of R^{4′}s and a plurality of R^{5′}s are present, R^{4′}s and R^{5′}s may be individually the same or different.

For R⁴ and R⁵, the alkyl group preferably has 1 to 4 carbon atoms. The alkyl group may have a substituent. R⁴ and R⁵ are preferably a hydrogen atom.

L represents a divalent linking group. L has the same definition as L in the formula (AN1).

W represents an organic group, and preferably represents an organic group including a ring structure. In particular, preferred is a cyclic organic group.

The cyclic organic group may be, for example, an alicyclic group, an aryl group, or a heterocyclic group.

The alicyclic group may be monocyclic or may be polycyclic. Examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. In particular, preferred are alicyclic groups having a bulky structure having 7 or more carbon atoms such as a norbornyl group, a tricyclodecanyl group, a tetracyclodecanyl group, a tetracyclododecanyl group, and an adamantyl group.

The aryl group may be monocyclic or polycyclic. Examples of the aryl group include a phenyl group, a naphthyl group, a phenanthryl group, and an anthryl group. The heterocyclic group may be monocyclic or polycyclic. In particular, in the case of a polycyclic heterocyclic group, diffusion of acid can be further suppressed. The heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle not having aromaticity include a tetrahydropyran ring, a lactone ring, a sultone ring, and a decahydroisoquinoline ring. In the heterocyclic group, the heterocycle is preferably a furan ring, a thiophene ring, a pyridine ring, or a decahydroisoquinoline ring.

The cyclic organic group may have a substituent. The substituent may be, for example, an alkyl group (that may be linear or branched and preferably has 1 to 12 carbon atoms), a cycloalkyl group (that may have a monocycle, a polycycle, or a spiro ring, and preferably has 3 to 20 carbon atoms), an aryl group (preferably having 6 to 14 carbon atoms), a hydroxy group, an alkoxy group, an ester group, an amide group, a urethane group, a ureido group, a thioether group, a sulfonamide group, or a sulfonic acid ester group. Note that a carbon constituting the cyclic organic group (carbon contributing to formation of the ring) may be a carbonyl carbon.

The anion represented by the formula (AN2) is preferably SO₃⁻—CF₂—CH₂—OCO-(L)_{q′}-W, SO₃⁻—CF₂—CHF—CH₂—OCO-(L)_{q′}-W, SO₃⁻—CF₂—COO-(L)_{q′}-W, SO₃⁻—CF₂—CF₂—CH₂—CH₂-(L)_{q}-W, or SO₃⁻—CF₂—CH(CF₃)—OCO-(L)_{q′}-W. Here, L, q, and W are the same as those in the formula (AN2). q′ represents an integer of 0 to 10.

The non-nucleophilic anion is also preferably an aromatic sulfonate anion represented by the following formula (AN3).

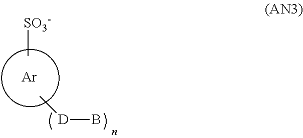

In the formula (AN3), Ar represents an aryl group (such as a phenyl group), and may further have a substituent other than the sulfonate anion and the -(D-B) group. Examples of the substituent that Ar may further have include a fluorine atom and a hydroxy group.

n represents an integer of 0 or more. n is preferably 1 to 4, more preferably 2 to 3, and still more preferably 3.

D represents a single bond or a divalent linking group. The divalent linking group may be an ether group, a thioether group, a carbonyl group, a sulfoxide group, a sulfo group, a sulfonic acid ester group, an ester group, or a group that is a combination of two or more of the foregoing.

B represents a hydrocarbon group.

B is preferably an aliphatic hydrocarbon group, and more preferably an isopropyl group, a cyclohexyl group, or an aryl group that may further have a substituent (such as a tricyclohexylphenyl group).

The non-nucleophilic anion is also preferably a disulfonamide anion.

The disulfonamide anion is, for example, an anion represented by N—(SO₂—R^{q})₂.

R^{q′}s represent an alkyl group that may have a substituent, and are preferably a fluoroalkyl group, and more preferably a perfluoroalkyl group. Two R^{q′}s may be bonded together to form a ring. The group formed by bonding together two R^{q′}s is preferably an alkylene group that may have a substituent, preferably a fluoroalkylene group, and more preferably a perfluoroalkylene group. The alkylene group preferably has 2 to 4 carbon atoms.

Other examples of the non-nucleophilic anion include anions represented by the following formulas (d1-1) to (d1-4). Note that the anion represented by the following formula (d1-3) or formula (d1-4) may or may not be an anion corresponding to the anionic moiety that is represented by the above-described formula (3) in which the “—SO₂—N⁻—” moiety has a pKa of −3.00 or more.

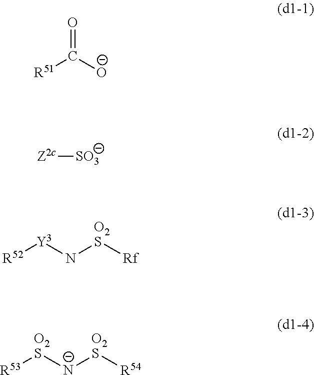

In the formula (d1-1), R⁵¹ represents a hydrocarbon group that may have a substituent (such as a hydroxy group) (for example, an aryl group such as a phenyl group).

In the formula (d1-2), Z^{2c} represents a hydrocarbon group that has 1 to 30 carbon atoms and that may have a substituent (provided that the carbon atom adjacent to S is not substituted with a fluorine atom).

In Z^{2c}, the hydrocarbon group may be linear or branched, and may have a ring structure. In the hydrocarbon group, a carbon atom (preferably, in a case where the hydrocarbon group has a ring structure, a carbon atom serving as a ring-member atom) may be a carbonyl carbon (—CO—). The hydrocarbon group may be, for example, a group that has a norbornyl group that may have a substituent. A carbon atom forming the norbornyl group may be a carbonyl carbon.

In the formula (d1-2), “Z²—SO₃⁻” is preferably different from the anions represented by the above-described formulas (AN1) to (AN3). For example, Z^{2c} is preferably not aryl groups. For example, in Z^{2c} , the atoms at the α position and the β position with respect to —SO₃⁻ are preferably atoms other than carbon atoms having, as a substituent, a fluorine atom. For example, in Z^{2c}, the atom at the α position and/or the atom at the β position with respect to —SO₃⁻ is preferably a ring-member atom in a ring group.

In the formula (d1-3), R⁵² represents an organic group (preferably a hydrocarbon group having a fluorine atom); Y³ represents a linear, branched, or cyclic alkylene group, an arylene group, or a carbonyl group; and Rf represents a hydrocarbon group.

In the formula (d1-4), R⁵³ and R⁵⁴ each independently represent an organic group (preferably a hydrocarbon group having a fluorine atom). R⁵³ and R⁵⁴ may be bonded together to form a ring.

Such organic anions may be used alone or in combination of two or more thereof.

The photoacid generator is also preferably at least one selected from the group consisting of compounds (I) to (II).

### Compound (I)

The compound (I) is a compound having one or more structural moieties X described below and one or more structural moieties Y described below, and is a compound that generates, upon irradiation with an actinic ray or a radiation, an acid including a first acidic moiety described below derived from the structural moiety X described below and a second acidic moiety described below derived from the structural moiety Y described below.

Structural moiety X: a structural moiety that is constituted by an anionic moiety A₁⁻ and a cationic moiety M₁⁺ and that forms, upon irradiation with an actinic ray or a radiation, the first acidic moiety represented by HA₁

Structural moiety Y: a structural moiety that is constituted by an anionic moiety A₂ and a cationic moiety M₂⁺ and that forms, upon irradiation with an actinic ray or a radiation, the second acidic moiety represented by HA₂

The compound (I) satisfies the following condition I.

Condition I: A compound PI in which the cationic moiety M₁⁺ in the structural moiety X and the cationic moiety M₂⁺ in the structural moiety Y in the compound (I) are replaced by H⁺ has an acid dissociation constant a1 derived from an acidic moiety represented by HA₁ in which the cationic moiety M₁⁺ in the structural moiety X is replaced by H⁺, and an acid dissociation constant a2 derived from an acidic moiety represented by HA₂ in which the cationic moiety M₂⁺ in the structural moiety Y is replaced by H⁺, and the acid dissociation constant a2 is larger than the acid dissociation constant a1.

Hereinafter, the condition I will be more specifically described.

When the compound (I) is, for example, a compound that generates an acid having one first acidic moiety derived from the structural moiety X and one second acidic moiety derived from the structural moiety Y, the compound PI corresponds to a “compound having HA₁ and HA₂”.

The acid dissociation constant a1 and the acid dissociation constant a2 of the compound PI will be more specifically described as follows: in determination of the acid dissociation constants of the compound PI, the pKa at the time when the compound PI turns into a “compound having A₁⁻ and HA₂” is the acid dissociation constant a1, and the pKa at the time when the “compound having A₁⁻ and HA₂” turns into a “compound having A₁⁻ and A₂⁻” is the acid dissociation constant a2.

When the compound (I) is, for example, a compound that generates an acid having two first acidic moieties derived from the structural moieties X and one second acidic moiety derived from the structural moiety Y, the compound PI corresponds to a “compound having two HA₁ and one HA₂”.

In determination of the acid dissociation constants of the compound PI, the acid dissociation constant at the time when the compound PI turns into a “compound having one A₁⁻, one HA₁, and one HA₂” and the acid dissociation constant at the time when the “compound having one A₁⁻, one HA₁, and one HA₂” turns into a “compound having two A₁⁻ and one HA₂” correspond to the above-described acid dissociation constant a1. The acid dissociation constant at the time when the “compound having two A₁⁻ and one HA₂” turns into a “compound having two A₁⁻ and A₂⁻” corresponds to the acid dissociation constant a2. In other words, when the compound PI has a plurality of acid dissociation constants derived from the acidic moieties represented by HA₁ in which the cationic moiety M₁⁺ in the structural moiety X is replaced by H⁺, the value of the acid dissociation constant a2 is larger than the largest value among the plurality of the acid dissociation constants a1. Note that, in a case where the acid dissociation constant at the time when the compound PI turns into the “compound having one A₁⁻, one HA₁, and one HA₂” is defined as aa, and the acid dissociation constant at the time when the “compound having one A₁⁻, one HA₁, and one HA₂” turns into the “compound having two A₁⁻ and one HA₂” is defined as ab, the relationship between aa and ab satisfies aa<ab.

The acid dissociation constant a1 and the acid dissociation constant a2 can be determined by the above-described method of measuring an acid dissociation constant. The compound PI corresponds to an acid generated upon irradiation of the compound (I) with an actinic ray or a radiation.

When the compound (I) has two or more structural moieties X, the structural moieties X may be the same or different. The two or more A₁⁻ and the two or more M₁⁺ may be individually the same or different.

In the compound (I), A₁⁻ above and A₂⁻ above, and M₁⁻ above and M₂⁺ above may be individually the same or different, but A₁⁻ above and A₂⁻ above are preferably different from each other.

In the compound PI, the difference (absolute value) between the acid dissociation constant a1 (when a plurality of acid dissociation constants a1 are present, the maximum value thereof) and the acid dissociation constant a2 is preferably 0.1 or more, more preferably 0.5 or more, and still more preferably 1.0 or more. Note that the upper limit value of the difference (absolute value) between the acid dissociation constant a1 (when a plurality of acid dissociation constants a1 are present, the maximum value thereof) and the acid dissociation constant a2 is not particularly limited, but is, for example, 16 or less.

In the compound PI, the acid dissociation constant a2 is preferably 20 or less, and more preferably 15 or less. Note that the lower limit value of the acid dissociation constant a2 is preferably −4.0 or more.

In the compound PI, the acid dissociation constant a1 is preferably 2.0 or less, and more preferably 0 or less. Note that the lower limit value of the acid dissociation constant a1 is preferably −20.0 or more.

The anionic moiety A₁⁻ and the anionic moiety A₂⁻ are structural moieties including a negatively charged atom or atomic group and may be, for example, structural moieties selected from the group consisting of the following formulas (AA-1) to (AA-3) and formulas (BB-1) to (BB-6).

The anionic moiety A₁⁻ is preferably an anionic moiety that can form an acidic moiety having a small acid dissociation constant, in particular, more preferably any one of the formulas (AA-1) to (AA-3), and still more preferably any one of the formulas (AA-1) and (AA-3).

The anionic moiety A₂⁻ is preferably an anionic moiety that can form an acidic moiety having a larger acid dissociation constant than the anionic moiety A₁⁻, more preferably any one of the formulas (BB-1) to (BB-6), and still more preferably any one of the formulas (BB-1) and (BB-4).

Note that, in the formulas (AA-1) to (AA-3) and the formulas (BB-1) to (BB-6) below, * represent a bonding site.

In the formula (AA-2), R^{A} represent a monovalent organic group. The monovalent organic groups represented by R^{A} are not particularly limited, but may be, for example, a cyano group, a trifluoromethyl group, or a methanesulfonyl group.

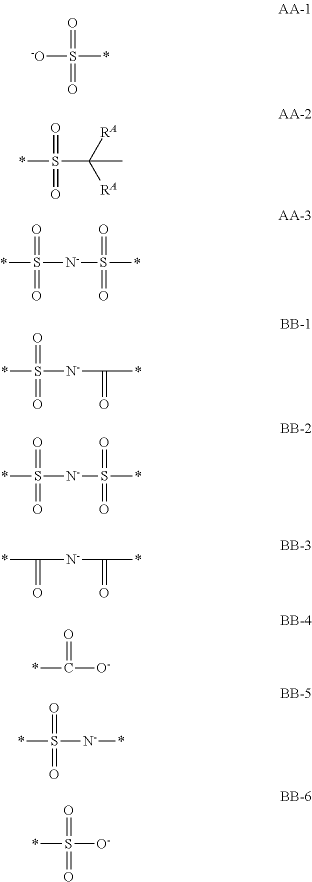

The cationic moiety M₁⁺ and the cationic moiety M₂⁺ are structural moieties including a positively charged atom or atomic group and may be, for example, singly charged organic cations. Note that such an organic cation may be, for example, the above-described organic cation represented by M⁺.

The compound (I) is not particularly limited in terms of specific structures; examples include compounds represented by a formula (Ia-1) to a formula (Ia-5) described later. Compound represented by formula (Ia-1)

Hereinafter, first, the compound represented by the formula (Ia-1) will be described.

M₁₁⁺A₁₁⁻-L₁-A₁₂-M₁₂⁺ (Ia-1)

The compound represented by the formula (Ia-1) generates, upon irradiation with an actinic ray or a radiation, an acid represented by HA₁₁-L₁-A₁₂H.

In the formula (Ia-1), M₁₁⁺ and M₁₂⁺ each independently represent an organic cation.

A₁₁− and A₁₂⁻ each independently represent a monovalent anionic functional group.

L₁ represents a divalent linking group.

M₁₁⁺ and M₁₂⁺ may be the same or different.

A₁₁⁻ and A₁₂⁻ may be the same or different, but are preferably different from each other. Note that, in the formula (Ia-1), in a compound PIa (HA₁₁-L₁-A₁₂H) in which the cations represented by M₁₁⁺ and M₁₂⁺ are replaced by H⁺, the acid dissociation constant a2 derived from the acidic moiety represented by A₁₂H is larger than the acid dissociation constant a1 derived from the acidic moiety represented by HA₁₁. Note that preferred values of the acid dissociation constant a1 and the acid dissociation constant a2 are the same as those described above. The compound PIa and the acid generated from the compound represented by the formula (Ia-1) upon irradiation with an actinic ray or a radiation are the same.

At least one of M₁₁⁺, M₁₂⁺, A₁₁⁻, A₁₂⁻, or L₁ may have, as a substituent, an acid-decomposable group.

In the formula (Ia-1), the organic cations represented by M₁₁⁺ and M₁₂⁺ are the same as those having been described for M⁺.

The monovalent anionic functional group represented by A₁₁⁻ means a monovalent group including the above-described anionic moiety A₁⁻. The monovalent anionic functional group represented by A₁₂⁻ means a monovalent group including the above-described anionic moiety A₂⁻.

The monovalent anionic functional groups represented by A₁₁⁻ and A₁₂⁻ are preferably monovalent anionic functional groups including the anionic moiety of any one of the above-described formulas (AA-1) to (AA-3) and formulas (BB-1) to (BB-6), and more preferably monovalent anionic functional groups selected from the group consisting of formulas (AX-1) to (AX-3) and formulas (BX-1) to (BX-7). In particular, the monovalent anionic functional group represented by A₁₁⁻ is preferably the monovalent anionic functional group represented by any one of the formulas (AX-1) to (AX-3). In particular, the monovalent anionic functional group represented by A₁₂⁻ is preferably the monovalent anionic functional group represented by any one of the formulas (BX-1) to (BX-7), and more preferably the monovalent anionic functional group represented by any one of the formulas (BX-1) to (BX-6).

Note that, as the anionic moiety of the compound represented by the formula (Ia-1), the anion having a monovalent anionic functional group represented by the following formula (BX-1), (BX-2), (BX-3), or (BX-6) may be or may not be an anion corresponding to the anionic moiety represented by the formula (3) in which the “—SO₂—N⁻—” moiety has a pKa of −3.00 or more.

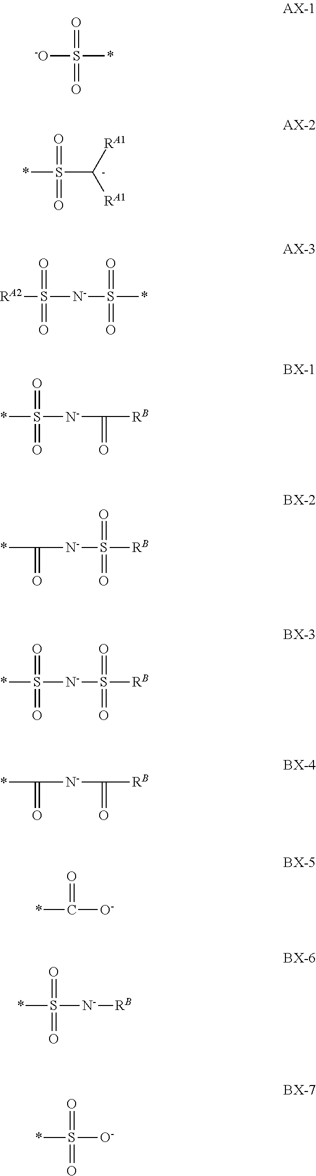

In the formulas (AX-1) to (AX-3), R^{A1} and R^{A2} each independently represent a monovalent organic group. * represent a bonding site.

The monovalent organic groups represented by R^{A1} are not particularly limited, but may be, for example, a cyano group, a trifluoromethyl group, or a methanesulfonyl group.

The monovalent organic group represented by R^{A2} is preferably a linear, branched, or cyclic alkyl group, or an aryl group.

In the formulas (BX-1) to (BX-4) and the formula (BX-6), R^{B} represent a monovalent organic group. * represent a bonding site.

The monovalent organic groups represented by R^{B} are preferably a linear, branched, or cyclic alkyl group, or an aryl group.

In the formula (Ia-1), the divalent linking group represented by L₁ is not particularly limited, and examples thereof include —CO—, —NR—, —O—, —S—, —SO—, —SO₂—, an alkylene group (that preferably has 1 to 6 carbon atoms and may be linear or branched), a cycloalkylene group (preferably having 3 to 15 carbon atoms), an alkenylene group (preferably having 2 to 6 carbon atoms), a divalent aliphatic heterocyclic group (having preferably a 5- to 10-membered ring, more preferably a 5- to 7-membered ring, and still more preferably a 5- to 6-membered ring that have at least one N atom, 0 atom, S atom, or Se atom in the ring structure), a divalent aromatic heterocyclic group (having preferably a 5- to 10-membered ring, more preferably a 5- to 7-membered ring, and still more preferably a 5- to 6-membered ring that have at least one N atom, 0 atom, S atom, or Se atom in the ring structure), a divalent aromatic hydrocarbon cyclic group (having preferably a 6- to 10-membered ring, and more preferably a 6-membered ring), and divalent linking groups that are combinations of a plurality of the foregoing. R above may be a hydrogen atom or a monovalent organic group. The monovalent organic group is not particularly limited, but is preferably, for example, an alkyl group (preferably having 1 to 6 carbon atoms).

The alkylene group, the cycloalkylene group, the alkenylene group, the divalent aliphatic heterocyclic group, the divalent aromatic heterocyclic group, and the divalent aromatic hydrocarbon cyclic group may have a substituent. Examples of the substituent include halogen atoms (preferably a fluorine atom).

In particular, the divalent linking group represented by L₁ is preferably a divalent linking group represented by a formula (L1).

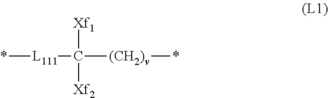

In the formula (L1), L₁₁₁ represents a single bond or a divalent linking group.

The divalent linking group represented by L₁₁₁ is not particularly limited, and examples thereof include —CO—, —NH—, —O—, —SO—, —SO₂—, an alkylene group that may have a substituent (that more preferably has 1 to 6 carbon atoms and may be linear or branched), a cycloalkylene group that may have a substituent (that preferably has 3 to 15 carbon atoms), an arylene group that may have a substituent (that preferably has 6 to 10 carbon atoms), and divalent linking groups that are combinations of a plurality of the foregoing. The substituent is not particularly limited, and may be, for example, a halogen atom.

p represents an integer of 0 to 3, and preferably represents an integer of 1 to 3.

v represents an integer of 0 or 1.

Xf₁ each independently represent a fluorine atom or an alkyl group substituted with at least one fluorine atom.

Xf₂ each independently represent a hydrogen atom, an alkyl group that may have, as a substituent, a fluorine atom, or a fluorine atom.

* represent a bonding site.

When, in the formula (Ia-1), L₁ represents a divalent linking group represented by the formula (L1), the L₁₁₁-side direct bond (*) in the formula (L1) is preferably bonded to A₁₂⁻ in the formula (Ia-1).

### Compounds Represented by Formulas (Ia-2) to (Ia-4)

Hereinafter, compounds represented by formulas (Ia-2) to (Ia-4) will be described.

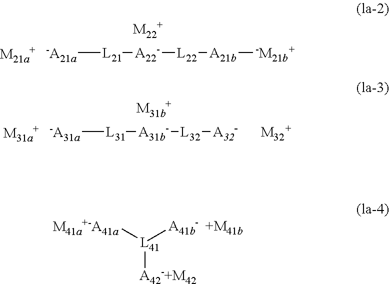

In the formula (Ia-2), A₂₁ₐ⁻ and A_{21b}⁻ each independently represent a monovalent anionic functional group. For A₂₁ₐ⁻ and A_{21b}⁻, the monovalent anionic functional group means a monovalent group including the above-described anionic moiety A₁⁻. For A₂₁ₐ⁻ and A_{21b}⁻, the monovalent anionic functional group is not particularly limited, but may be, for example, a monovalent anionic functional group selected from the group consisting of the above-described formulas (AX-1) to (AX-3).

A₂₂⁻ represents a divalent anionic functional group. The divalent anionic functional group represented by A₂₂⁻ means a divalent linking group including the above-described anionic moiety A₂⁻. For the divalent anionic functional group represented by A₂₂⁻, examples include divalent anionic functional groups represented by the following formulas (BX-8) to (BX-11).

Note that, as the anionic moiety of the compound represented by the formula (Ia-2), the anion having a divalent anionic functional group represented by the following formula (BX-8), (BX-9), or (BX-11) may be or may not be an anion corresponding to the anionic moiety represented by the formula (3) in which the “—SO₂—N⁻—” moiety has a pKa of −3.00 or more.

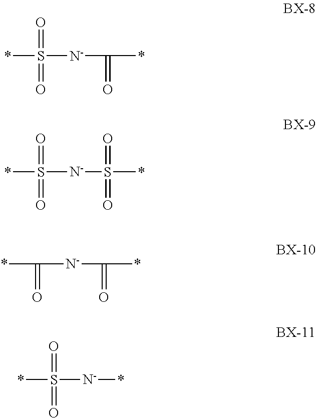 [SMILES: *C(=O)[N-]S(*)(=O)=O ; *S(=O)(=O)[N-]S(*)(=O)=O ; *C(=O)[N-]C(*)=O ; *[N-]S(*)(=O)=O]

M₂₁ₐ⁺, M_{21b}⁺, and M₂₂⁺ each independently represent an organic cation. The organic cations represented by M₂₁ₐ⁺, M_{21b}⁺, and M₂₂⁺ have the same definitions and preferred examples as those of M₁₁⁺ described above.

L₂₁ and L₂₂ each independently represent a divalent organic group.

In a compound PIa-2 in which organic cations represented by M₂₁ₐ⁺, M_{21b}⁺, and M₂₂⁺ in the formula (Ia-2) are replaced by H⁺, the acid dissociation constant a2 derived from the acidic moiety represented by A₂₂H is larger than the acid dissociation constant a1-1 derived from the acidic moiety represented by A₂₁ₐH and the acid dissociation constant a1-2 derived from the acidic moiety represented by A_{21b}H. Note that the acid dissociation constant a1-1 and the acid dissociation constant a1-2 correspond to the above-described acid dissociation constant a1.

Note that A₂₁ₐ⁻ and A_{21b}⁻ may be the same or different. M₂₁ₐ⁺, M_{21b}⁺, and M₂₂⁺ may be the same or different.

At least one of M₂₁ₐ⁺, M_{21b}⁺, M₂₂⁺, A₂₁ₐ⁻, A_{21b}⁻, L₂₁, or L₂₂ may have, as a substituent, an acid-decomposable group.

In the formula (Ia-3), A₃₁ₐ⁻ and A₃₂⁻ each independently represent a monovalent anionic functional group. Note that the monovalent anionic functional group represented by A₃₁a has the same definition and preferred examples as the above-described A₂₁ₐ⁻ and A_{21b}⁻ in the formula (Ia-2).

The monovalent anionic functional group represented by A₃₂⁻ means a monovalent group including the above-described anionic moiety A₂⁻. The monovalent anionic functional group represented by A₃₂⁻ is not particularly limited, but may be, for example, a monovalent anionic functional group selected from the group consisting of the above-described formulas (BX-1) to (BX-7).

Note that, as the anionic moiety of the compound represented by the formula (Ia-3), the anion having a monovalent anionic functional group represented by the above-described formula (BX-1), (BX-2), (BX-3), or (BX-6) may be or may not be an anion corresponding to the anionic moiety represented by the above-described formula (3) in which the “—SO₂—N⁻—” moiety has a pKa of −3.00 or more.

A_{31b}⁻ represents a divalent anionic functional group. The divalent anionic functional group represented by A_{31b}⁻ means a divalent linking group including the above-described anionic moiety A₁⁻. The divalent anionic functional group represented by A_{31b}⁻ may be, for example, a divalent anionic functional group represented by the following formula (AX-4).

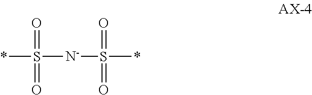 [SMILES: *S(=O)(=O)[N-]S(*)(=O)=O]

M₃₁ₐ⁺, M_{31b}⁺, and M₃₂⁺ each independently represent a monovalent organic cation. The organic cations represented by M₃₁ₐ⁺, M_{31b}⁺, and M₃₂⁺ have the same definitions and preferred examples as M₁₁⁺ described above.

L₃₁ and L₃₂ each independently represent a divalent organic group.

In a compound PIa-3 in which organic cations represented by M₃₁ₐ⁺, M_{31b}⁺, and M₃₂⁺ are replaced by H⁺ in the above-described formula (Ia-3), the acid dissociation constant a2 derived from the acidic moiety represented by A₃₂H is larger than the acid dissociation constant a1-3 derived from the acidic moiety represented by A₃₁ₐH and the acid dissociation constant a1-4 derived from the acidic moiety represented by A_{31b}H. Note that the acid dissociation constant a1-3 and the acid dissociation constant a1-4 correspond to the above-described acid dissociation constant a1.

Note that A₃₁ₐ⁻ and A₃₂⁻ may be the same or different. M₃₁ₐ⁺, M_{31b}⁺, and M₃₂⁺ may be the same or different.

At least one of M₃₁ₐ⁺, M_{31b}⁺, M₃₂⁺, A₃₁ₐ⁻, A₃₂⁻, L₃₁, or L₃₂ may have, as a substituent, an acid-decomposable group.

In the formula (Ia-4), A₄₁ₐ⁻, A_{41b}⁻, and A₄₂⁻ each independently represent a monovalent anionic functional group. Note that, for A₄₁ₐ⁻ and A_{41b}⁻ the monovalent anionic functional group has the same definition as the above-described A₂₁ₐ⁻ and A_{21b}⁻ in the formula (Ia-2). The monovalent anionic functional group represented by A₄₂⁻ has the same definition and preferred examples as the above-described A₃₂⁻ in the formula (Ia-3).

M₄₁ₐ⁺, M_{41b}⁺, and M₄₂⁺ each independently represent an organic cation. The organic cations represented by M₄₁ₐ⁺, M_{41b}⁺, and M₄₂⁺ have the same definitions and preferred examples as M₁₁⁺ described above.

L₄₁ represents a trivalent organic group.

Note that, as the anionic moiety of the compound represented by the formula (Ia-4), the anion having a monovalent anionic functional group represented by the above-described formula (BX-1), (BX-2), (BX-3), or (BX-6) may be or may not be an anion corresponding to the anionic moiety represented by the above-described formula (3) in which the “—SO₂—N⁻—” moiety has a pKa of −3.00 or more.

In a compound PIa-4 in which the organic cations represented by M₄₁ₐ⁺, M_{41b}⁺, and M₄₂⁺ in the above-described formula (Ia-4) are replaced by H⁺, the acid dissociation constant a2 derived from the acidic moiety represented by A₄₂H is larger than the acid dissociation constant a1-5 derived from the acidic moiety represented by A₄₁ₐH and the acid dissociation constant a1-6 derived from the acidic moiety represented by A_{41b}H. Note that the acid dissociation constant a1-5 and the acid dissociation constant a1-6 correspond to the above-described acid dissociation constant a1.

Note that A₄₁ₐ⁻, A_{41b}⁻, and A₄₂⁻ may be the same or different. M₄₁ₐ⁺, M_{41b}⁺, and M₄₂⁺ may be the same or different.

At least one of M₄₁ₐ⁺, M_{41b}⁺, M₄₂⁺, A₄₁ₐ⁻, A_{41b}⁻, A₄₂⁻, or L₄₁ may have, as a substituent, an acid-decomposable group.

For L₂₁ and L₂₂ in the formula (Ia-2) and L₃₁ and L₃₂ in the formula (Ia-3), the divalent organic group is not particularly limited, and examples thereof include —CO—, —NR—, —O—, —S—, —SO—, —SO₂—, an alkylene group (that preferably has 1 to 6 carbon atoms and may be linear or branched), a cycloalkylene group (preferably having 3 to 15 carbon atoms), an alkenylene group (preferably having 2 to 6 carbon atoms), a divalent aliphatic heterocyclic group (having preferably a 5- to 10-membered ring, more preferably a 5- to 7-membered ring, and still more preferably a 5- to 6-membered ring that have at least one N atom, 0 atom, S atom, or Se atom in the ring structure), a divalent aromatic heterocyclic group (having preferably a 5- to 10-membered ring, more preferably a 5- to 7-membered ring, and still more preferably a 5- to 6-membered ring that have at least one N atom, 0 atom, S atom, or Se atom in the ring structure), a divalent aromatic hydrocarbon cyclic group (having preferably a 6- to 10-membered ring, and still more preferably a 6-membered ring), and divalent organic groups that are combinations of a plurality of the foregoing. In —NR— above, R may be a hydrogen atom or a monovalent organic group. The monovalent organic group is not particularly limited, but is preferably, for example, an alkyl group (preferably having 1 to 6 carbon atoms). The alkylene group, the cycloalkylene group, the alkenylene group, the divalent aliphatic heterocyclic group, the divalent aromatic heterocyclic group, and the divalent aromatic hydrocarbon cyclic group may have a substituent. Examples of the substituent include halogen atoms (preferably a fluorine atom).

For L₂₁ and L₂₂ in the formula (Ia-2) and L₃₁ and L₃₂ in the formula (Ia-3), the divalent organic group is also preferably, for example, a divalent organic group represented by the following formula (L2).

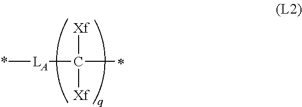

In the formula (L2), q represents an integer of 1 to 3. * represent a bonding site.

Xf's each independently represent a fluorine atom or an alkyl group substituted with at least one fluorine atom. The alkyl group preferably has 1 to 10 carbon atoms, and more preferably 1 to 4 carbon atoms. The alkyl group substituted with at least one fluorine atom is preferably a perfluoroalkyl group.

Xf's are preferably a fluorine atom or a perfluoroalkyl group having 1 to 4 carbon atoms, and more preferably a fluorine atom or CF₃. In particular, still more preferably, both of Xf's are fluorine atoms.

L_{A} represents a single bond or a divalent linking group.

The divalent linking group represented by L_{A} is not particularly limited, and examples thereof include —CO—, —O—, —SO—, —SO₂—, an alkylene group (that preferably has 1 to 6 carbon atoms and may be linear or branched), a cycloalkylene group (preferably having 3 to 15 carbon atoms), a divalent aromatic hydrocarbon cyclic group (having preferably a 6- to 10-membered ring, and more preferably a 6-membered ring), and divalent linking groups that are combinations of a plurality of the foregoing.

The alkylene group, the cycloalkylene group, and the divalent aromatic hydrocarbon cyclic group may have a substituent. Examples of the substituent include halogen atoms (preferably a fluorine atom).

Examples of the divalent organic group represented by the formula (L2) include *—CF₂—*, *—CF₂—CF₂—*, *—CF₂—CF₂—CF₂—*, *-Ph-O—SO₂—CF₂—*, *-Ph-O—SO₂—CF₂—CF₂—*, *-Ph-O—SO₂—CF₂—CF₂—CF₂—*, and *-Ph-OCO—CF₂—*. Note that Ph are a phenylene group that may have a substituent, and preferably a 1,4-phenylene group. The substituent is not particularly limited, but is preferably an alkyl group (for example, preferably having 1 to 10 carbon atoms, and more preferably having 1 to 6 carbon atoms), an alkoxy group (for example, preferably having 1 to 10 carbon atoms, and more preferably having 1 to 6 carbon atoms), or an alkoxycarbonyl group (for example, preferably having 2 to 10 carbon atoms, and more preferably having 2 to 6 carbon atoms).

When L₂₁ and L₂₂ in the formula (Ia-2) represent the divalent organic group represented by the formula (L2), the L_{A}-side direct bond (*) in the formula (L2) is preferably bonded to A₂₁ₐ⁻ and A_{21b}⁻ in the formula (Ia-2).

When L₃₁ and L₃₂ in the formula (Ia-3) represent the divalent organic group represented by the formula (L2), the L_{A}-side direct bond (*) in the formula (L2) is preferably bonded to A₃₁ₐ⁻ and A₃₂⁻ in the formula (Ia-3).

### Compound Represented by Formula (Ia-5)

Hereinafter, the formula (Ia-5) will be described.

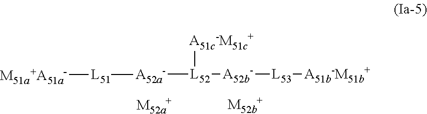

In the formula (Ia-5), A₅₁ₐ⁻, A_{51b}⁻, and A_{51c}⁻ each independently represent a monovalent anionic functional group. For A₅₁ₐ⁻, A_{51b}⁻, and A_{51c}⁻, the monovalent anionic functional group means a monovalent group including the above-described anionic moiety A₁⁻. For A₅₁ₐ⁻, A_{51b}⁻, and A_{51c}⁻, the monovalent anionic functional group is not particularly limited, but may be, for example, a monovalent anionic functional group selected from the group consisting of the above-described formulas (AX-1) to (AX-3).

A₅₂ₐ⁻ and A_{52b}⁻ represent a divalent anionic functional group. For A₅₂ₐ⁻ and A_{52b}⁻, the divalent anionic functional group means a divalent linking group including the above-described anionic moiety A₂⁻. The divalent anionic functional group represented by A₂₂⁻ may be, for example, a divalent anionic functional group selected from the group consisting of the above-described formulas (BX-8) to (BX-11).

Note that, as the anionic moiety of the compound represented by the formula (Ia-5), the anion having a divalent anionic functional group represented by the above-described formula (BX-8), (BX-9) or (BX-11) may be or may not be an anion corresponding to the anionic moiety represented by the above-described formula (3) in which the “—SO₂—N⁻—” moiety has a pKa of −3.00 or more.

M₅₁ₐ⁺, M_{51b}⁺, M_{51c}⁺, M₅₂ₐ⁺, and M_{52b}⁺ each independently represent an organic cation. The organic cations represented by M₅₁ₐ⁺, M_{51b}⁺, M_{51c}⁺, M₅₂ₐ⁺, and M_{52b}⁺ have the same definitions and preferred examples as M₁₁⁺ described above.

L₅₁ and L₅₃ each independently represent a divalent organic group. For L₅₁ and L₅₃, the divalent organic group has the same definition and preferred examples as the above-described L₂₁ and L₂₂ in the formula (Ia-2).

L₅₂ represents a trivalent organic group. The trivalent organic group represented by L₅₂ has the same definition and preferred examples as the above-described L₄₁ in the formula (Ia-4).

In a compound PIa-5 in which organic cations represented by M₅₁ₐ⁺, M_{51b}⁺, M_{51c}⁺, M₅₂ₐ⁺, and M_{52b}⁺ in the above-described formula (Ia-5) are replaced by H⁺, the acid dissociation constant a2-1 derived from the acidic moiety represented by A₅₂ₐH and the acid dissociation constant a2-2 derived from the acidic moiety represented by A_{52b}H are larger than the acid dissociation constant a1-1 derived from the acidic moiety represented by A₅₁ₐH, the acid dissociation constant a1-2 derived from the acidic moiety represented by A_{51b}H, and the acid dissociation constant a1-3 derived from the acidic moiety represented by A_{51c}H. Note that the acid dissociation constants a1-1 to a1-3 correspond to the above-described acid dissociation constant a1, and the acid dissociation constants a2-1 and a2-2 correspond to the above-described acid dissociation constant a2.

Note that A₅₁ₐ⁻, A_{51b}⁻, and A_{51c}⁻ may be the same or different. A₅₂ₐ⁻ and A_{52b}⁻ may be the same or different.

M₅₁ₐ⁺, M_{51b}⁺, M_{51c}⁺, M₅₂ₐ⁺, and M_{52b}⁺ may be the same or different.

At least one of M_{51b}⁺, M_{51c}⁺, M₅₂ₐ⁺, M_{52b}⁺, A₅₁ₐ⁻, A_{51b}⁻, A_{51c}⁻, L₅₁, L₅₂, or L₅₃ may have, as a substituent, an acid-decomposable group.

### Compound (II)

A compound (II) is a compound having two or more structural moieties X above and one or more structural moieties Z below, and is a compound that generates, upon irradiation with an actinic ray or a radiation, an acid including two or more first acidic moieties derived from the structural moieties X and the structural moiety Z.

Structural Moiety Z: A Nonionic Moiety that can Neutralize Acid

In the compound (II), the definition of the structural moiety X and the definitions of A₁⁻ and M₁⁺ are the same as the definition of the structural moiety X and the definitions of A₁⁻ and M₁⁺ in the above-described compound (I), and preferred examples are also the same.

In a compound PII in which the cationic moiety M₁⁺ in the structural moiety X in the compound (II) is replaced by H⁺, the preferred range of the acid dissociation constant a1 derived from the acidic moiety represented by HA₁ in which the cationic moiety M₁⁺ in the structural moiety X is replaced by H⁺ is the same as in the acid dissociation constant a1 in the compound PI.

Note that, when the compound (II) is, for example, a compound that generates an acid having two first acidic moieties derived from the structural moiety X and the structural moiety Z, the compound PII corresponds to a “compound having two HA₁”. In determination of the acid dissociation constants of this compound PII, the acid dissociation constant at the time when the compound PII turns into a “compound having one A⁻ and one HA₁” and the acid dissociation constant at the time when the “compound having one A₁⁻ and one HA₁” turns into a “compound having two A₁⁻” correspond to the acid dissociation constant a1.

The acid dissociation constant a1 can be determined by the above-described method of measuring an acid dissociation constant.

The compound PII corresponds to an acid generated upon irradiation of the compound (II) with an actinic ray or a radiation.

Note that the two or more structural moieties X may be the same or different. The two or more A₁⁻ and the two or more M₁⁺ may be individually the same or different.

The nonionic moiety that can neutralize acid in the structural moiety Z is not particularly limited, and is preferably, for example, a moiety including a group that can electrostatically interact with a proton or a functional group having an electron.

Examples of the group that can electrostatically interact with a proton or the functional group having an electron include a functional group having a macrocyclic structure such as cyclic polyether, and a functional group having a nitrogen atom having an unshared electron pair that does not contribute to π-conjugation. Examples of the nitrogen atom having an unshared electron pair that does not contribute to π-conjugation include nitrogen atoms having partial structures represented by the following formulas.

[symbol]

Unshared Electron Pair

The partial structure of the group that can electrostatically interact with a proton or the functional group having an electron may be, for example, a crown ether structure, an azacrown ether structure, a primary to tertiary amine structure, a pyridine structure, an imidazole structure, or a pyrazine structure; in particular, preferred are primary to tertiary amine structures.

Non-limiting specific examples of the photoacid generator include Compounds B-1 to B-15 and Compounds C-1 to C-35 used in Examples.

When a composition of the present invention includes a photoacid generator, the content thereof is not particularly limited, and is, from the viewpoint of forming a pattern having a more square profile, relative to the total solid content of the composition, preferably 0.5 mass % or more, and more preferably 1.0 mass % or more. The content is, relative to the total solid content of the composition, preferably 70.0 mass % or less, more preferably 60.0 mass % or less, and still more preferably 50.0 mass % or less.

Such photoacid generators may be used alone or in combination of two or more thereof.

As the photoacid generator, such ionic compounds (Y) may be used alone or in combination of two or more thereof. As the photoacid generator, compounds other than the ionic compound (Y) may be used alone or in combination of two or more thereof. Alternatively, the ionic compound (Y) and a compound other than the ionic compound (Y) may be used in combination.

### Acid Diffusion Control Agent

A composition of the present invention may include an acid diffusion control agent.

The acid diffusion control agent serves as a quencher that traps the acid generated from the photoacid generator or the like upon exposure and that suppresses the reaction of the acid-decomposable resin, in the unexposed region, caused by an excess of generated acid.

The acid diffusion control agent may be the above-described ionic compound (Y) or may not be the ionic compound (Y).

The type of the acid diffusion control agent is not particularly limited, and examples thereof include a basic compound (CA), a low-molecular-weight compound (CB) having a nitrogen atom and having a group that leaves by the action of an acid, and a compound (CC) whose acid diffusion control ability is reduced or lost upon irradiation with an actinic ray or a radiation.

Examples of the compound (CC) include an onium salt compound (CD) that becomes a weak acid relative to the photoacid generator, and a basic compound (CE) whose basicity is reduced or lost upon irradiation with an actinic ray or a radiation.

Specific examples of the basic compound (CA) include, for example, those described in Paragraphs [0132] to [0136] of WO2020/066824A; specific examples of the basic compound (CE) whose basicity is reduced or lost upon irradiation with an actinic ray or a radiation include those described in Paragraphs [0137] to [0155] of WO2020/066824A, and those described in Paragraph [0164] of WO2020/066824A; and, specific examples of the low-molecular-weight compound (CB) having a nitrogen atom and having a group that leaves by the action of an acid include those described in Paragraphs [0156] to [0163] of WO2020/066824A.

Specific examples of the onium salt compound (CD) that becomes a weak acid relative to the photoacid generator include, for example, those described in Paragraphs [0305] to [0314] of WO2020/158337A.

In a preferred embodiment, the onium salt compound (CD) that becomes a weak acid relative to the photoacid generator is an onium salt compound having an anion represented by the above-described formulas (d1-1) to (d1-4).

When the onium salt compound (CD) has an anion represented by the above-described formula (d1-3) or formula (d1-4), the onium salt compound (CD) may be or may not be the ionic compound (Y). The anion represented by the above-described formula (d1-3) or formula (d1-4) may be or may not be an anion corresponding to the anionic moiety that is represented by the formula (3) in which the “—SO₂—N⁻—” moiety has a pKa of −3.00 or more.

In a preferred embodiment, the anion represented by the above-described formula (d1-3) is an anionic moiety represented by the above-described formula (3-2). The anionic moiety represented by the formula (3-2) is preferably an anionic moiety represented by a formula (3-3) below.

In a preferred embodiment, the acid diffusion control agent is preferably a compound having an anionic moiety represented by the following formula (3-3).

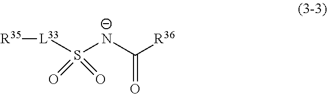

In the formula (3-3),

L³³ represents an alkylene group.

R³⁵ represents a halogen atom or a group having an alicyclic structure.

R³⁶ represents an alkyl group or a cycloalkyl group.

In the formula (3-3), L³³ represents an alkylene group.

L³³ is preferably a linear or branched alkylene group having 1 to 12 carbon atoms that may have a halogen atom, and more preferably a linear or branched alkylene group having 1 to 3 carbon atoms that may have a fluorine atom.

In the formula (3-3), R³⁵ represents a halogen atom or a group having an alicyclic structure.

For R³⁵, the halogen atom is preferably a fluorine atom.

For R³⁵, the group having an alicyclic structure is preferably a group represented by -L^{35a}-R^{35a} (where L^{35a} represents a single bond, an alkylene group, —O—, —C(═O)—, or a group that is a combination of the foregoing; R^{35a} represents an alicyclic group).

The alicyclic group may be monocyclic or may be polycyclic. Examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. The alicyclic group may further have a substituent, and a part of methylene groups in the alicyclic structure may be substituted with a carbonyl group.

In the formula (3-3), R³⁶ represents an alkyl group or a cycloalkyl group.

R³⁶ is preferably an alkyl group having 1 to 3 carbon atoms that may have a fluorine atom, or a monocyclic or polycyclic cycloalkyl group having 6 to 10 carbon atoms.

The compound having an anionic moiety represented by the above-described formula (3-3) has an anionic moiety represented by the above-described formula (3-3) and a cationic moiety.

The cationic moiety is preferably an organic cation. For the valence, the organic cation may be mono-, di-, or higher valent. The organic cation is not particularly limited, and may be the above-described M⁺.

In a preferred embodiment, the acid diffusion control agent is preferably a compound having an anionic moiety represented by the following formula (3-4).

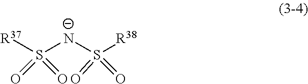

In the formula (3-4),

R³⁷ and R³⁸ each independently represent an alkyl group or a cycloalkyl group.

R³⁷ and R³⁸ are each independently preferably an alkyl group having 1 to 12 carbon atoms and not having fluorine atoms, or a monocyclic cycloalkyl group having 6 to 12 carbon atoms and not having fluorine atoms.

The compound having an anionic moiety represented by the above-described formula (3-4) has an anionic moiety represented by the above-described formula (3-4) and a cationic moiety.

The cationic moiety is preferably an organic cation. For the valence, the organic cation may be mono-, di-, or higher valent. The organic cation is not particularly limited, and may be the above-described M⁺.

In the compound having an anionic moiety represented by the above-described formula (3-3), a compound in which the “—SO₂—N⁻—” moiety has a pKa of −3.00 or more is included in the ionic compound (Y).

In the compound having an anionic moiety represented by the above-described formula (3-4), a compound in which the “—SO₂—N⁻—” moiety has a pKa of −3.00 or more is included in the ionic compound (Y).

In addition to those described above, for example, the publicly known compounds disclosed in Paragraphs [0627] to [0664] in US2016/0070167A1, Paragraphs [0095] to [0187] in US2015/0004544A1, Paragraphs [0403] to [0423] in US2016/0237190A1, and Paragraphs [0259] to [0328] in US2016/0274458A1 can be suitably used as acid diffusion control agents.

Non-limiting specific examples of the acid diffusion control agent also include Compounds G-1 to G-5, Compounds E-1 to E-15, and Compounds D-1 to D-9 used in Examples.

When a composition of the present invention includes an acid diffusion control agent, the content of the acid diffusion control agent (when there are a plurality of acid diffusion control agents, the total content thereof) is preferably, relative to the total solid content of the composition, 0.1 to 15.0 mass % and more preferably 1.0 to 15.0 mass %.

In a composition of the present invention, such acid diffusion control agents may be used alone or in combination of two or more thereof.

### Hydrophobic Resin (I)

A composition of the present invention may further include a hydrophobic resin different from the resin (A).

The hydrophobic resin is preferably designed so as to be localized in the surface of the actinic ray-sensitive or radiation-sensitive film; however, unlike surfactants, the hydrophobic resin does not necessarily need to have intramolecularly a hydrophilic group, and does not necessarily contribute to homogeneous mixing of a polar substance and a nonpolar substance.

Advantages due to addition of the hydrophobic resin may be control of static and dynamic contact angles (for water) at the surface of the resist film, and suppression of outgassing.

The hydrophobic resin, from the viewpoint of localization in the surface layer of the film, preferably has one or more species, more preferably two or more species, selected from the group consisting of a fluorine atom, a silicon atom, and a CH₃ moiety included in the side chain moiety of the resin. The hydrophobic resin preferably has a hydrocarbon group having 5 or more carbon atoms. The resin may have such a group in the main chain or, as a substituent, in a side chain.

Examples of the hydrophobic resin include the compounds described in Paragraphs [0275] to [0279] in WO2020/004306A.

When a composition of the present invention includes a hydrophobic resin, the content of the hydrophobic resin is, relative to the total solid content of the composition, preferably 0.01 to 20.0 mass %, and more preferably 0.1 to 15.0 mass %.

### Surfactant (H)

A composition of the present invention may include a surfactant. In the case of including a surfactant, a pattern having higher adhesiveness and a less number of development defects can be formed.

The surfactant is preferably a fluorine-based and/or silicone-based surfactant.

Examples of the fluorine-based and/or silicone-based surfactant include the surfactants disclosed in Paragraphs [0218] and [0219] of WO2018/193954A.

Such surfactants may be used alone or in combination of two or more thereof.

When a composition of the present invention includes a surfactant, the content of the surfactant is, relative to the total solid content of the composition, preferably 0.0001 to 2.0 mass %, more preferably 0.0005 to 1.0 mass %, and still more preferably 0.1 to 1.0 mass %.

### Solvent (F)

A composition of the present invention preferably includes a solvent.

The solvent preferably includes at least one of (M1) a propylene glycol monoalkyl ether carboxylate or (M2) at least one selected from the group consisting of a propylene glycol monoalkyl ether, a lactate, an acetate, an alkoxypropionate, a chain ketone, a cyclic ketone, a lactone, and an alkylene carbonate. Note that the solvent may further include a component other than the components (M1) and (M2).

A combination of the above-described solvent and the above-described resin is preferred from the viewpoint of improving the coatability of the composition and reducing the number of development defects of the pattern. The above-described solvent is well-balanced in terms of solubility of the above-described resin, boiling point, and viscosity, to thereby suppress, for example, unevenness of the film thickness of the resist film and generation of deposit during spin-coating.

Details of the component (M1) and the component (M2) are described in Paragraphs [0218] to [0226] in WO2020/004306A, and these contents are incorporated herein by reference.

When the solvent further includes a component other than the components (M1) and (M2), the content of the component other than the components (M1) and (M2) relative to the total amount of the solvent is preferably 5 to 30 mass %.

The content of the solvent in a composition of the present invention is determined such that the solid-content concentration is preferably 0.5 to 30 mass %, and more preferably 1 to 20 mass %. This further improves the coatability of the composition of the present invention.

Note that the solid content means all the components other than the solvent, and, as described above, means components that form the actinic ray-sensitive or radiation-sensitive film.

The solid-content concentration is a mass percentage of the mass of other components excluding the solvent relative to the total mass of a composition of the present invention.

The “total solid content” refers to the total mass of the components excluding the solvent from all the components of a composition of the present invention. As described above, the “solid content” is components excluding the solvent, and may be a solid or a liquid at 25° C., for example.

### Other Additives

A composition of the present invention may further include a dissolution-inhibiting compound, a dye, a plasticizer, a photosensitizer, a light absorbent, and/or a compound that promotes solubility in a developer (for example, a phenol compound having a molecular weight of 1000 or less, or an alicyclic or aliphatic compound including a carboxyl group).

The “dissolution-inhibiting compound” is a compound that is decomposed by the action of an acid to undergo a decrease in the degree of solubility in organic-based developers, and has a molecular weight of 3000 or less.

A composition of the present invention is suitably used as a photosensitive composition for EUV exposure.

The EUV light has a wavelength of 13.5 nm, which is a shorter wavelength than in the ArF (wavelength: 193 nm) light and the like, and hence provides, upon exposure at the same sensitivity, a smaller number of incident photons. Thus, “photon shot noise”, which is random variations in the number of photons, exerts a strong effect, which leads to degradation of LER and bridge defects. In order to reduce the photon shot noise, a method of increasing the exposure dose to increase the number of incident photons may be employed; however, there is a tradeoff between this method and the demand for an increase in the sensitivity. Actinic ray-sensitive or radiation-sensitive film and pattern forming method

The procedures of the pattern forming method using the composition are not particularly limited, but preferably have the following steps.

Step 1: a step of using the actinic ray-sensitive or radiation-sensitive resin composition to form an actinic ray-sensitive or radiation-sensitive film on a substrate
Step 2: a step of exposing the actinic ray-sensitive or radiation-sensitive film
Step 3: a step of using a developer to develop the exposed actinic ray-sensitive or radiation-sensitive film to form a pattern

Hereinafter, procedures of the steps will be individually described in detail.

### Step 1: Actinic Ray-Sensitive or Radiation-Sensitive Film Formation Step

The step 1 is a step of using the actinic ray-sensitive or radiation-sensitive resin composition to form an actinic ray-sensitive or radiation-sensitive film on a substrate.

Examples of the method of using the actinic ray-sensitive or radiation-sensitive resin composition to form an actinic ray-sensitive or radiation-sensitive film (preferably, a resist film) on a substrate include a method of applying a composition of the present invention onto a substrate.

Note that a composition of the present invention is preferably filtered through a filter before application as needed. The filter preferably has a pore size of 0.1 m or less, more preferably 0.05 m or less, and still more preferably 0.03 m or less. The filter is preferably formed of polytetrafluoroethylene, polyethylene, or nylon.

A composition of the present invention can be applied onto a substrate (such as a silicon, silicon dioxide-coated substrate) used in the production of an integrated circuit element, by an appropriate application process using a spinner, a coater, or the like. The application process is preferably spin-coating using a spinner. The spin-coating using a spinner is preferably performed at a rotation rate of 1000 to 3000 rpm.

After application of a composition of the present invention, the substrate may be dried to form an actinic ray-sensitive or radiation-sensitive film. Note that, as needed, as underlayers of the actinic ray-sensitive or radiation-sensitive film, various underlying films (an inorganic film, an organic film, or an antireflection film) may be formed.

The drying process may be, for example, a process of performing heating to achieve drying. The heating can be performed using means included in an ordinary exposure device and/or an ordinary development device, or may alternatively be performed using a hot plate, for example. The heating temperature is preferably 80 to 150° C., more preferably 80 to 140° C., and still more preferably 80 to 130° C. The heating time is preferably 30 to 1000 seconds, more preferably 60 to 800 seconds, and still more preferably 60 to 600 seconds.

The film thickness of the actinic ray-sensitive or radiation-sensitive film is not particularly limited, but is, from the viewpoint of enabling formation of more precise fine patterns, preferably 10 to 120 nm. In particular, in the case of employing EUV exposure, the film thickness of the actinic ray-sensitive or radiation-sensitive film is more preferably 10 to 65 nm, and still more preferably 15 to 50 nm. In the case of employing ArF liquid immersion exposure, the film thickness of the actinic ray-sensitive or radiation-sensitive film is more preferably 10 to 120 nm, and still more preferably 15 to 90 nm.

Note that, for an overlying layer of the actinic ray-sensitive or radiation-sensitive film, a topcoat composition may be used to form a topcoat.

The topcoat composition preferably does not mix with the actinic ray-sensitive or radiation-sensitive film, and can be uniformly applied for an overlying layer of the actinic ray-sensitive or radiation-sensitive film. The topcoat is not particularly limited; a publicly known topcoat can be formed by a publicly known process; for example, on the basis of descriptions of Paragraphs [0072] to [0082] in JP2014-059543A, a topcoat can be formed.

For example, a topcoat including a basic compound and described in JP2013-61648A is preferably formed on the actinic ray-sensitive or radiation-sensitive film. Specific examples of the basic compound that can be included in the topcoat include basic compounds that may be included in the resist composition.

The topcoat also preferably includes a compound including at least one group or bond selected from the group consisting of an ether bond, a thioether bond, a hydroxy group, a thiol group, a carbonyl bond, and an ester bond.

### Step 2: Exposure Step

The step 2 is a step of exposing the actinic ray-sensitive or radiation-sensitive film.

The exposure process may be a process of irradiating the formed actinic ray-sensitive or radiation-sensitive film, through a predetermined mask, with an actinic ray or a radiation.

Examples of the actinic ray or the radiation include infrared light, visible light, ultraviolet light, far-ultraviolet light, extreme ultraviolet light, X-rays, and an electron beam; preferred is 250 nm or less, more preferred is 220 nm or less, and particularly preferred are far-ultraviolet light having a wavelength of 1 to 200 nm and specifically KrF excimer laser (248 nm), ArF excimer laser (193 nm), F₂ excimer laser (157 nm), EUV (13.5 nm), X-rays, and an electron beam.

After the exposure, before development, baking (heating) is preferably performed. The baking accelerates the reaction in the exposed regions, to provide higher sensitivity and a better pattern profile.

The heating temperature is preferably 80 to 150° C., more preferably 80 to 140° C., and still more preferably 80 to 130° C.

The heating time is preferably 10 to 1000 seconds, more preferably 10 to 180 seconds, and still more preferably 30 to 120 seconds.

The heating can be performed using means included in an ordinary exposure device and/or an ordinary development device, and may alternatively be performed using a hot plate, for example.

This step is also referred to as post-exposure baking.

### Step 3: Development Step

The step 3 is a step of using a developer to develop the exposed actinic ray-sensitive or radiation-sensitive film, to form a pattern.

The developer may be an alkali developer or may be a developer containing an organic solvent (hereafter, also referred to as organic-based developer).

Examples of the development process include a process of immersing, for a predetermined time, the substrate in a tank filled with the developer (dipping process), a process of puddling, with the developer, the surface of the substrate using surface tension and leaving the developer at rest for a predetermined time to achieve development (puddling process), a process of spraying the developer to the surface of the substrate (spraying process), and a process of scanning, at a constant rate, over the substrate rotated at a constant rate, a developer ejection nozzle to continuously eject the developer (dynamic dispensing process).

After the step of performing development, a step of performing exchange with another solvent to stop the development may be performed.

The development time is not particularly limited as long as the resin in the unexposed regions is sufficiently dissolved in the time, and is preferably 10 to 300 seconds, and more preferably 20 to 120 seconds.

The temperature of the developer is preferably 0 to 50° C., and more preferably 15 to 35° C.

The alkali developer employed is preferably an alkali aqueous solution including an alkali. The type of the alkali aqueous solution is not particularly limited, but may be, for example, an alkali aqueous solution including a quaternary ammonium salt represented by tetramethylammonium hydroxide, an inorganic alkali, a primary amine, a secondary amine, a tertiary amine, an alcoholamine, a cyclic amine, or the like. In particular, the alkali developer is preferably an aqueous solution of a quaternary ammonium salt represented by tetramethylammonium hydroxide (TMAH). To the alkali developer, an appropriate amount of an alcohol, a surfactant, or the like may be added. The alkali developer ordinarily preferably has an alkali concentration of 0.1 to 20 mass %. The alkali developer ordinarily preferably has a pH of 10.0 to 15.0.

The organic-based developer is preferably a developer containing at least one organic solvent selected from the group consisting of ketone-based solvents, ester-based solvents, alcohol-based solvents, amide-based solvents, ether-based solvents, and hydrocarbon-based solvents.

A plurality of such solvents may be mixed together, or such a solvent may be mixed with a solvent other than those described above or water. The developer as a whole has a moisture content of preferably less than 50 mass %, more preferably less than 20 mass %, still more preferably less than 10 mass %, and particularly preferably contains substantially no moisture.

In the organic-based developer, the content of the organic solvent relative to the total amount of the developer is preferably 50 mass % or more and 100 mass % or less, more preferably 80 mass % or more and 100 mass % or less, still more preferably 90 mass % or more and 100 mass % or less, and particularly preferably 95 mass % or more and 100 mass % or less.

### Other Step

The pattern forming method preferably includes a step of, after the step 3, using a rinse liquid to perform rinsing.

After the development step using an alkali developer, in the rinsing step, the rinse liquid employed may be, for example, pure water. Note that, to the pure water, an appropriate amount of surfactant may be added.

To the rinse liquid, an appropriate amount of surfactant may be added.

After the development step using an organic-based developer, in the rinsing step, the rinse liquid employed is not particularly limited as long as it does not dissolve the pattern, and may be a solution including an ordinary organic solvent. The rinse liquid employed is preferably a rinse liquid containing at least one organic solvent selected from the group consisting of hydrocarbon-based solvents, ketone-based solvents, ester-based solvents, alcohol-based solvents, amide-based solvents, and ether-based solvents.

The process of performing the rinsing step is not particularly limited; examples include a process of continuously ejecting, onto the substrate rotated at a constant rate, the rinse liquid (spin-coating process), a process of immersing, in a tank filled with the rinse liquid, the substrate for a predetermined time (dipping process), and a process of spraying, to the surface of the substrate, the rinse liquid (spraying process).

The pattern forming method may include a heating step (Post Bake) performed after the rinsing step. In this step, baking removes the developer and the rinse liquid remaining between and within the patterns. In addition, this step also provides an effect of annealing the resist pattern to address the rough surface of the pattern. The heating step after the rinsing step is performed ordinarily at 40 to 250° C. (preferably 90 to 200° C.) for ordinarily 10 seconds to 3 minutes (preferably 30 seconds to 120 seconds).

The formed pattern may be used as a mask for subjecting the substrate to etching treatment. Specifically, the pattern formed in the step 3 may be used as a mask for processing the substrate (or the underlayer film and the substrate), to form a pattern in the substrate.

The process of processing the substrate (or the underlayer film and the substrate) is not particularly limited, but is preferably a process of using the pattern formed in the step 3 as a mask for subjecting the substrate (or the underlayer film and the substrate) to dry etching, to thereby form a pattern in the substrate. The dry etching is preferably oxygen plasma etching.

Various materials used in the composition of this Specification and the pattern forming method of this Specification (for example, a solvent, a developer, a rinse liquid, an antireflection film-forming composition, and a topcoat-forming composition) preferably do not include impurities such as metals. The content of impurities included in such materials is preferably 1 mass ppm or less, more preferably 10 mass ppb or less, still more preferably 100 mass ppt or less, particularly preferably 10 mass ppt or less, and most preferably 1 mass ppt or less. The lower limit is not particularly limited, but is preferably 0 mass ppt or more. Examples of the metallic impurities include Na, K, Ca, Fe, Cu, Mg, Al, Li, Cr, Ni, Sn, Ag, As, Au, Ba, Cd, Co, Pb, Ti, V, W, and Zn.

The process of removing, from the various materials, impurities such as metals may be, for example, filtration using a filter. The details of filtration using a filter are described in Paragraph [0321] in WO2020/004306A.

Examples of the process of reducing the amount of impurities such as metals included in the various materials include a process of selecting, as raw materials constituting the various materials, raw materials having lower metal content, a process of subjecting raw materials constituting the various materials to filtration using a filter, and a process of performing distillation under conditions under which contamination is minimized by, for example, lining the interior of the apparatuses with TEFLON (registered trademark).

Instead of the filtration using a filter, an adsorption material may be used to remove impurities; alternatively, the filtration using a filter may be used in combination with an adsorption material. Such adsorption materials can be publicly known adsorption materials, and examples include inorganic-based adsorption materials such as silica gel and zeolite, and organic-based adsorption materials such as active carbon. In order to reduce the amount of impurities such as metals included in the various materials, ingress of metallic impurities in the production steps needs to be prevented. Whether or not metallic impurities are sufficiently removed from the production apparatuses can be determined by measuring the content of metallic components included in the washing liquid having been used for washing the production apparatuses. The content of metallic components included in the washing liquid having been used is preferably 100 mass ppt (parts per trillion) or less, more preferably 10 mass ppt or less, and still more preferably 1 mass ppt or less. The lower limit is not particularly limited, but is preferably 0 mass ppt or more.

To organic-based treatment liquids such as the rinse liquid, in order to prevent electrostatic buildup and the subsequent electrostatic discharge causing failure of the chemical solution pipe and various parts (such as a filter, an O-ring, and a tube), a conductive compound may be added. The conductive compound is not particularly limited, but may be, for example, methanol. The amount of addition is not particularly limited, but is, from the viewpoint of maintaining preferred development performance or rinsing performance, preferably 10 mass % or less, and more preferably 5 mass % or less. The lower limit is not particularly limited, but is preferably 0.01 mass % or more.

Examples of the chemical solution pipe include various pipes formed of SUS (stainless steel), or coated with polyethylene, polypropylene, or a fluororesin (such as polytetrafluoroethylene or a perfluoroalkoxy resin) treated so as to be antistatic. Similarly for the filter and the O-ring, polyethylene, polypropylene, or a fluororesin (such as polytetrafluoroethylene or a perfluoroalkoxy resin) treated so as to be antistatic can be used.

### Method for Producing Electronic Device

This Specification also relates to a method for producing an electronic device, the method including the above-described pattern forming method, and an electronic device produced by the production method.

The electronic device in this Specification is, in a preferred embodiment, mounted on electric or electronic devices (such as household appliances, OA (Office Automation), media-related devices, optical devices, and communication devices).

### EXAMPLES

Hereinafter, the present invention will be described further in detail with reference to Examples. In the following Examples, materials, usage amounts, ratios, details of treatments, orders of treatments, and the like can be appropriately changed without departing from the spirit and scope of the present invention. Thus, the scope of the present invention should not be construed as being limited to the following Examples.

### Various Components of Actinic Ray-Sensitive or Radiation-Sensitive Resin Composition Resin (A)

The resin (A) (resins A-1 to A-61 and A-1R to A-5R) described in Table 3 will be described below.

For the resin (A), resins synthesized in accordance with a method for synthesizing a resin A-1 (Synthesis Example 1) described later were used.

The resin (A) including a part of the repeating units having a phenolic hydroxyl group (using M-b-2 to M-b-5, M-b-15, M-b-17, M-b-22 to M-b-25, and M-b-28 as corresponding monomers) was synthesized in accordance with the synthesis methods (Synthesis Examples 2 to 4) of resins A-2 to A-4 using precursors in which the phenolic hydroxyl group was protected.

As precursors of M-b-3 to M-b-5, M-b-15, M-b-17, M-b-22 to M-b-25, and M-b-28, M-b-3-i to M-b-5-i, M-b-15-i, M-b-17-i, M-b-22-i to M-b-25-i, and M-b-28-i were used. As the precursor of M-b-2, M-b-2-i or M-b-2-ii was used.

Table 1 describes the compositional ratio (mol % ratio), weight-average molecular weight (Mw), and dispersity (Mw/Mn) of each repeating unit described later. Note that, for the resins A-1 to A-61 and A-1R to A-5R, the weight-average molecular weight (Mw) and the dispersity (Mw/Mn) were measured by GPC (carrier: tetrahydrofuran (THF)) (polystyrene-equivalent amounts). The compositional ratios (mol % ratios) of the resins were measured by ¹³C-NMR (nuclear magnetic resonance).

TABLE 1

| | Repeating unit 1 | | Repeating unit 2 | | Repeating unit 3 | | Repeating unit 4 | | Repeating unit 5 | | | |
|---|---|---|---|---|---|---|---|---|---|---|---|---|
| Table 1 | Type | Molar ratio | Type | Molar ratio | Type | Molar ratio | Type | Molar ratio | Type | Molar ratio | Mw | Mw/Mn |
| Resin A-1 | M-1 | 30 | M-a-1 | 40 | — | — | M-b-1 | 30 | — | — | 6500 | 1.60 |
| Resin A-2 | M-1 | 20 | M-a-1 | 20 | — | — | M-b-2 | 60 | — | — | 7200 | 1.59 |
| Resin A-3 | M-1 | 20 | M-a-3 | 25 | — | — | M-b-2 | 55 | — | — | 7000 | 1.58 |
| Resin A-4 | M-1 | 40 | M-a-2 | 30 | — | — | M-b-15 | 30 | — | — | 7500 | 1.55 |
| Resin A-5 | M-2 | 15 | M-a-4 | 45 | — | — | M-b-3 | 30 | M-d-1 | 10 | 8500 | 1.59 |
| Resin A-6 | M-3 | 20 | M-a-5 | 35 | — | — | M-b-4 | 35 | M-d-2 | 10 | 5500 | 1.68 |
| Resin A-7 | M-4 | 30 | M-a-6 | 30 | — | — | M-b-5 | 30 | M-d-3 | 10 | 4500 | 1.77 |
| Resin A-8 | M-5 | 20 | M-a-7 | 20 | — | — | M-b-6 | 45 | M-d-4 | 15 | 12000 | 1.84 |
| Resin A-9 | M-6 | 25 | M-a-8 | 38 | — | — | M-b-7 | 25 | M-d-5 | 12 | 14000 | 1.65 |
| Resin A-10 | M-7 | 43 | M-a-9 | 22 | — | — | M-b-8 | 23 | M-d-6 | 12 | 8800 | 1.55 |
| Resin A-11 | M-8 | 25 | M-a-10 | 40 | — | — | M-b-9 | 23 | M-d-7 | 12 | 22000 | 1.56 |
| Resin A-12 | M-9 | 38 | M-a-11 | 34 | — | — | M-b-10 | 13 | M-d-8 | 15 | 14000 | 1.65 |
| Resin A-13 | M-10 | 30 | M-a-12 | 8 | — | — | M-b-11 | 52 | M-1-9 | 10 | 6500 | 1.40 |
| Resin A-14 | M-11 | 40 | M-a-13 | 15 | — | — | M-b-12 | 35 | M-d-10 | 10 | 6700 | 1.50 |
| Resin A-15 | M-12 | 10 | M-a-14 | 25 | — | — | M-b-13 | 45 | M-d-11 | 20 | 7200 | 1.54 |
| Resin A-16 | M-13 | 15 | M-a-15 | 50 | — | — | M-b-14 | 30 | M-d-12 | 5 | 8000 | 1.29 |
| Resin A-17 | M-1 | 30 | M-a-16 | 20 | — | — | M-b-15 | 45 | M-d-13 | 5 | 4500 | 1.35 |
| Resin A-18 | M-1 | 50 | M-a-17 | 10 | — | — | M-b-16 | 20 | M-d-14 | 10 | 5000 | 1.25 |
| Resin A-19 | M-1 | 25 | M-a-18 | 30 | M-c-2 | 5 | M-b-17 | 30 | M-d-15 | 10 | 5500 | 1.50 |
| Resin A-20 | M-1 | 20 | M-a-19 | 30 | M-c-3 | 10 | M-b-18 | 30 | M-d-16 | 10 | 5600 | 1.60 |
| Resin A-21 | M-1 | 13 | M-a-20 | 27 | M-c-1 | 20 | M-b-19 | 30 | M-d-17 | 10 | 7800 | 1.56 |
| Resin A-22 | M-1 | 20 | M-a-21 | 31 | M-c-5 | 20 | M-b-20 | 19 | M-d-18 | 10 | 9000 | 1.54 |
| Resin A-23 | M-1 | 15 | M-a-22 | 29 | M-c-6 | 5 | M-b-21 | 41 | M-d-19 | 10 | 8000 | 1.74 |
| Resin A-24 | M-1 | 20 | M-a-23 | 20 | M-c-7 | 10 | M-b-22 | 40 | M-d-20 | 10 | 7500 | 1.55 |
| Resin A-25 | M-1 | 25 | M-a-24 | 11 | M-c-8 | 10 | M-b-23 | 54 | — | — | 8600 | 1.72 |
| Resin A-26 | M-1 | 30 | M-a-25 | 31 | M-c-4 | 5 | M-b-24 | 34 | — | — | 12500 | 1.80 |
| Resin A-27 | M-1 | 20 | M-a-26 | 20 | — | — | M-b-25 | 60 | — | — | 5500 | 1.33 |
| Resin A-28 | M-1 | 25 | M-a-27 | 20 | M-c-1 | 10 | M-b-26 | 45 | — | — | 4500 | 1.40 |
| Resin A-29 | M-1 | 30 | M-a-28 | 15 | — | — | M-b-27 | 55 | — | — | 6500 | 1.55 |
| Resin A-30 | M-1 | 40 | M-a-1 | 5 | M-c-1 | 10 | M-b-28 | 45 | — | — | 6000 | 1.65 |
| Resin A-31 | M-1 | 40 | M-a-1 | 10 | M-a-12 | 10 | M-b-2 | 40 | — | — | 5900 | 1.56 |
| Resin A-32 | M-1 | 37 | M-a-1 | 10 | M-a-5 | 10 | M-b-2 | 43 | — | — | 8900 | 1.55 |
| Resin A-33 | M-1 | 20 | M-a-1 | 10 | M-a-14 | 20 | M-b-2 | 50 | — | — | 12000 | 1.65 |
| Resin A-34 | M-1 | 15 | M-a-1 | 27 | — | — | M-b-2 | 58 | — | — | 8000 | 1.55 |
| Resin A-35 | M-1 | 13 | M-a-1 | 21 | — | — | M-b-2 | 66 | — | — | 14000 | 1.56 |

TABLE 2

| Table 1 | Repeating unit 1 | | Repeating unit 2 | | Repeating unit 3 | | Repeating unit 4 | | Repeating unit 5 | | | |
|---|---|---|---|---|---|---|---|---|---|---|---|---|
| (continued) | Type | Molar ratio | Type | Molar ratio | Type | Molar ratio | Type | Molar ratio | Type | Molar ratio | Mw | Mw/Mn |
| Resin A-36 | M-1 | 35 | M-a-1 | 15 | — | — | M-b-2 | 50 | — | — | 12000 | 1.65 |
| Resin A-37 | M-1 | 20 | M-a-1 | 30 | — | — | M-b-2 | 50 | — | — | 8000 | 1.40 |
| Resin A-38 | M-1 | 55 | M-a-1 | 10 | — | — | M-b-3 | 20 | M-d-8 | 15 | 6500 | 1.54 |
| Resin A-39 | M-1 | 57 | M-a-1 | 15 | — | — | M-b-3 | 18 | M-d-9 | 10 | 5500 | 1.29 |
| Resin A-40 | M-1 | 44 | M-a-2 | 10 | — | — | M-b-2 | 46 | — | — | 4000 | 1.35 |
| Resin A-41 | M-1 | 44 | M-a-2 | 10 | M-a-12 | 11 | M-b-3 | 35 | — | — | 8800 | 1.25 |
| Resin A-42 | M-1 | 42 | M-a-3 | 15 | — | — | M-b-2 | 33 | M-d-1 | 10 | 10000 | 1.50 |
| Resin A-43 | M-1 | 24 | M-a-3 | 25 | — | — | M-b-2 | 51 | — | — | 7100 | 1.67 |
| Resin A-44 | M-1 | 40 | M-a-3 | 30 | M-a-12 | 5 | M-b-3 | 25 | — | — | 6600 | 1.65 |
| Resin A-45 | M-1 | 35 | M-a-3 | 25 | M-a-12 | 10 | M-b-15 | 30 | — | — | 12200 | 1.55 |
| Resin A-46 | M-1 | 17 | M-a-5 | 35 | — | — | M-b-2 | 48 | — | — | 7700 | 1.56 |
| Resin A-47 | M-2 | 40 | M-a-1 | 16 | — | — | M-b-2 | 44 | — | — | 5700 | 1.65 |
| Resin A-48 | M-2 | 40 | M-a-1 | 15 | — | — | M-b-2 | 35 | M-d-18 | 10 | 3400 | 1.40 |
| Resin A-49 | M-2 | 44 | M-a-1 | 20 | — | — | M-b-3 | 36 | — | — | 4300 | 1.54 |
| Resin A-50 | M-2 | 19 | M-a-1 | 20 | M-a-10 | 6 | M-b-15 | 55 | — | — | 7500 | 1.59 |
| Resin A-51 | M-2 | 21 | M-a-2 | 22 | M-a-12 | 6 | M-b-19 | 41 | M-d-1 | 10 | 5800 | 1.53 |
| Resin A-52 | M-2 | 20 | M-a-2 | 40 | — | — | M-b-2 | 40 | — | — | 5800 | 1.55 |
| Resin A-53 | M-2 | 10 | M-a-2 | 50 | — | — | M-b-2 | 40 | — | — | 7400 | 1.50 |
| Resin A-54 | M-2 | 20 | M-a-2 | 30 | — | — | M-b-3 | 40 | M-d-18 | 10 | 6900 | 1.60 |
| Resin A-55 | M-2 | 25 | M-a-3 | 50 | — | — | M-b-3 | 25 | — | — | 8500 | 1.55 |
| Resin A-56 | M-2 | 15 | M-a-3 | 40 | M-a-14 | 16 | M-b-15 | 35 | — | — | 6500 | 1.55 |
| Resin A-57 | M-2 | 20 | M-a-3 | 20 | M-a-12 | 10 | M-b-19 | 50 | — | — | 5500 | 1.55 |
| Resin A-58 | M-2 | 18 | M-a-4 | 30 | M-a-10 | 7 | M-b-19 | 35 | M-d-1 | 10 | 4000 | 1.55 |
| Resin A-59 | M-2 | 16 | M-a-5 | 25 | — | — | M-b-2 | 59 | — | — | 8800 | 1.55 |
| Resin A-60 | M-2 | 50 | M-a-5 | 20 | — | — | M-b-15 | 30 | — | — | 10000 | 1.55 |
| Resin A-61 | M-2 | 48 | M-a-5 | 20 | — | — | M-b-21 | 32 | — | — | 7100 | 1.55 |
| Resin A-1R | M-1 | 30 | M-a-2 | 20 | — | — | M-b-2 | 30 | M-b-7 | 20 | 6100 | 1.27 |
| Resin A-2R | M-1 | 20 | M-a-12 | 15 | — | — | M-b-2 | 55 | M-e-1 | 10 | 7500 | 1.74 |
| Resin A-3R | M-1 | 50 | — | — | — | — | M-b-1 | 50 | — | — | 6500 | 1.60 |
| Resin A-4R | — | — | M-a-1 | 50 | — | — | M-b-1 | 50 | — | — | 6500 | 1.60 |
| Resin A-5R | M-1 | 22 | M-c-2 | 12 | — | — | M-b-2 | 66 | — | — | 13000 | 1.60 |

The structures of M-1 to M-13, M-a-1 to M-a-28, M-b-1 to M-b-28, M-c-1 to M-c-8, M-d-1 to M-d-20, and M-e-1 to M-e-2, which are monomers corresponding to the repeating units described in Table 1, and the structures of M-b-2-i, M-b-2-ii, M-b-3-i to M-b-5-i, M-b-15-i, M-b-17-i, M-b-22-i to M-b-25-i, and M-b-28-i, which are precursors of M-b-2 to M-b-5, M-b-15, M-b-17, M-b-22 to M-b-25, and M-b-28, will be described below.

The number described in the structure of M-e-1 represents the pKa of the “—SO₂—N⁻—” moiety. The measurement method is as described above.

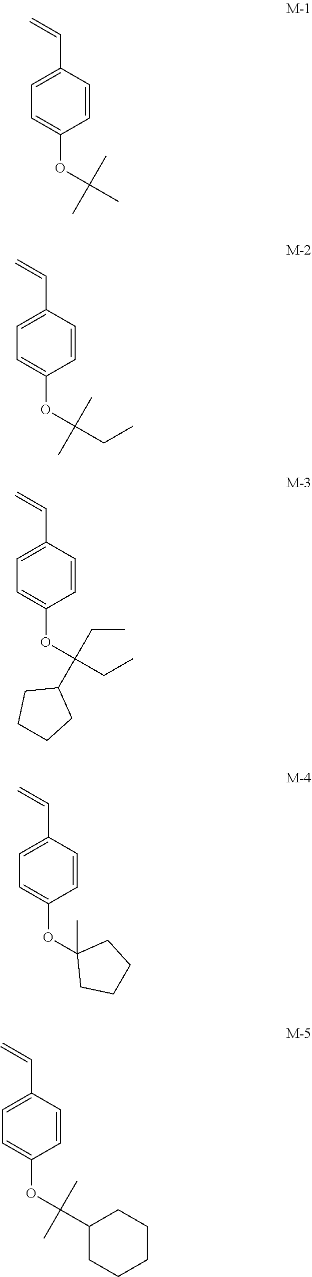 [SMILES: C=Cc1ccc(OC(C)(C)C)cc1 ; C=Cc1ccc(OC(C)(C)CC)cc1 ; C=Cc1ccc(OC(CC)(CC)C2CCCC2)cc1 ; C=Cc1ccc(OC2(C)CCCC2)cc1 ; C=Cc1ccc(OC(C)(C)C2CCCCC2)cc1]

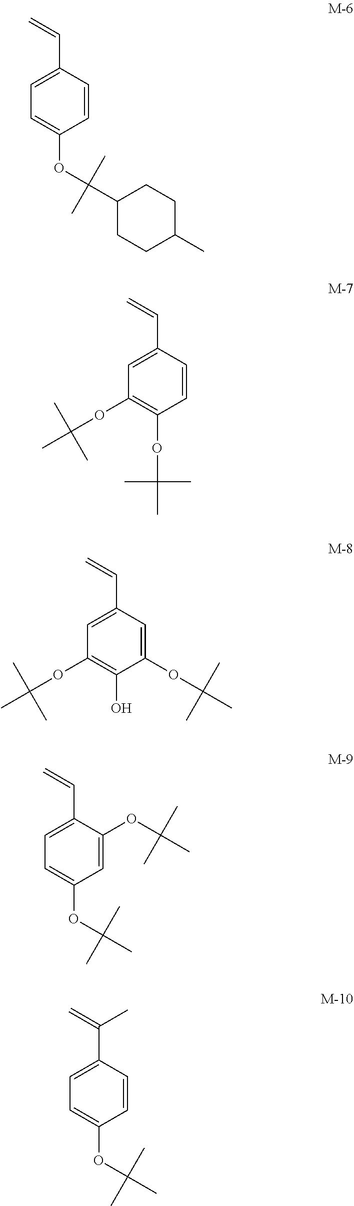

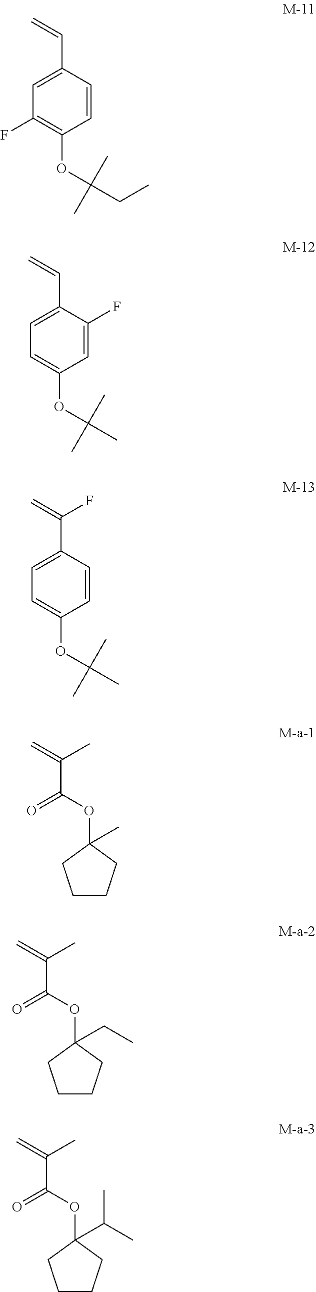

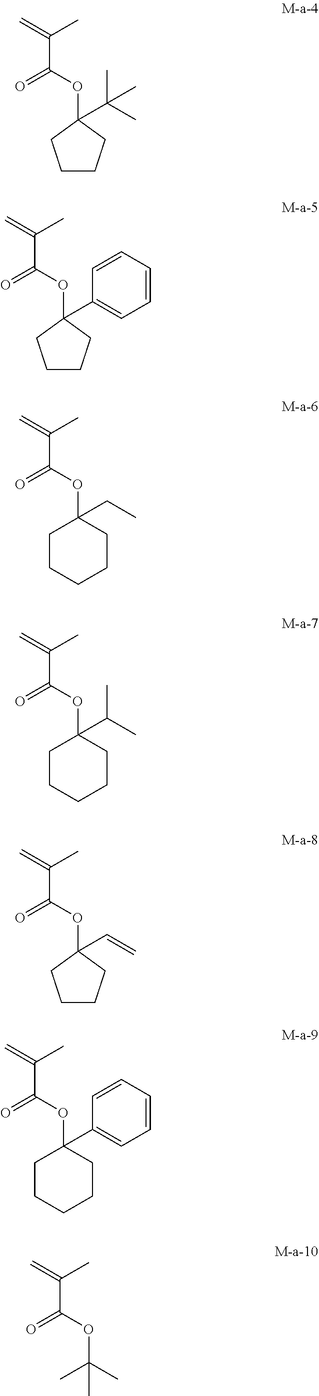

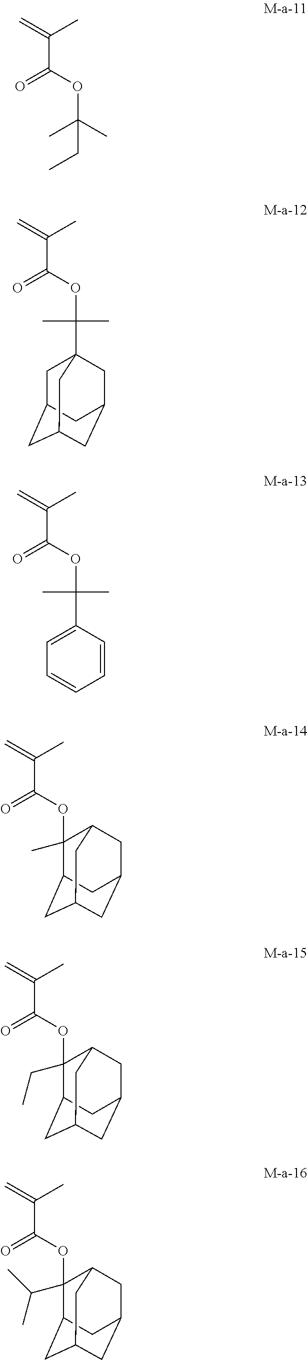 [SMILES: C=C(C)C(=O)OC(C)(C)CC ; C=C(C)C(=O)OC(C)(C)C12CC3CC(CC(C3)C1)C2 ; C=C(C)C(=O)OC(C)(C)c1ccccc1 ; C=C(C)C(=O)OC1(C)C2CC3CC(C2)CC1C3 ; C=C(C)C(=O)OC1(CC)C2CC3CC(C2)CC1C3 ; C=C(C)C(=O)OC1(C(C)C)C2CC3CC(C2)CC1C3]

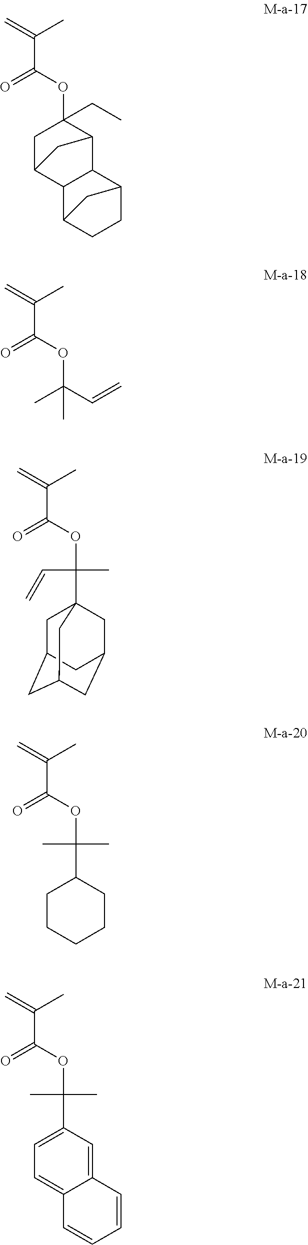 [SMILES: C=C(C)C(=O)OC1(CC)CC2CC1C1C3CCC(C3)C21 ; C=CC(C)(C)OC(=O)C(=C)C ; C=CC(C)(OC(=O)C(=C)C)C12CC3CC(CC(C3)C1)C2 ; C=C(C)C(=O)OC(C)(C)C1CCCCC1 ; C=C(C)C(=O)OC(C)(C)c1ccc2ccccc2c1]

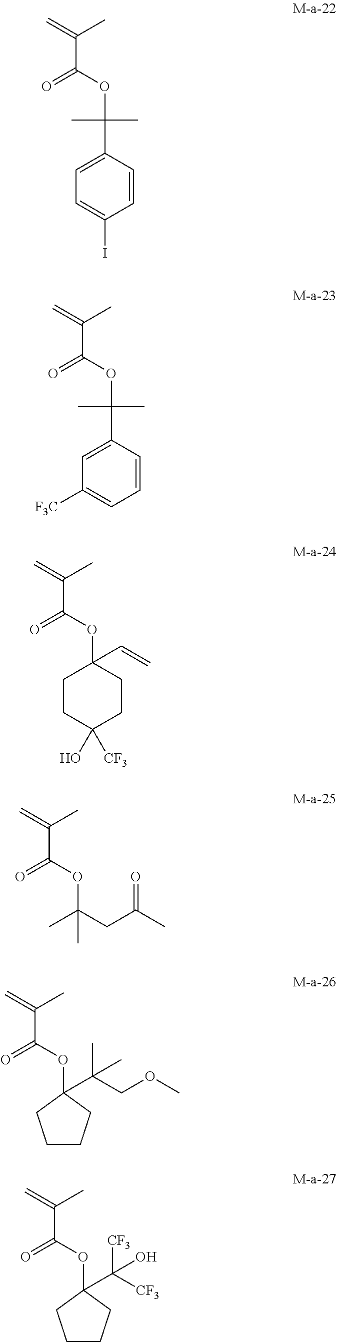

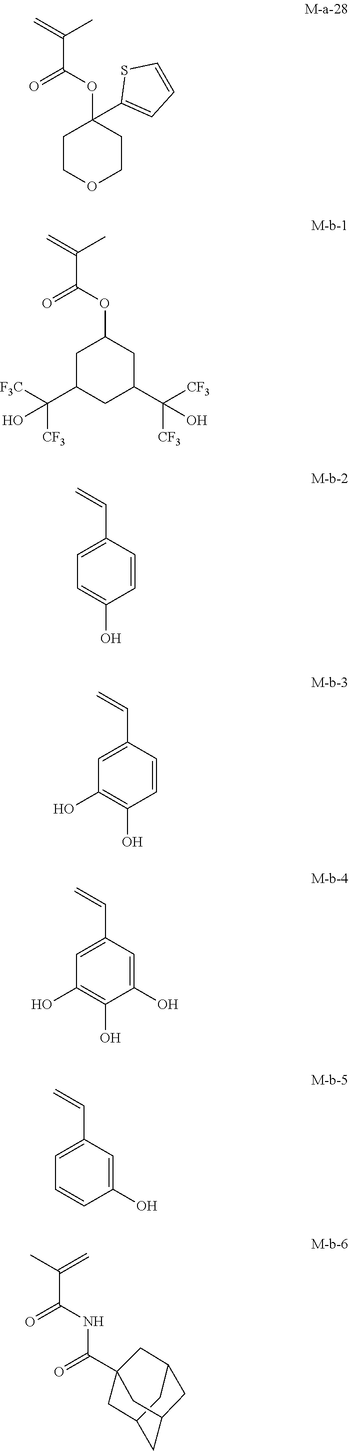

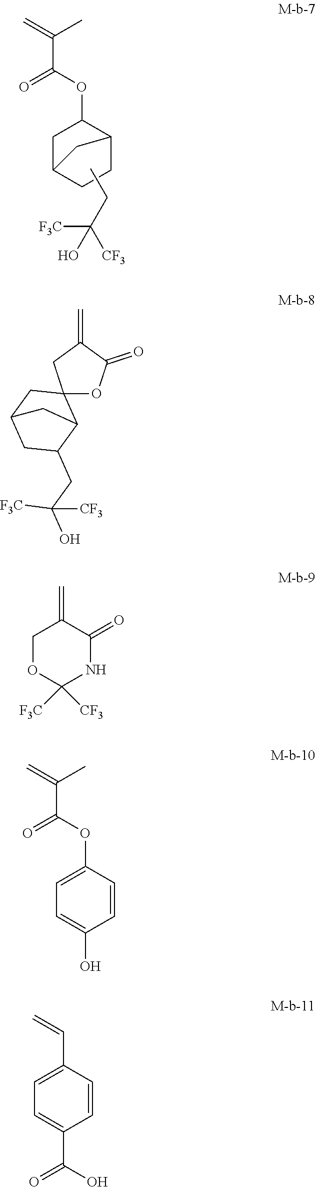

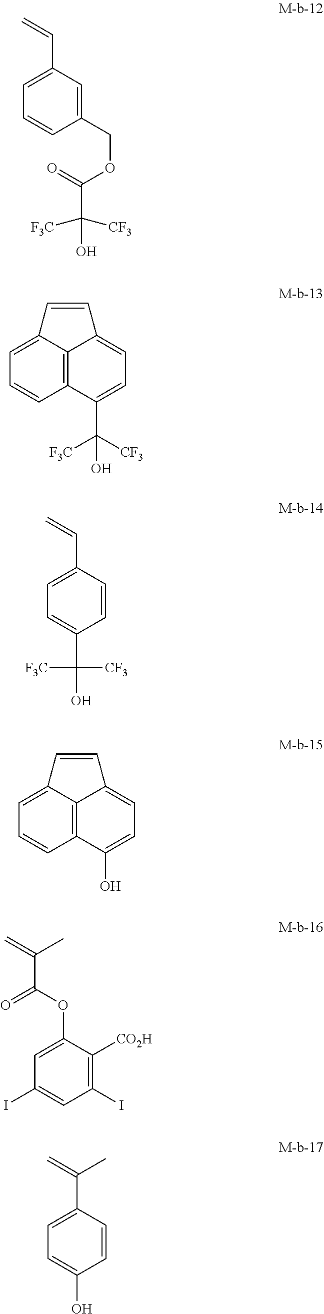

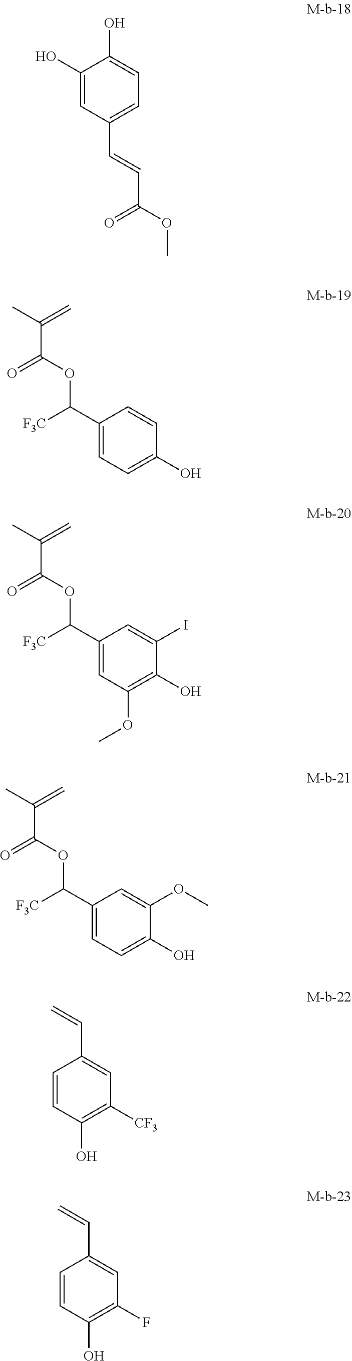

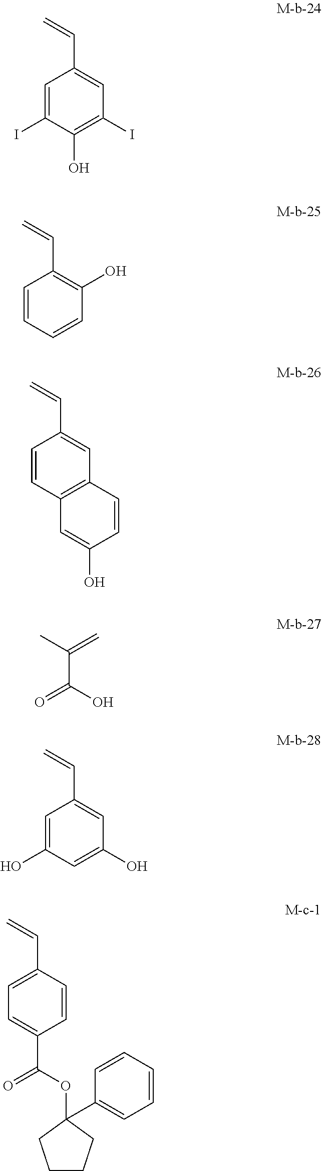

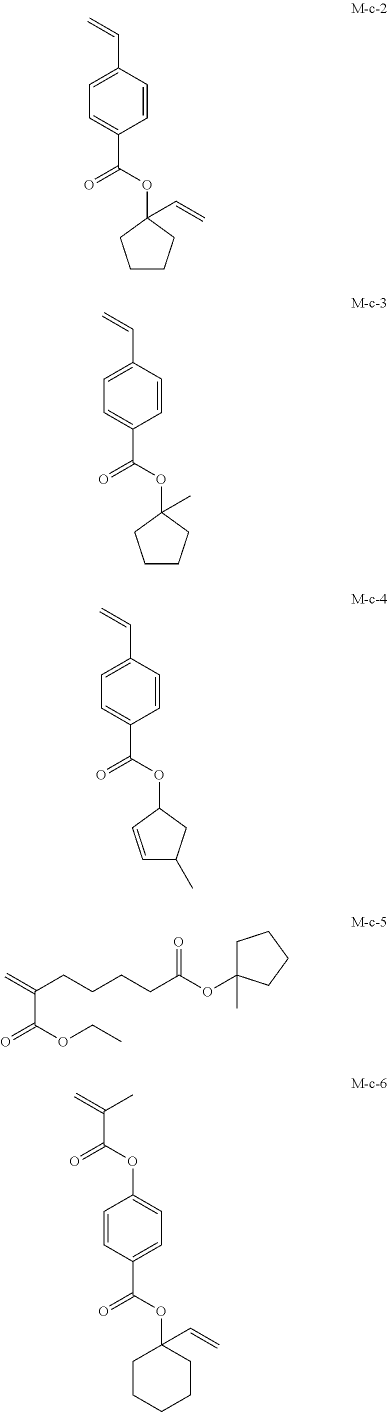 [SMILES: C=Cc1ccc(C(=O)OC2(C=C)CCCC2)cc1 ; C=Cc1ccc(C(=O)OC2(C)CCCC2)cc1 ; C=Cc1ccc(C(=O)OC2C=CC(C)C2)cc1 ; C=C(CCCCC(=O)OC1(C)CCCC1)C(=O)OCC ; C=CC1(OC(=O)c2ccc(OC(=O)C(=C)C)cc2)CCCCC1]

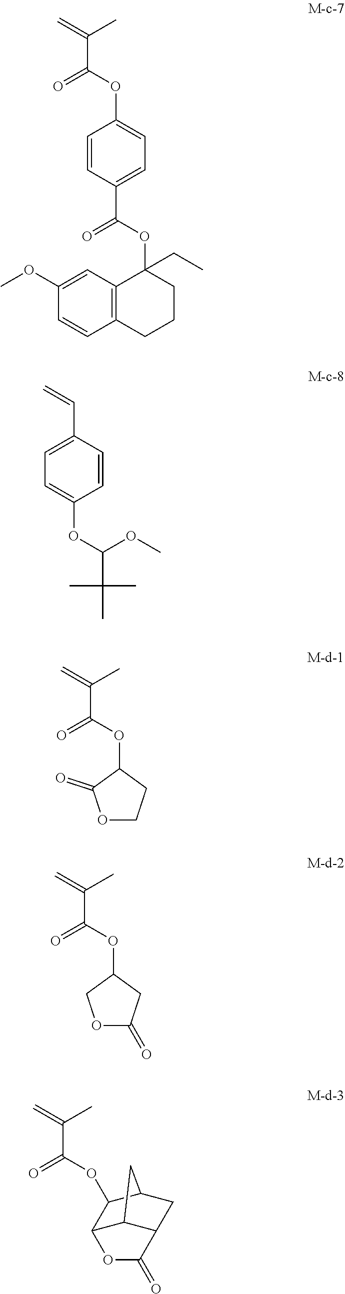 [SMILES: C=C(C)C(=O)Oc1ccc(C(=O)OC2(CC)CCCc3ccc(OC)cc32)cc1 ; C=Cc1ccc(OC(OC)C(C)(C)C)cc1 ; C=C(C)C(=O)OC1CCOC1=O ; C=C(C)C(=O)OC1COC(=O)C1 ; C=C(C)C(=O)OC1C2CC3C(=O)OC1C3C2]

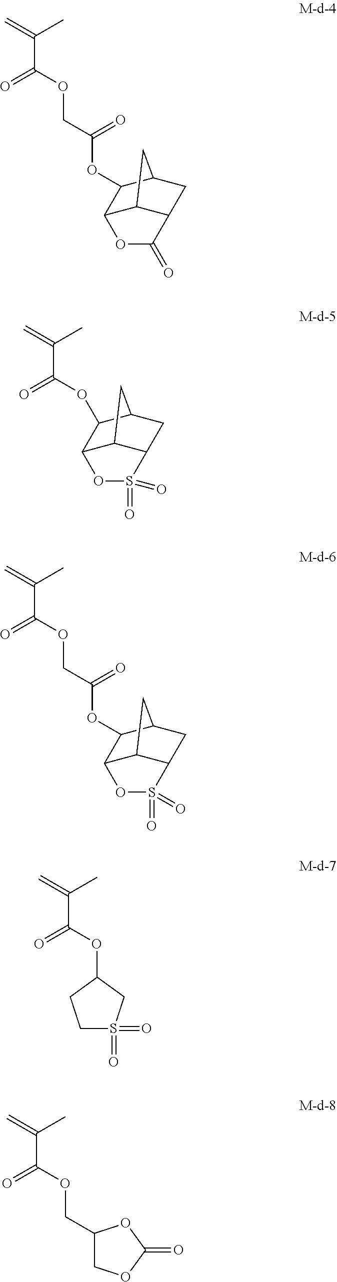 [SMILES: C=C(C)C(=O)OCC(=O)OC1C2CC3C(=O)OC1C3C2 ; C=C(C)C(=O)OC1C2CC3C1OS(=O)(=O)C3C2 ; C=C(C)C(=O)OCC(=O)OC1C2CC3C1OS(=O)(=O)C3C2 ; C=C(C)C(=O)OC1CCS(=O)(=O)C1 ; C=C(C)C(=O)OCC1COC(=O)O1]

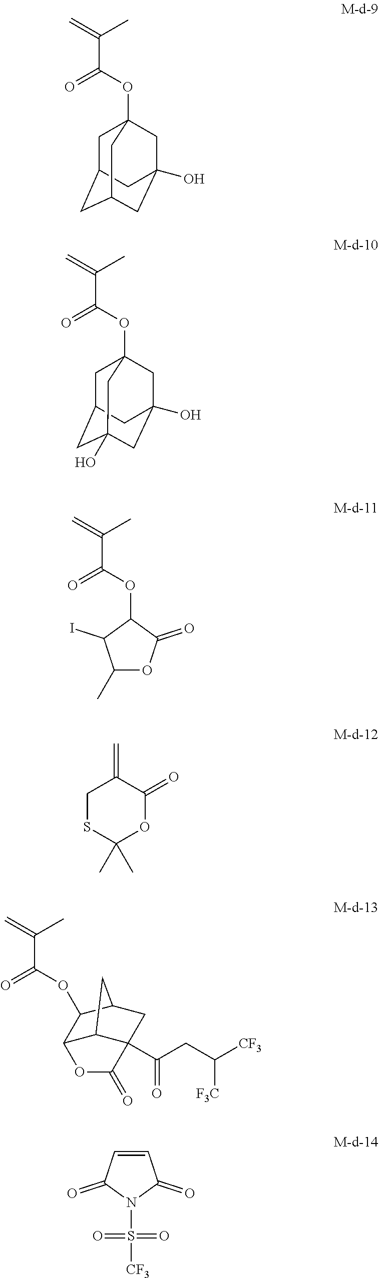

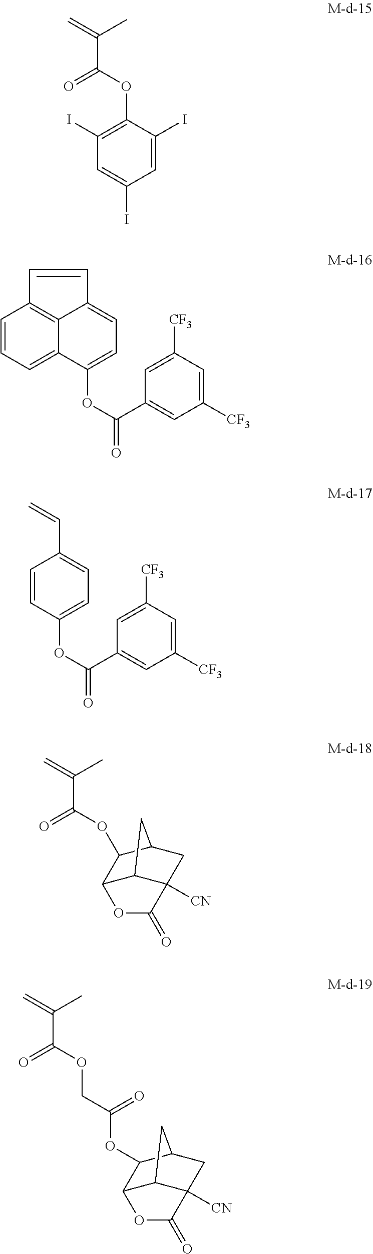 [SMILES: C=C(C)C(=O)Oc1c(I)cc(I)cc1I ; O=C(Oc1ccc2c3c(cccc13)C=C2)c1cc(C(F)(F)F)cc(C(F)(F)F)c1 ; C=Cc1ccc(OC(=O)c2cc(C(F)(F)F)cc(C(F)(F)F)c2)cc1 ; C=C(C)C(=O)OC1C2CC3C1OC(=O)C3(C#N)C2 ; C=C(C)C(=O)OCC(=O)OC1C2CC3C1OC(=O)C3(C#N)C2]

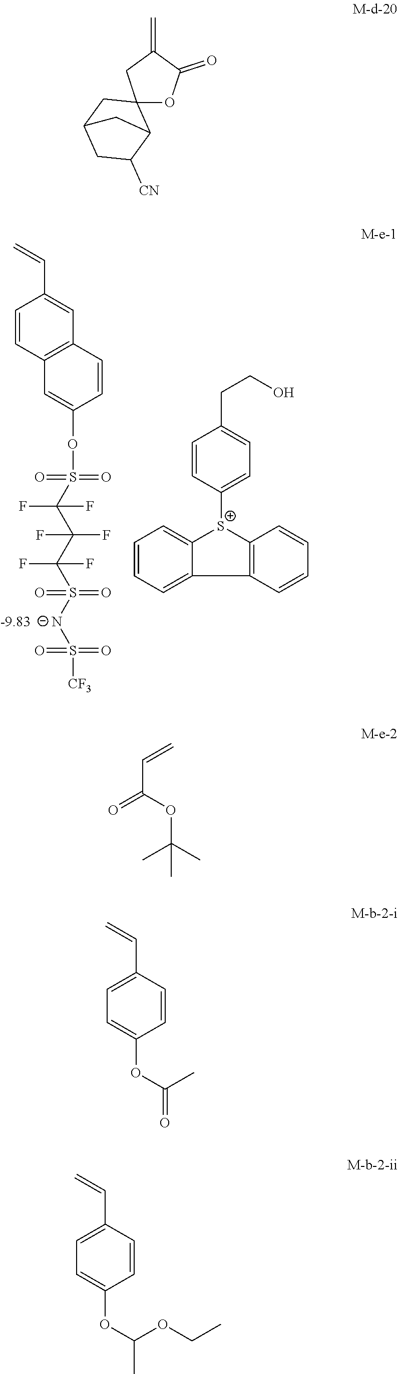

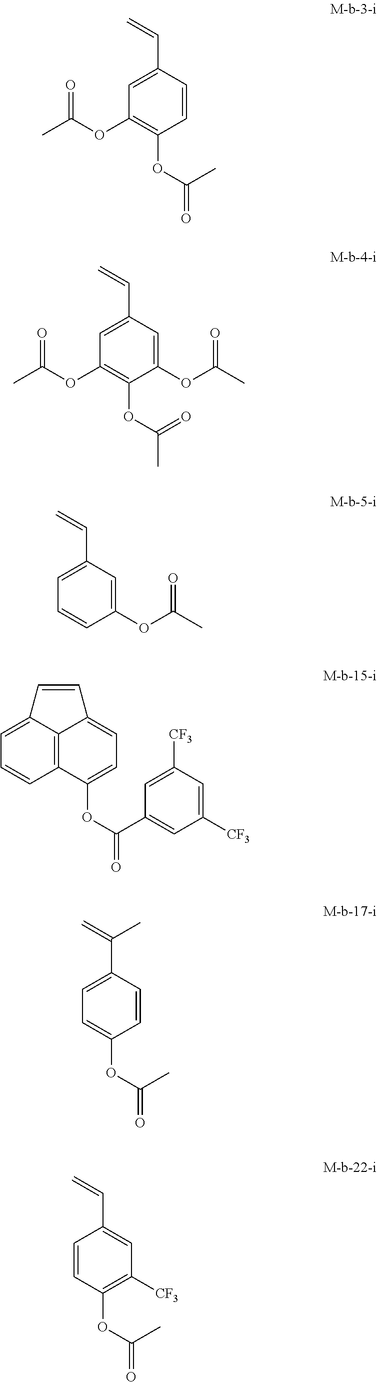

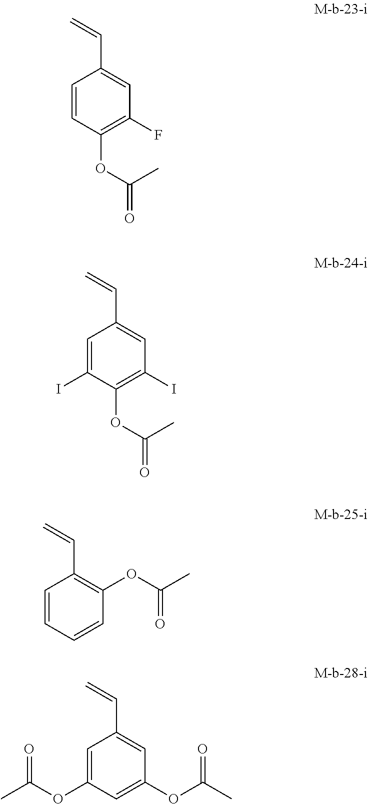

### Synthesis Example 1: Synthesis of Resin (A-1)

Cyclohexanone (41 g) was heated to 85° C. under a nitrogen stream. To this liquid, a mixed solution of cyclohexanone (7 g) and dimethyl 2,2′-azobisisobutyrate [V-601, manufactured by Wako Pure Chemical Industries, Ltd.] (0.7 g) was added and stirred for 5 minutes. To this liquid under stirring, a mixed solution of a monomer (19.5 g) represented by a formula M-1 below, a monomer (25 g) represented by a formula M-a-1 below, a monomer (55.5 g) represented by a formula M-b-1 below, cyclohexanone (187 g), and dimethyl 2,2′-azobisisobutyrate [V-601, manufactured by Wako Pure Chemical Industries, Ltd.] (6.9 g) was added dropwise over 6 hours, to obtain a reaction solution. After completion of the dropwise addition, the reaction solution was further stirred at 85° C. for 2 hours. The obtained reaction solution was left to cool, subsequently diluted with 167 g of ethyl acetate, reprecipitated with a large amount of n-heptane, and subsequently filtered; and the obtained solid was vacuum-dried to thereby obtain 71 g of a resin A-1.

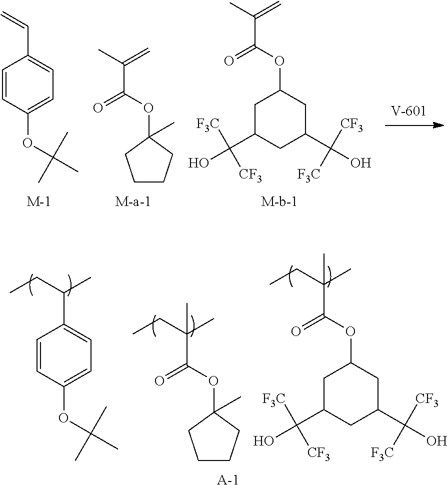

The obtained resin A-1 was subjected to GPC (carrier: tetrahydrofuran (THF)) and found to have a weight-average molecular weight (Mw: polystyrene-equivalent) of 6500, and a dispersity (Mw/Mn) of 1.60. The compositional ratio measured by ¹³C-NMR was 30/40/30 in terms of a molar ratio.

### Synthesis Example 2: Synthesis of Resin A-2

Cyclohexanone (44 g) was heated to 85° C. under a nitrogen stream. To this liquid, a mixed solution of cyclohexanone (3.1 g) and dimethyl 2,2′-azobisisobutyrate [V-601, manufactured by Wako Pure Chemical Industries, Ltd.] (0.8 g) was added and stirred for 5 minutes. To this liquid under stirring, a mixed solution of a monomer (19.1 g) represented by a formula M-1 below, a monomer (18.4 g) represented by a formula M-a-1 below, a monomer (62.5 g) represented by a formula M-b-2-ii below, cyclohexanone (187 g), and dimethyl 2,2′-azobisisobutyrate [V-601, manufactured by Wako Pure Chemical Industries, Ltd.] (9.2 g) was added dropwise over 6 hours, to obtain a reaction solution. After completion of the dropwise addition, the reaction solution was further stirred at 85° C. for 2 hours to thereby obtain a resin A-2′ solution.

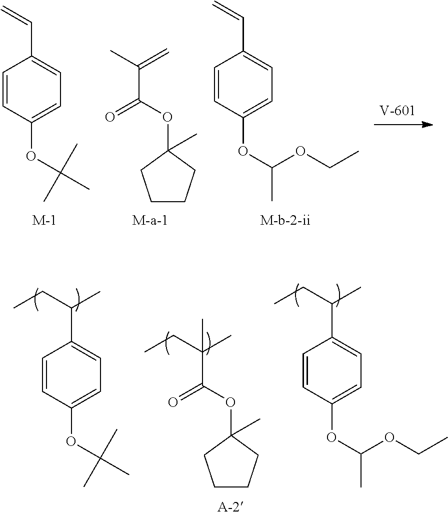

To the resin A-2′ solution, a 0.3 mol/L aqueous hydrochloric acid solution (5.6 g) was added and stirred at 40° C. for 1 hour. To the resultant reaction solution, ethyl acetate (1560 g) was added and the reaction solution was subjected to liquid-liquid separation and purification five times using 1 L of distilled water. The organic layer was reprecipitated with a large amount of a mixed solution of n-heptane/ethyl acetate (weight ratio of 9/1), and subsequently filtered; the obtained solid was vacuum-dried to thereby obtain 70 g of a resin A-2.

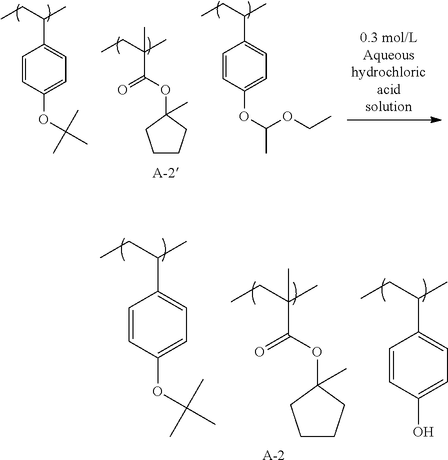

The obtained resin A-2 was subjected to GPC (carrier: tetrahydrofuran (THF)) and found to have a weight-average molecular weight (Mw: polystyrene-equivalent) of 7200 and a dispersity (Mw/Mn) of 1.59. The compositional ratio measured by ¹³C-NMR was 20/20/60 in terms of a molar ratio.

### Synthesis Example 3: Synthesis of Resin A-3

Cyclohexanone (43 g) was heated to 85° C. under a nitrogen stream. To this liquid, a mixed solution of cyclohexanone (4.0 g) and dimethyl 2,2′-azobisisobutyrate [V-601, manufactured by Wako Pure Chemical Industries, Ltd.] (0.47 g) was added, and stirred for 5 minutes. To this liquid under stirring, a mixed solution of a monomer (20.4 g) represented by a formula M-1 below, a monomer (28.2 g) represented by a formula M-a-3 below, a monomer (51.5 g) represented by a formula M-b-2-i below, cyclohexanone (187 g), and dimethyl 2,2′-azobisisobutyrate [V-601, manufactured by Wako Pure Chemical Industries, Ltd.] (9.2 g) was added dropwise over 6 hours to obtain a reaction solution. After completion of the dropwise addition, the reaction solution was further stirred at 85° C. for 2 hours to thereby obtain a resin A-3′ solution.

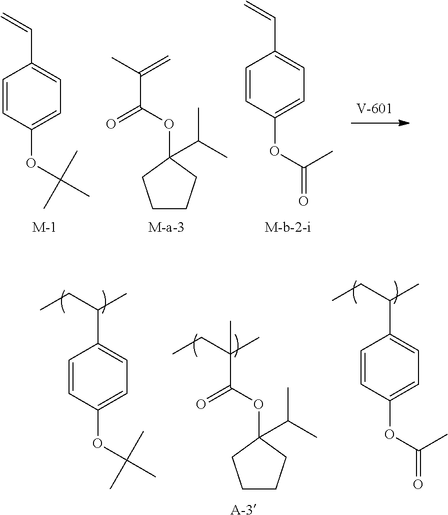

To the resin A-3′ solution, triethylamine (67 g) and methanol (203 g) were added, and the mixture was stirred at 80° C. for 15 hours under a nitrogen stream. The obtained reaction solution was left to cool; subsequently a 0.2 mol/L aqueous hydrochloric acid solution (4 L) was added and stirred, and ethyl acetate (1570 g) was further added and stirred. The organic layer was extracted and subsequently subjected to liquid-liquid separation and purification once with a 0.2 mol/L aqueous hydrochloric acid solution (0.5 L) and five times with distilled water (1 L). The obtained organic layer was reprecipitated with a large amount of a mixed solution of n-heptane/ethyl acetate (weight ratio of 9:1) and subsequently filtered; the obtained solid was vacuum-dried to obtain 80 g of a resin A-3.

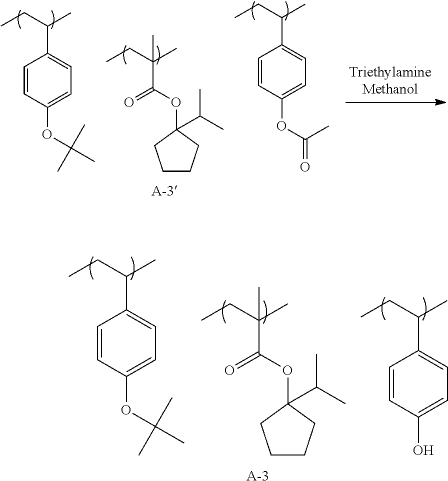

The obtained resin A-3 was subjected to GPC (carrier: tetrahydrofuran (THF)) and found to have a weight-average molecular weight (Mw: polystyrene-equivalent) of 7000 and a dispersity (Mw/Mn) of 1.58. The compositional ratio measured by ¹³C-NMR was 20/25/55 in terms of a molar ratio.

### Synthesis Example 4: Synthesis of Resin A-4

Cyclohexanone (44 g) was heated to 85° C. under a nitrogen stream. To this liquid, a mixed solution of cyclohexanone (2.4 g) and dimethyl 2,2′-azobisisobutyrate [V-601, manufactured by Wako Pure Chemical Industries, Ltd.] (0.57 g) was added, and stirred for 5 minutes. To this liquid under stirring, a mixed solution of a monomer (28.3 g) represented by a formula M-1 below, a monomer (21.9 g) represented by a formula M-a-2 below, a monomer (49.8 g) represented by a formula M-b-15-i below, cyclohexanone (187 g), and dimethyl 2,2′-azobisisobutyrate [V-601, manufactured by Wako Pure Chemical Industries, Ltd.] (5.5 g) was added dropwise over 6 hours to obtain a reaction solution. After completion of the dropwise addition, the reaction solution was further stirred at 85° C. for 2 hours to thereby obtain a resin A-4′ solution.

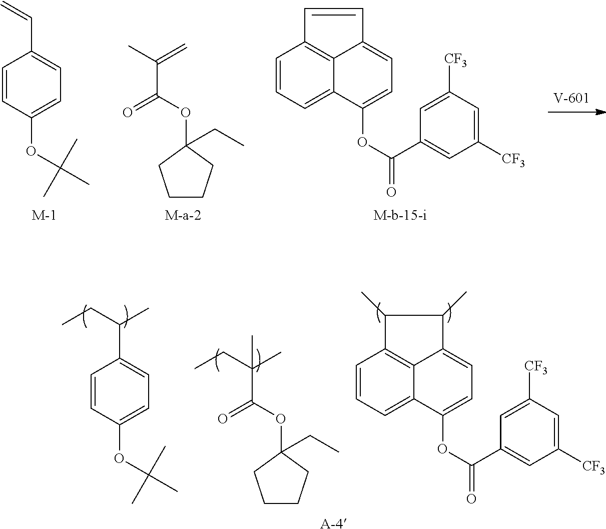

To the resin A-4′ solution, triethylamine (50 g) and methanol (79.1 g) were added, and stirred at 80° C. for 3 hours under a nitrogen stream. The obtained reaction solution was left to cool; subsequently, a 0.2 mol/L aqueous hydrochloric acid solution (3.0 L) was added and stirred, and ethyl acetate (1570 g) was further added and stirred. The organic layer was extracted and subsequently subjected to liquid-liquid separation and purification once with a 0.2 mol/L aqueous hydrochloric acid solution (0.5 L) and five times with distilled water (1 L). The obtained organic layer was reprecipitated with a large amount of a mixed solution of n-heptane/ethyl acetate (weight ratio of 9:1) and subsequently filtered; the obtained solid was vacuum-dried to thereby obtain 63 g of a resin A-4.

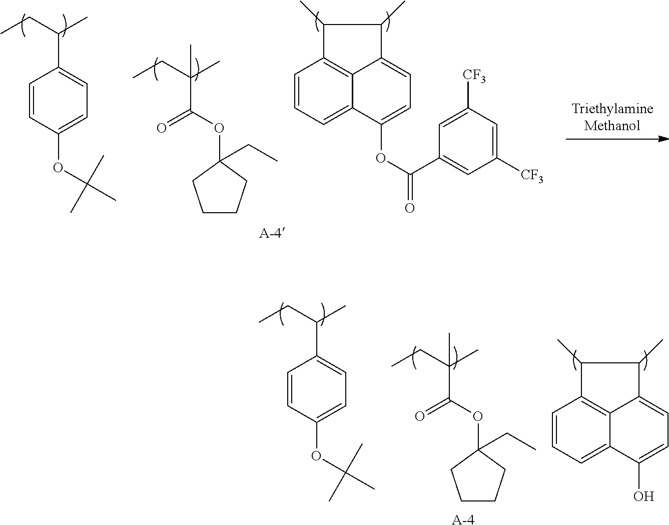

The obtained resin A-4 was subjected to GPC (carrier: tetrahydrofuran (THF)) and found to have a weight-average molecular weight (Mw: polystyrene-equivalent) of 7500 and a dispersity (Mw/Mn) of 1.55. The compositional ratio measured by ¹³C-NMR was 40/30/30 in terms of a molar ratio.

### Photoacid Generator (B)

The structures of the photoacid generator (B) (compounds B-1 to B-15) described in Table 3 will be described below. The photoacid generator (B) is a photoacid generator corresponding to the above-described ionic compound (Y).

The values described in the structures represent the pKa of the “—SO₂—N⁻—” moiety. The method for measuring the pKa is as described above.

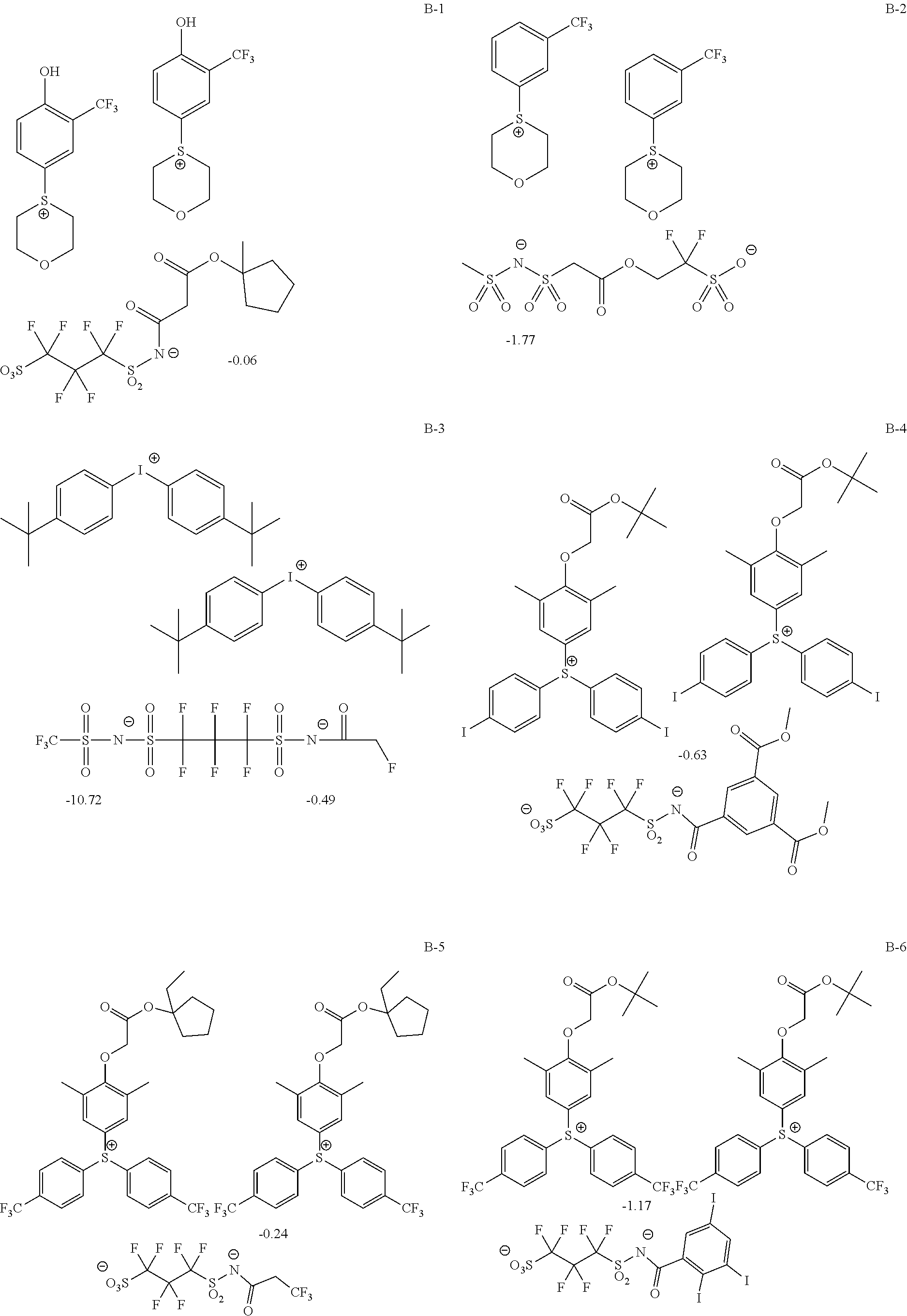

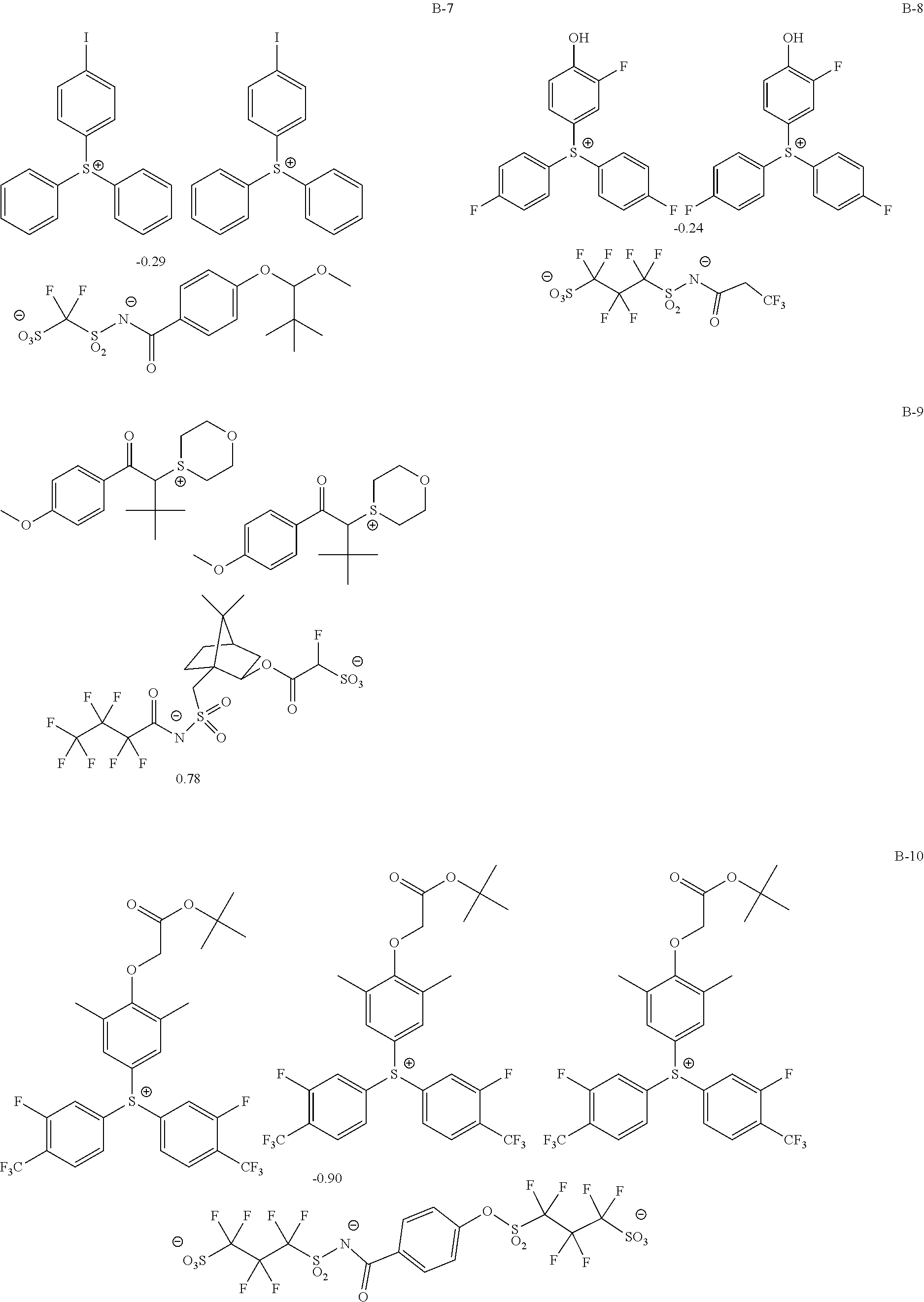

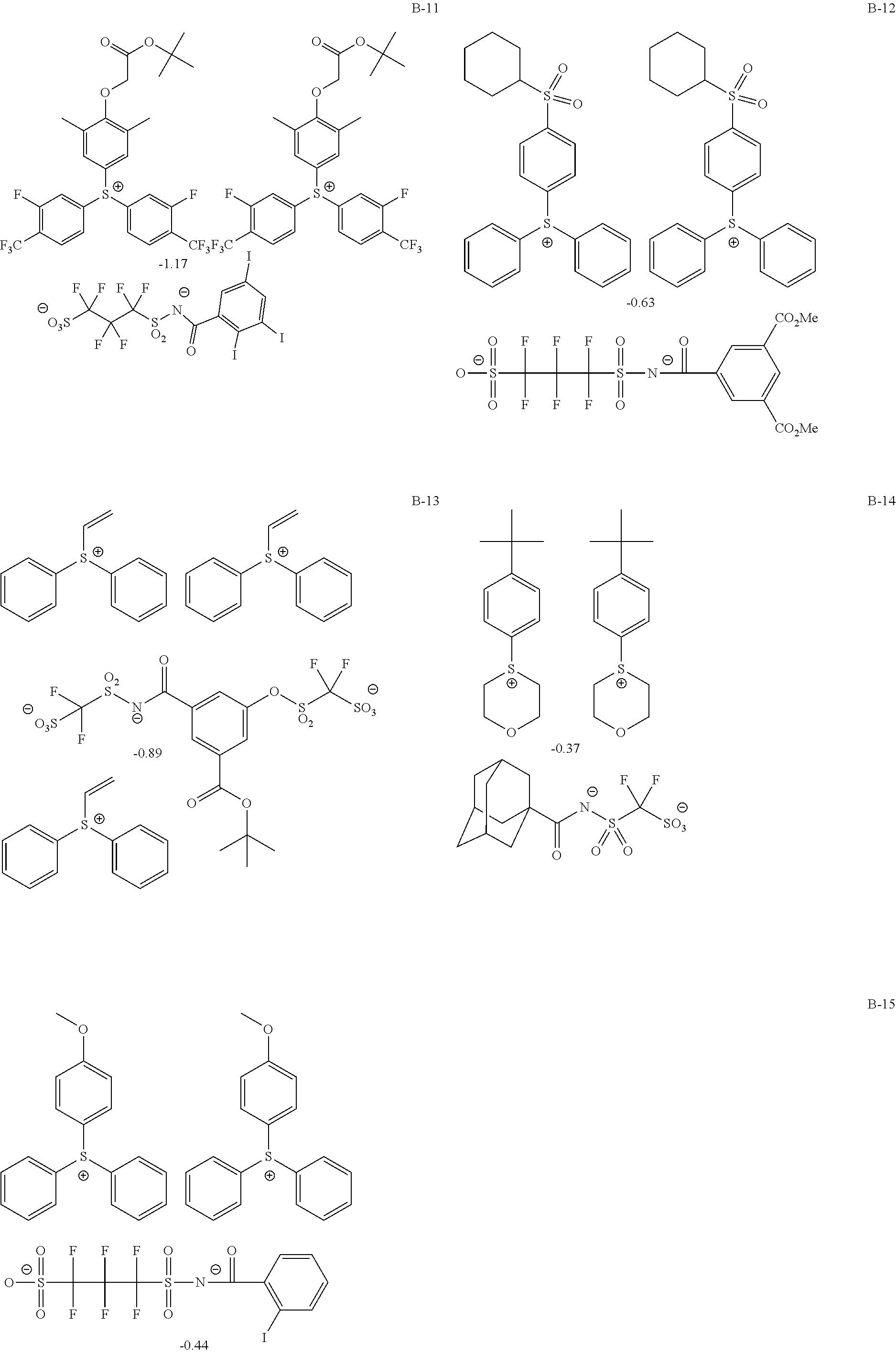

### Photoacid Generator (C)

The structures of the photoacid generator (C) (compounds C-1 to C-35) described in Table 3 will be described below. The photoacid generator (C) is a photoacid generator that does not correspond to the above-described ionic compound (Y).

The values described in the structures represent the pKa of the “—SO₂—N⁻—” moiety.

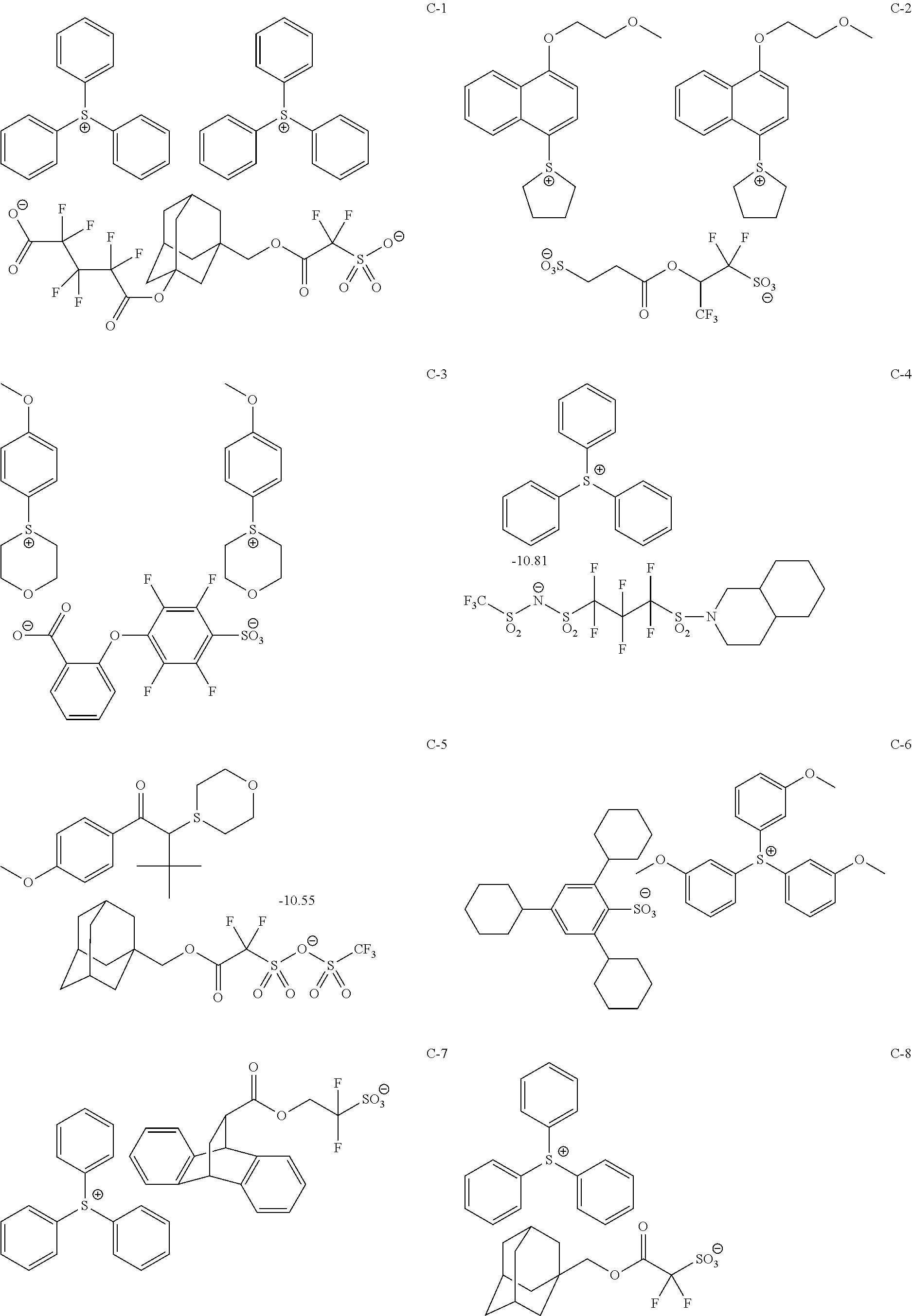

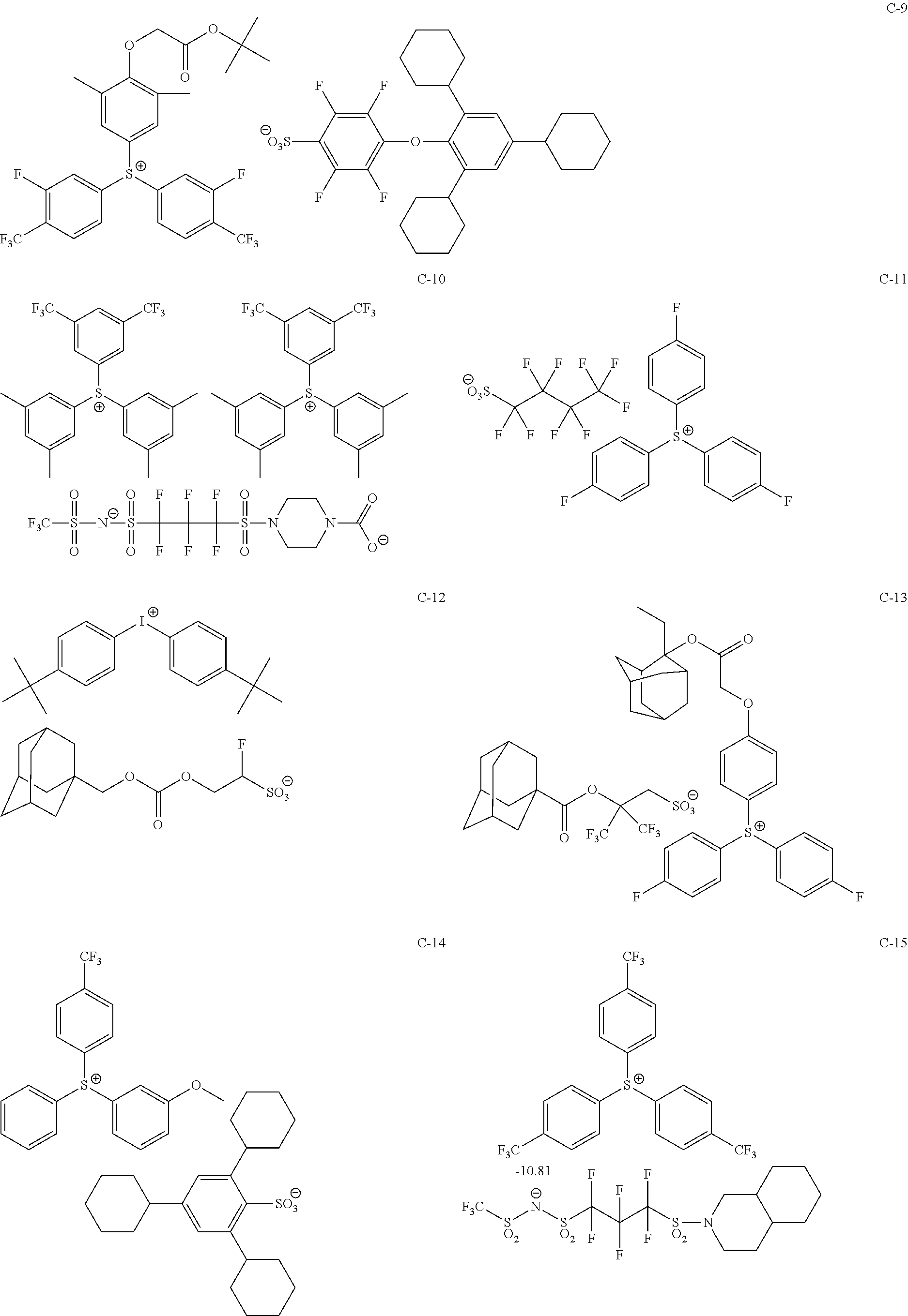

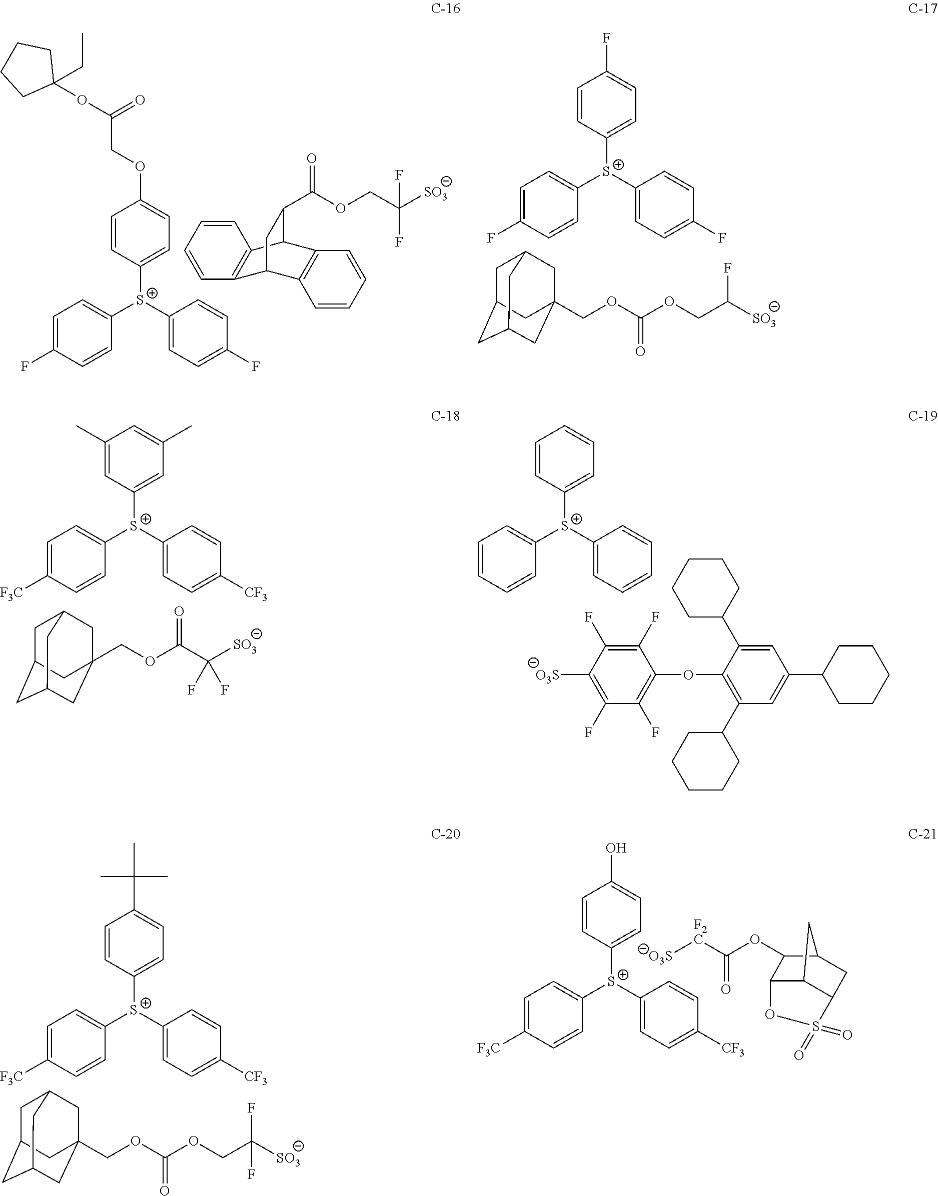

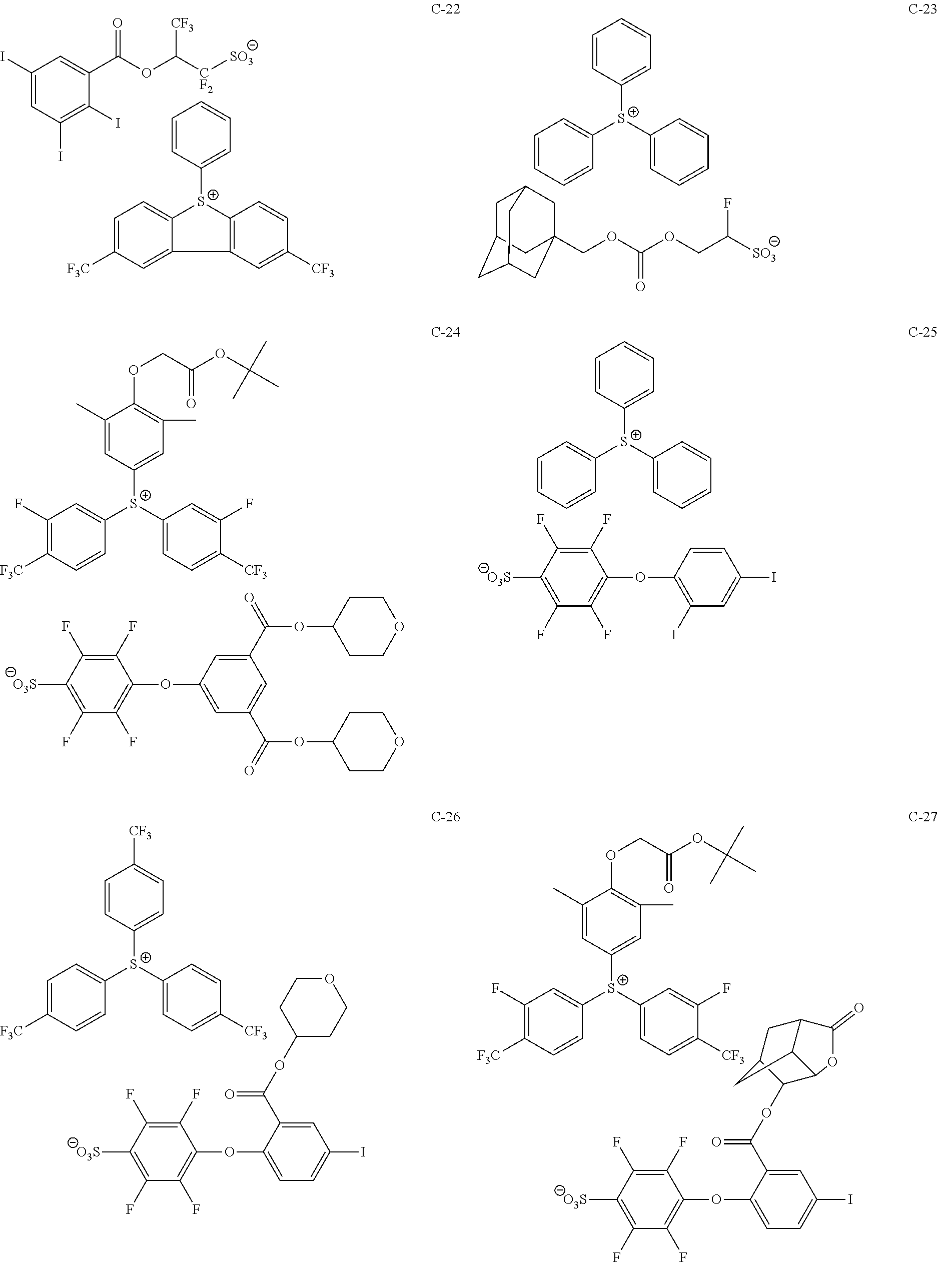

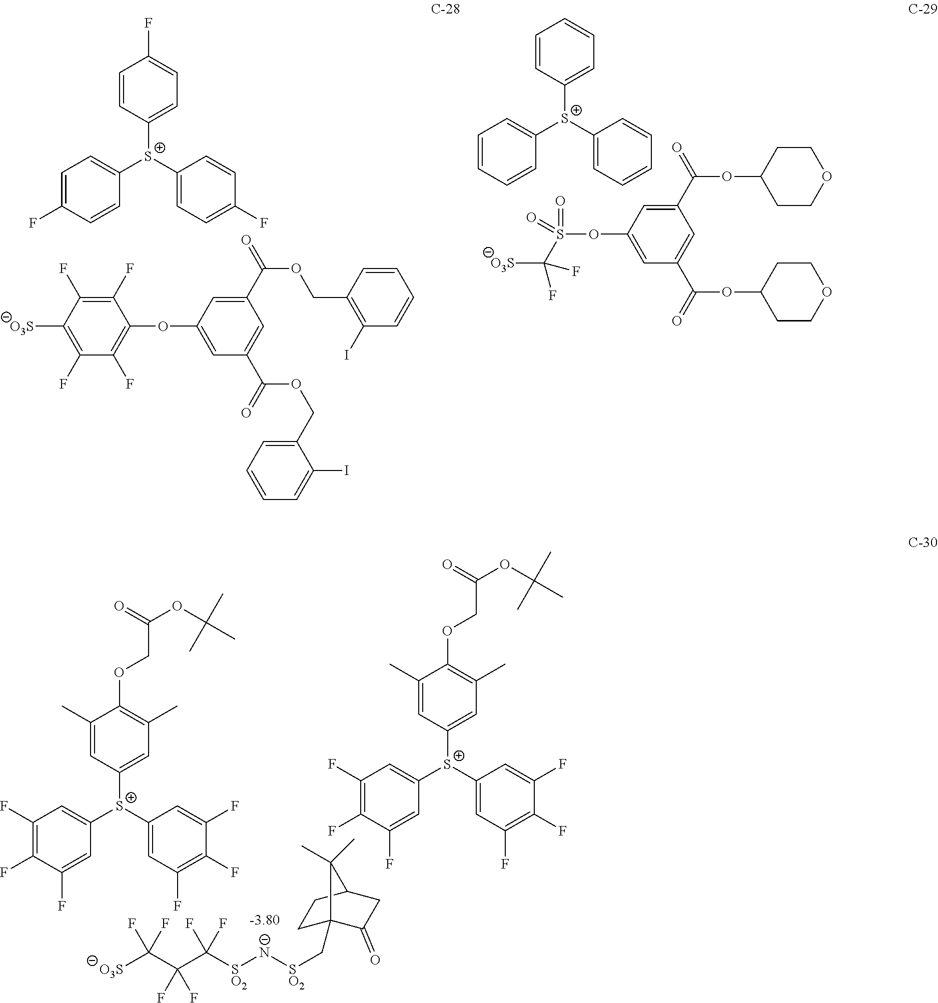

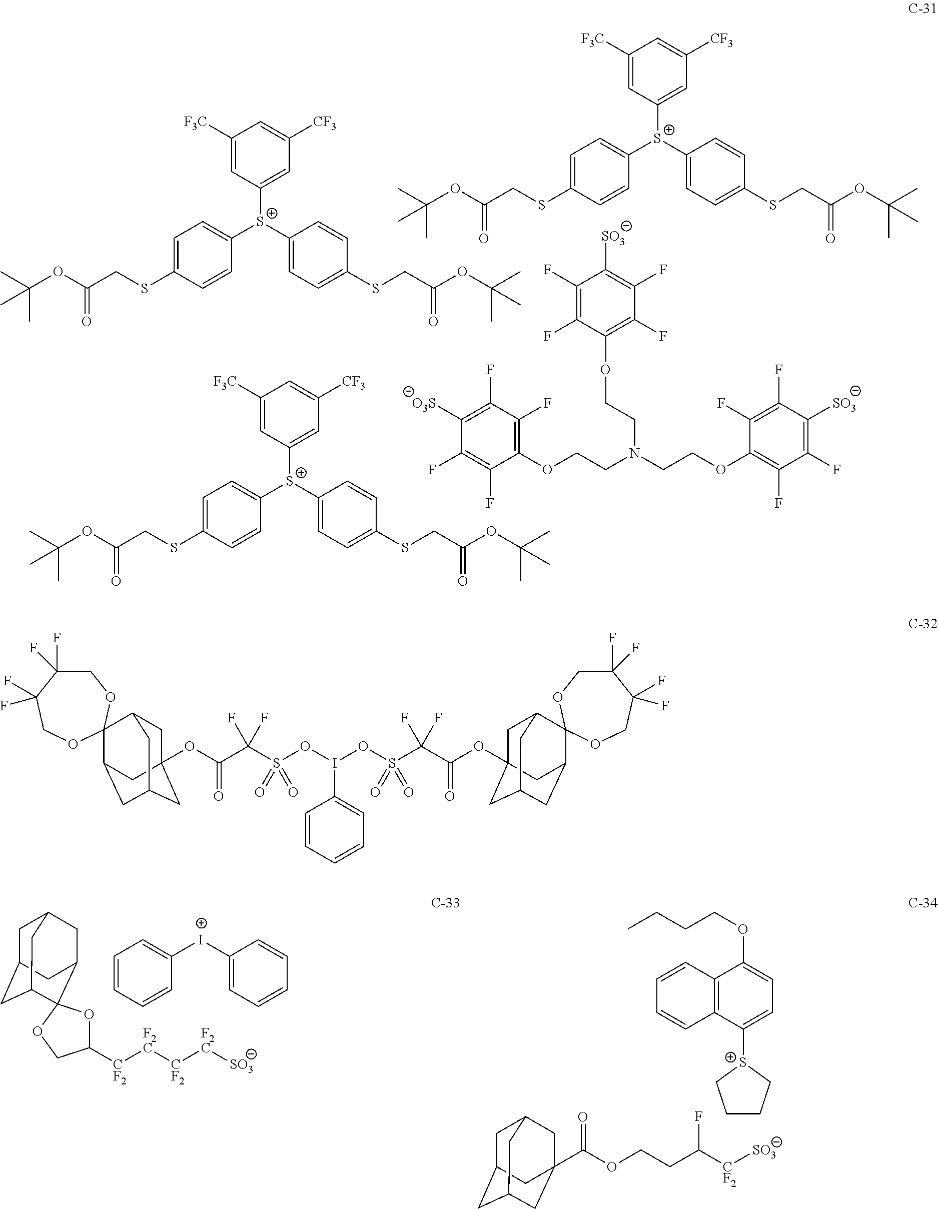

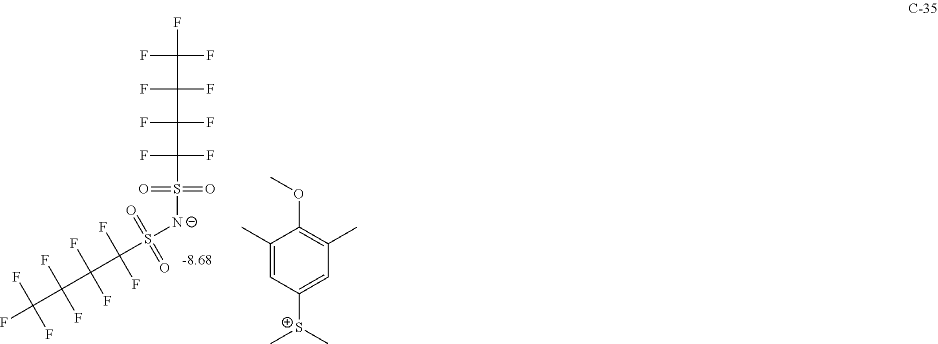

### Acid Diffusion Control Agent (D)

The structures of the acid diffusion control agent (D) (compounds D-1 to D-9) described in Table 3 will be described below. The acid diffusion control agent (D) is an acid diffusion control agent corresponding to the above-described ionic compound (Y).

The values described in the structures represent the pKa of the “—SO₂—N⁻—” moiety.

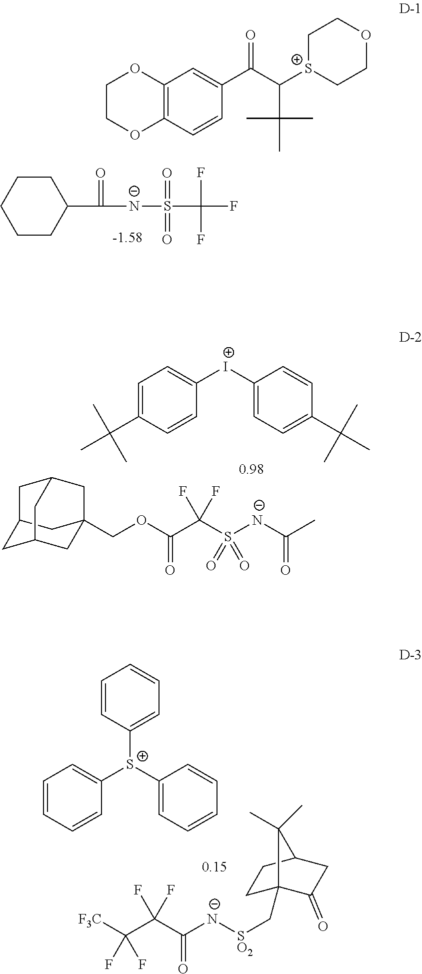 [SMILES: CC(C)(C)C(C(=O)c1ccc2c(c1)OCCO2)[S+]1CCOCC1 ; O=C([N-]S(=O)(=O)C(F)(F)F)C1CCCCC1 ; CC(C)(C)c1ccc([I+]c2ccc(C(C)(C)C)cc2)cc1 ; CC(=O)[N-]S(=O)(=O)C(F)(F)C(=O)OCC12CC3CC(CC(C3)C1)C2 ; c1ccc([S+](c2ccccc2)c2ccccc2)cc1 ; CC1(C)C2CCC1(CS(=O)(=O)[N-]C(=O)C(F)(F)C(F)(F)C(F)(F)F)C(=O)C2]

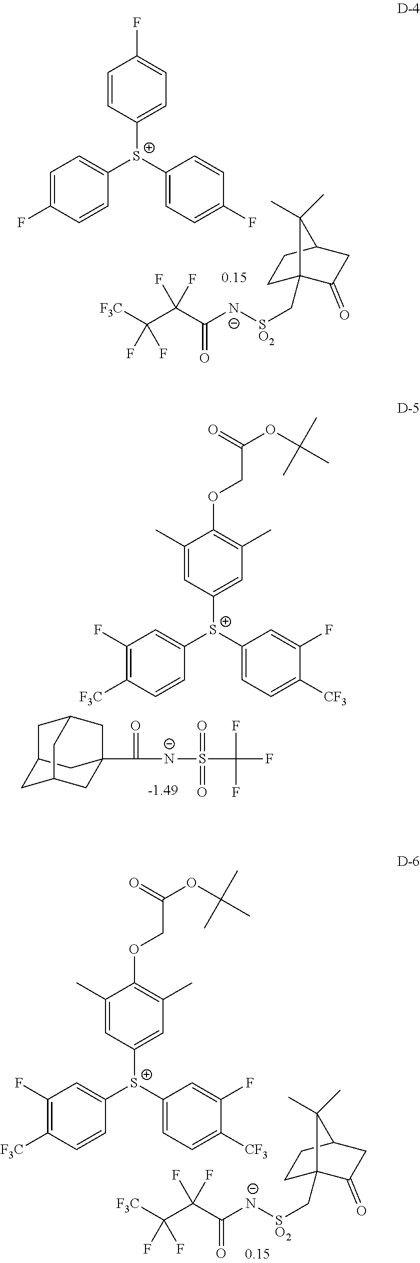 [SMILES: Fc1ccc([S+](c2ccc(F)cc2)c2ccc(F)cc2)cc1 ; CC1(C)C2CCC1(CS(=O)(=O)[N-]C(=O)C(F)(F)C(F)(F)C(F)(F)F)C(=O)C2 ; Cc1cc([S+](c2ccc(C(F)(F)F)c(F)c2)c2ccc(C(F)(F)F)c(F)c2)cc(C)c1OCC(=O)OC(C)(C)C ; O=C([N-]S(=O)(=O)C(F)(F)F)C12CC3CC(CC(C3)C1)C2 ; Cc1cc([S+](c2ccc(C(F)(F)F)c(F)c2)c2ccc(C(F)(F)F)c(F)c2)cc(C)c1OCC(=O)OC(C)(C)C ; CC1(C)C2CCC1(CS(=O)(=O)[N-]C(=O)C(F)(F)C(F)(F)C(F)(F)F)C(=O)C2]

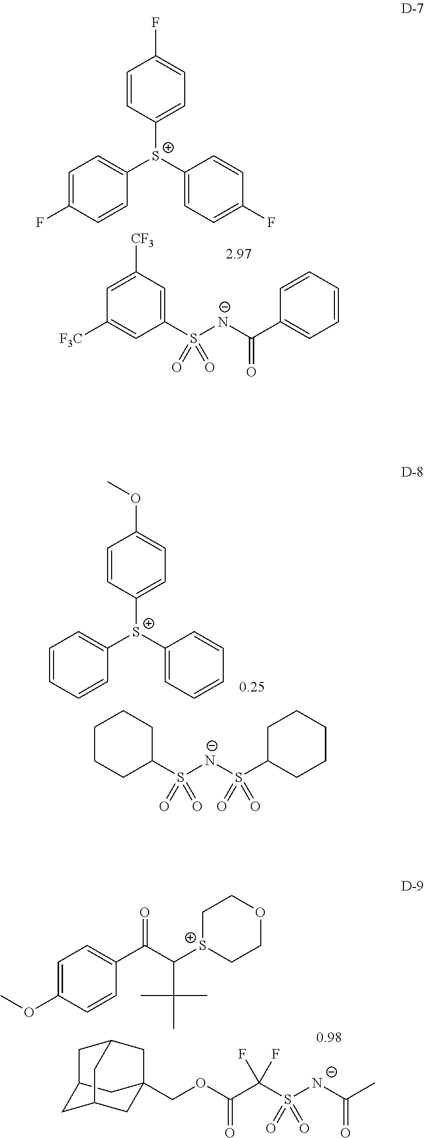 [SMILES: Fc1ccc([S+](c2ccc(F)cc2)c2ccc(F)cc2)cc1 ; O=C([N-]S(=O)(=O)c1cc(C(F)(F)F)cc(C(F)(F)F)c1)c1ccccc1 ; COc1ccc([S+](c2ccccc2)c2ccccc2)cc1 ; O=S(=O)([N-]S(=O)(=O)C1CCCCC1)C1CCCCC1 ; COc1ccc(C(=O)C([S+]2CCOCC2)C(C)(C)C)cc1 ; CC(=O)[N-]S(=O)(=O)C(F)(F)C(=O)OCC12CC3CC(CC(C3)C1)C2]

### Acid Diffusion Control Agent (E)

The structures of the acid diffusion control agent (E) (compounds E-1 to E-15) described in Table 3 will be described below. The acid diffusion control agent (E) is an acid diffusion control agent that does not correspond to the above-described ionic compound (Y), and is an acid diffusion control agent that corresponds to the above-described compound (CC) whose acid diffusion control ability is reduced or lost upon irradiation with an actinic ray or a radiation.

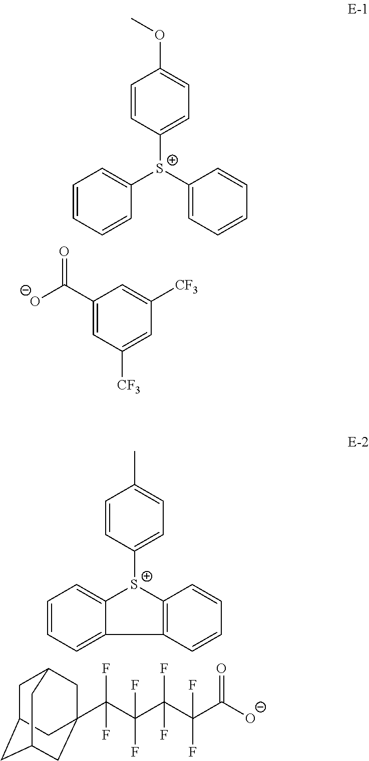 [SMILES: COc1ccc([S+](c2ccccc2)c2ccccc2)cc1 ; O=C([O-])c1cc(C(F)(F)F)cc(C(F)(F)F)c1 ; Cc1ccc(-[s+]2c3ccccc3c3ccccc32)cc1 ; O=C([O-])C(F)(F)C(F)(F)C(F)(F)C(F)(F)C12CC3CC(CC(C3)C1)C2]

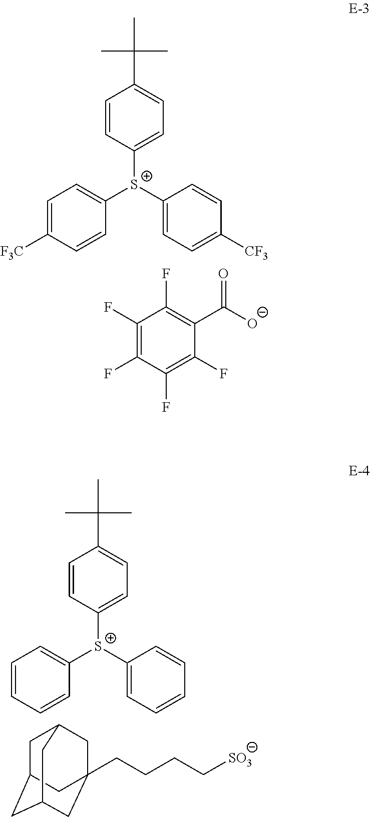

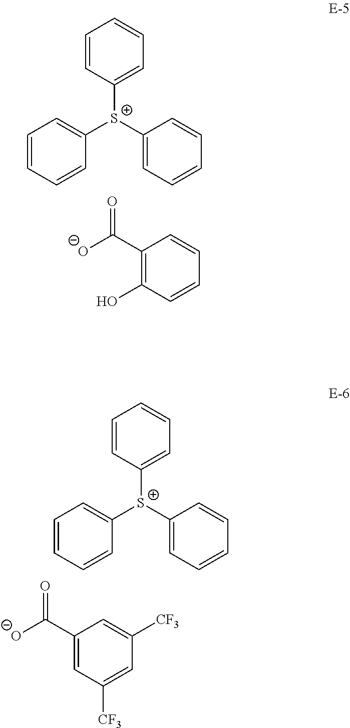 [SMILES: c1ccc([S+](c2ccccc2)c2ccccc2)cc1 ; O=C([O-])c1ccccc1O ; c1ccc([S+](c2ccccc2)c2ccccc2)cc1 ; O=C([O-])c1cc(C(F)(F)F)cc(C(F)(F)F)c1]

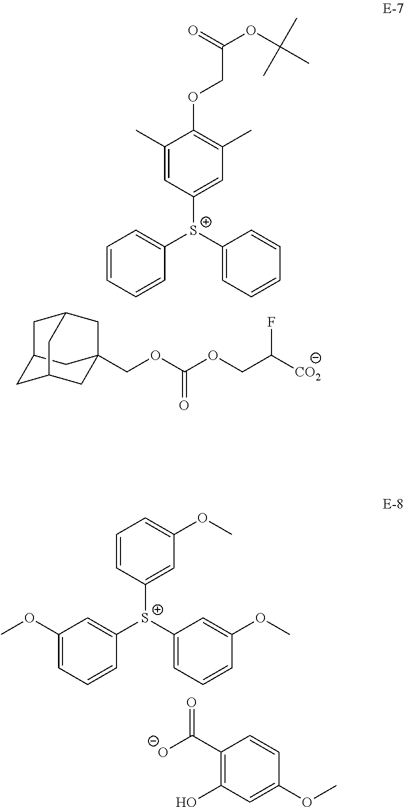

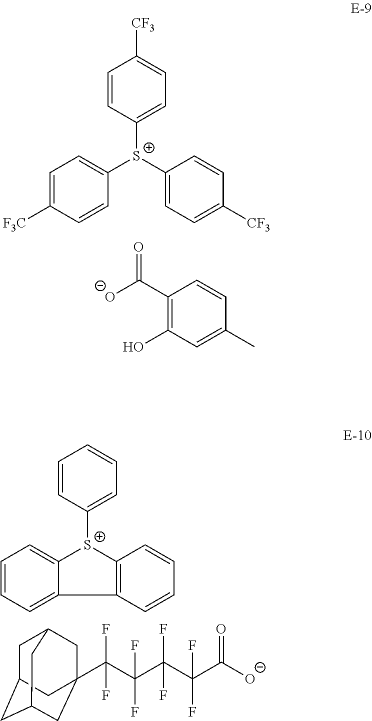 [SMILES: FC(F)(F)c1ccc([S+](c2ccc(C(F)(F)F)cc2)c2ccc(C(F)(F)F)cc2)cc1 ; Cc1ccc(C(=O)[O-])c(O)c1 ; c1ccc(-[s+]2c3ccccc3c3ccccc32)cc1 ; O=C([O-])C(F)(F)C(F)(F)C(F)(F)C(F)(F)C12CC3CC(CC(C3)C1)C2]

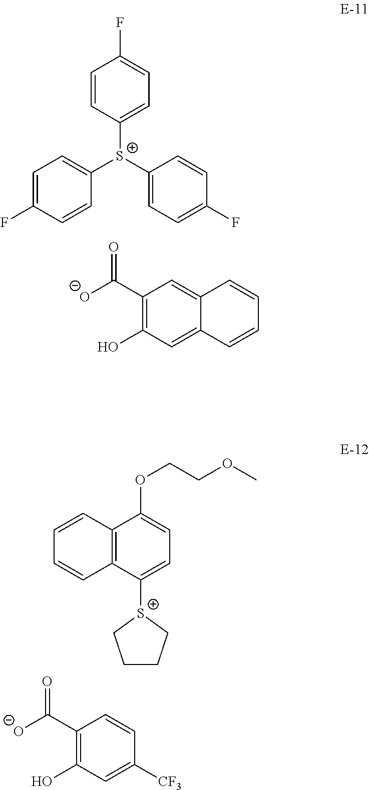 [SMILES: Fc1ccc([S+](c2ccc(F)cc2)c2ccc(F)cc2)cc1 ; O=C([O-])c1cc2ccccc2cc1O ; COCCOc1ccc([S+]2CCCC2)c2ccccc12 ; O=C([O-])c1ccc(C(F)(F)F)cc1O]

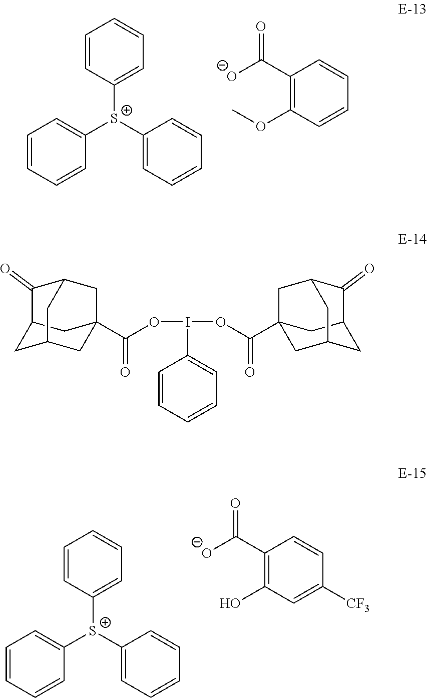 [SMILES: c1ccc([S+](c2ccccc2)c2ccccc2)cc1 ; COc1ccccc1C(=O)[O-] ; O=C1C2CC3CC1CC(C(=O)OI(OC(=O)C14CC5CC(C1)C(=O)C(C5)C4)c1ccccc1)(C3)C2 ; c1ccc([S+](c2ccccc2)c2ccccc2)cc1 ; O=C([O-])c1ccc(C(F)(F)F)cc1O]

### Acid Diffusion Control Agent (G)

The structure of the acid diffusion control agent (G) (compounds G-1 to G-5 described in Table 3 will be described below. The acid diffusion control agent (G) is an acid diffusion control agent that does not correspond to the above-described ionic compound (Y), and is an acid diffusion control agent that corresponds to the above-described basic compound (CA).

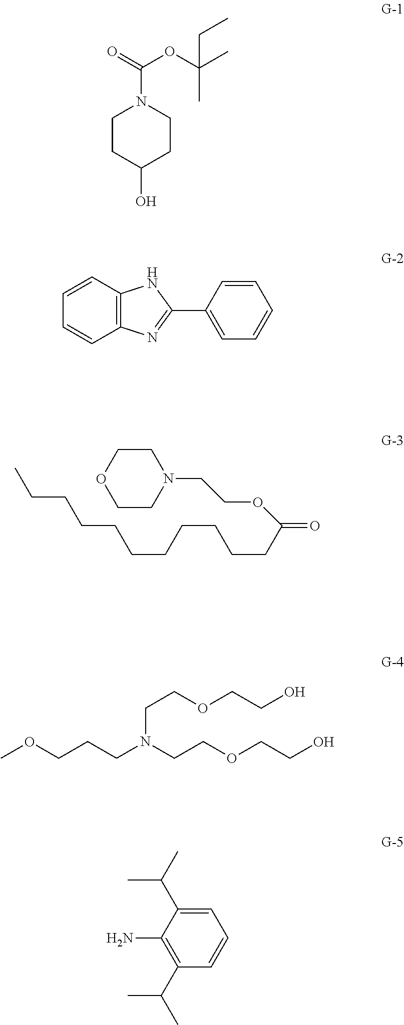 [SMILES: CCC(C)(C)OC(=O)N1CCC(O)CC1 ; c1ccc(-c2nc3ccccc3[nH]2)cc1 ; CCCCCCCCCCCC(=O)OCCN1CCOCC1 ; COCCCN(CCOCCO)CCOCCO ; CC(C)c1cccc(C(C)C)c1N]

### Resin (I)

The resin (I) (resins I-1 to I-8) described in Table 3 will be described below.

As the resins I-1 to I-8, resins synthesized in accordance with the above-described synthesis method (Synthesis Example 1) of the resin A-1 were used. Table 2 describes the compositional ratio (mass % ratio; sequentially described from the left) of repeating units described later, weight-average molecular weight (Mw), and dispersity (Mw/Mn).

Note that, for the resins I-1 to I-8, the weight-average molecular weight (Mw) and the dispersity (Mw/Mn) were measured by GPC (carrier: tetrahydrofuran (THF)) (polystyrene-equivalent amounts). The compositional ratios (mass % ratio) of the resins were measured by ¹³C-NMR.

TABLE 3

| Table 2 | Mass ratio of repeating units | | | | Mw | Mw/Mn |
|---|---|---|---|---|---|---|
| Resin I-1 | 50 | 45 | 5 | — | 6500 | 1.52 |
| Resin I-2 | 50 | 50 | — | — | 25000 | 1.65 |
| Resin I-3 | 30 | 65 | 5 | — | 22000 | 1.55 |
| Resin I-4 | 40 | 40 | 20 | — | 12000 | 1.68 |
| Resin I-5 | 40 | 50 | 5 | 5 | 5500 | 1.49 |
| Resin I-6 | 90 | 8 | 2 | — | 12000 | 1.63 |
| Resin I-7 | 20 | 30 | 40 | 10 | 13000 | 1.55 |
| Resin I-8 | 50 | 10 | 40 | — | 9000 | 1.51 |

The structural formulas of the resins I-1 to I-8 described in Table 2 are as follows.
I-1 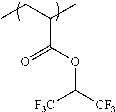 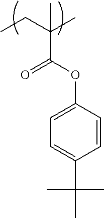 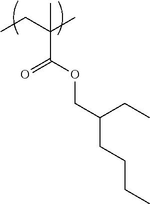
I-2 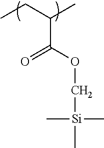 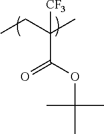
I-3 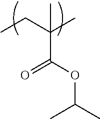 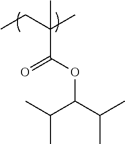 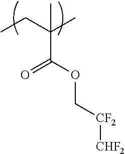
I-4 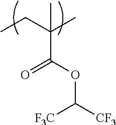 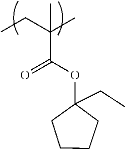 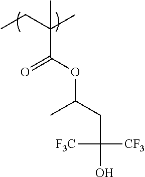
I-5 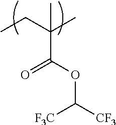 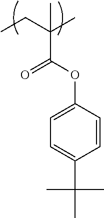 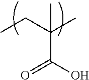 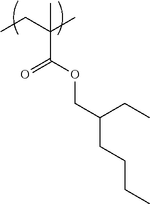
I-6 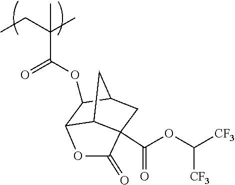 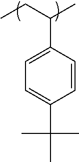 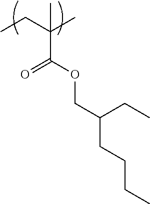
I-7 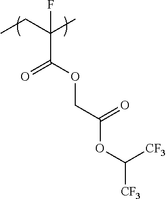 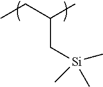 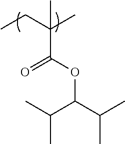 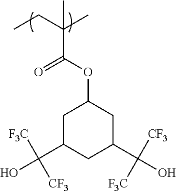
I-8

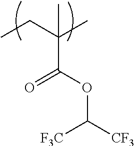

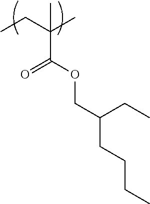

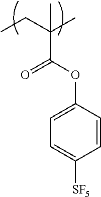

### Surfactant (H)

The surfactants described in Table 3 are as follows.
H-1: MEGAFACE F176 (manufactured by DIC Corporation, fluorine-based surfactant)
H-2: MEGAFACE R08 (manufactured by DIC Corporation, fluorine-based and silicone-based surfactant)
H-3: PF656 (manufactured by OMNOVA SOLUTIONS INC., fluorine-based surfactant)

### Solvent (F)

The solvents described in Table 3 are as follows.
F-1: propylene glycol monomethyl ether acetate (PGMEA)
F-2: propylene glycol monomethyl ether (PGME)
F-3: propylene glycol monoethyl ether (PGEE)
F-4: cyclohexanone
F-5: cyclopentanone
F-6: 2-heptanone
F-7: ethyl lactate
F-8: γ-butyrolactone
F-9: propylene carbonate

### Preparation of Resist Compositions

Components described in Table 3 were mixed together so as to provide a solid-content concentration of 2.0 mass %. Subsequently, the obtained mixed solution was filtered first through a polyethylene filter having a pore size of 50 nm, subsequently through a nylon filter having a pore size of 10 nm, and finally through a polyethylene filter having a pore size of 5 nm in this order; in this way, resist compositions (Re-1 to Re-61, Re-1R to Re-6R) were prepared.

Note that the solid content means all the components other than the solvent. The obtained resist compositions were used in Examples and Comparative Examples.

In Tables, the columns “Amount” describe the content (mass %) of each component relative to the total solid content of the resist composition.

| | Solid content | | | | | | | | | |
|---|---|---|---|---|---|---|---|---|---|---|
| | | | Photoacid | | Photoacid | | Acid diffusion | | Acid diffusion | |
| Table | Resin (A) | | generator (B) | | generator (C) | | control agent (D) | | control agent (E) | |
| 3 | Type | Amount | Type | Amount | Type | Amount | Type | Amount | Type | Amount |
| Re-1 | A-1 | 65.0 | B-1 | 32.0 | — | — | D-1 | 3.0 | — | — |
| Rc-2 | A-2 | 60.0 | B-2 | 38.0 | — | — | D-2 | 2.0 | — | — |
| Re-3 | A-3 | 52.0 | B-3 | 44.0 | — | — | D-3 | 4.0 | — | — |
| Re-4 | A-4 | 55.0 | B-4 | 40.0 | — | — | D-4 | 5.0 | — | — |
| Re-5 | A-5 | 60.0 | B-5 | 38.0 | — | — | D-5 | 2.0 | — | — |
| Re-6 | A-6 | 65.0 | B-6 | 29.0 | — | — | D-6 | 6.0 | — | — |
| Re-7 | A-7 | 54.0 | B-7 | 33.9 | — | — | D-7 | 12.0 | — | — |
| Re-8 | A-8 | 38.0 | B-8 | 55.0 | — | — | D-8 | 7.0 | — | — |
| Re-9 | A-9 | 50.0 | B-9 | 35.0 | — | — | D-9 | 15.0 | — | — |
| Re-10 | A-10 | 50.0 | B-10 | 40.0 | — | — | — | — | E-1 | 10.0 |
| Re-11 | A-11 | 55.0 | B-11 | 30.0 | C-1 | 10.0 | — | — | E-2 | 5.0 |
| Re-12 | A-12 | 80.0 | B-12 | 8.0 | C-2 | 10.0 | — | — | E-3 | 2.0 |
| Re-13 | A-13 | 60.0 | B-13 | 30.0 | C-3 | 4.0 | — | — | E-4 | 4.0 |
| Re-14 | A-14 | 70.0 | B-14 | 20.0 | C-4 | 5.0 | — | — | E-5 | 2.0 |
| Re-15 | A-15 | 65.0 | B-15 | 24.0 | C-5 | 6.0 | — | — | E-6 | 2.0 |
| Re-16 | A-16 | 80.0 | B-1 | 11.0 | C-6 | 3.0 | — | — | E-7 | 1.0 |
| Re-17 | A-17 | 63.5 | — | — | C-7 | 28.0 | D-1 | 4.0 | E-8 | 0.5 |
| Re-18 | A-18 | 85.0 | — | — | C-8 | 11.0 | D-2 | 2.0 | E-9 | 1.0 |
| Re-19 | A-19 | 65.5 | — | — | C-9 | 20.0 | D-3 | 10.0 | E-10 | 2.5 |
| Re-20 | A-20 | 68.0 | — | — | C-10 | 18.0 | D-4 | 6.0 | E-11 | 3.0 |
| Re-21 | A-21 | 55.0 | — | — | C-11 | 35.0 | D-5 | 5.0 | E-12 | 1.0 |
| Re-22 | A-22 | 57.0 | — | — | C-12 | 30.0 | D-6 | 3.0 | E-13 | 1.0 |
| Re-23 | A-23 | 80.0 | — | — | C-13 | 14.0 | D-7 | 2.0 | E-14 | 1.0 |
| Re-24 | A-24 | 78.0 | — | — | C-14 | 13.0 | D-1 | 4.0 | — | — |
| Re-25 | A-25 | 70.0 | — | — | C-15 | 22.0 | D-1 | 4.0 | — | — |

| | Solid content | | | | | | | |
|---|---|---|---|---|---|---|---|---|
| | Acid diffusion | | | | | | Solvent (F) | |
| Table | control agent (G) | | Resin (I) | | Surfactant (H) | | | Mixing ratio |
| 3 | Type | Amount | Type | Amount | Type | Amount | Type | (mass ratio) |
| Re-1 | — | — | — | — | — | — | F-1/F-2 | 80/20 |
| Rc-2 | — | — | — | — | — | — | F-1/F-5 | 85/15 |
| Re-3 | — | — | — | — | — | — | F-1/F-2 | 80/20 |
| Re-4 | — | — | — | — | — | — | F-1/F-2/F-8 | 40/20/40 |
| Re-5 | — | — | — | — | — | — | F-1/F-2 | 80/20 |
| Re-6 | — | — | — | — | — | — | F-1/F-9 | 85/15 |
| Re-7 | — | — | — | — | H-1 | 0.1 | F-1/F-7 | 90/10 |
| Re-8 | — | — | — | — | — | — | F-1/F-2 | 80/20 |
| Re-9 | — | — | — | — | — | — | F-1/F-2 | 80/20 |
| Re-10 | — | — | — | — | — | — | F-1/F-2/F-6 | 70/20/10 |
| Re-11 | — | — | — | — | — | — | F-1/F-2 | 80/20 |
| Re-12 | — | — | — | — | — | — | F-1/F-4 | 80/20 |
| Re-13 | — | — | I-1 | 2.0 | — | — | F-1/F-2 | 80/20 |
| Re-14 | — | — | I-2 | 2.9 | H-2 | 0.1 | F-4 | 100 |
| Re-15 | G-1 | 3.0 | — | — | — | — | F-1/F-2/F-8 | 85/12/3 |
| Re-16 | G-2 | 5.0 | — | — | — | — | F-1/F-5 | 80/20 |
| Re-17 | — | — | I-3 | 4.0 | — | — | F-1/F-2 | 75/25 |
| Re-18 | G-3 | 1.0 | — | — | — | — | F-1/F-2/F-8 | 34/33/33 |
| Re-19 | — | — | I-4 | 2.0 | — | — | F-1/F-2 | 80/20 |
| Re-20 | G-4 | 5.0 | — | — | — | — | F-1/F-9 | 80/20 |
| Re-21 | G-5 | 4.0 | — | — | — | — | F-1/F-2/F-8 | 85/12/3 |
| Re-22 | — | — | I-5 | 8.9 | H-3 | 0.1 | F-1/F-2 | 85/15 |
| Re-23 | — | — | I-6 | 3.0 | — | — | F-1/F-2 | 80/20 |
| Re-24 | — | — | I-7 | 5.0 | — | — | F-1/F-2/F-6 | 80/15/5 |
| Re-25 | — | — | 1-8 | 4.0 | — | — | F-1/F-2 | 90/10 |

TABLE 5

| | Solid content | | | | | | | | | |
|---|---|---|---|---|---|---|---|---|---|---|
| | | | Photoacid | | Photoacid | | Acid diffusion | | Acid diffusion | |
| Table 3 | Resin (A) | | generator (B) | | generator (C) | | control agent (D) | | control agent (E) | |
| (continued) | Type | Amount | Type | Amount | Type | Amount | Type | Amount | Type | Amount |
| Re-26 | A-26 | 65.0 | — | — | C-16 | 33.0 | D-2 | 2.0 | — | — |
| Re-27 | A-27 | 55.0 | — | — | C-17 | 35.0 | D-2 | 10.0 | — | — |
| Re-28 | A-28 | 45.0 | — | — | C-18 | 30.0 | D-3 | 24.9 | — | — |
| Re-29 | A-29 | 40.0 | — | — | C-19 | 35.0 | D-3 | 16.1 | — | — |
| Re-30 | A-30 | 75.0 | — | — | C-20 | 17.0 | D-4 | 5.0 | — | — |
| Re-31 | A-31 | 75.0 | — | — | C-21 | 15.0 | D-4 | 4.9 | — | — |
| Re-32 | A-32 | 75.0 | — | — | C-22 | 16.0 | D-5 | 5.0 | — | — |
| Rc-33 | A-33 | 70.0 | — | — | C-23 | 22.0 | D-5 | 8.0 | — | — |
| Re-34 | A-34 | 55.0 | — | — | C-24 | 30.0 | D-6 | 15.0 | — | — |
| Re-35 | A-35 | 57.0 | B-10/B-11 | 39.0/1.0 | — | — | D-6 | 3.0 | — | — |
| Re-36 | A-36 | 65.0 | B-8/B-9 | 25.0/6.0 | — | — | D-7 | 2.0 | — | — |
| Re-37 | A-37 | 67.0 | B-6/B-7 | 20.0/10.0 | — | — | D-7 | 3.0 | — | — |
| Re-38 | A-38 | 55.0 | B-4/B-5 | 22.0/8.0 | — | — | D-8 | 15.0 | — | — |
| Re-39 | A-39 | 55.0 | B-2/B-3 | 30.0/10.0 | — | — | D-8 | 5.0 | — | — |
| Re-40 | A-40 | 46.0 | B-14 | 33.0 | — | — | D-9 | 15.0 | — | — |
| Re-41 | A-41 | 60.0 | B-15 | 27.0 | — | — | D-9 | 10.0 | — | — |
| Re-42 | A-42 | 53.0 | B-11 | 35.0 | — | — | — | — | E-1 | 7.0 |
| Re-43 | A-43 | 46.0 | B-1 | 30.0 | C-25 | 10.0 | — | — | E-2 | 10.0 |
| Re-44 | A-44 | 65.0 | B-2 | 31.0 | C-26 | 2.0 | — | — | E-3 | 2.0 |
| Re-45 | A-45 | 61.0 | B-3 | 35.0 | C-27 | 2.0 | — | — | E-4 | 2.0 |
| Re-46 | A-46 | 65.0 | B-4 | 33.0 | C-28 | 1.0 | — | — | E-5 | 1.0 |
| Re-47 | A-47 | 60.0 | B-5 | 35.0 | C-29 | 2.0 | — | — | E-6 | 3.0 |
| Re-48 | A-48 | 55.0 | B-6 | 40.0 | C-30 | 1.0 | — | — | E-7 | 4.0 |
| Re-49 | A-49 | 45.0 | B-7 | 45.0 | C-31 | 2.0 | — | — | E-8 | 8.0 |
| Re-50 | A-50 | 57.0 | B-8 | 28.0 | C-32 | 2.0 | — | — | E-9 | 10.0 |

| | Solid content | | | | | | | |
|---|---|---|---|---|---|---|---|---|
| | Acid diffusion | | | | | | Solvent (F) | |
| Table 3 | control agent (G) | | Resin (I) | | Surfactant (H) | | | Mixing ratio |
| (continued) | Type | Amount | Type | Amount | Type | Amount | Type | (mass ratio) |
| Re-26 | — | — | — | — | — | — | F-1/F-4 | 80/20 |
| Re-27 | — | — | — | — | — | — | F-1/F-2 | 80/20 |
| Re-28 | — | — | — | — | H-3 | 0.1 | F-4 | 100 |
| Re-29 | — | — | I-5 | 8.9 | — | — | F-1/F-3 | 85/15 |
| Re-30 | — | — | I-6 | 3.0 | — | — | F-1/F-5 | 80/20 |
| Re-31 | — | — | I-7 | 5.0 | H-1 | 0.1 | F-1/F-2 | 75/25 |
| Re-32 | — | — | I-8 | 4.0 | — | — | F-1/F-2/F-8 | 40/20/40 |
| Rc-33 | — | — | — | — | — | — | F-1/F-2 | 80/20 |
| Re-34 | — | — | — | — | — | — | F-1/F-9 | 80/20 |
| Re-35 | — | — | — | — | — | — | F-1/F-7 | 80/20 |
| Re-36 | — | — | I-1 | 2.0 | — | — | F-1/F-2 | 85/15 |
| Re-37 | — | — | — | — | — | — | F-1/F-2 | 90/10 |
| Re-38 | — | — | — | — | — | — | F-1/F-2/F-6 | 60/20/20 |
| Re-39 | — | — | — | — | — | — | F-1/F-2 | 90/10 |
| Re-40 | — | — | I-5 | 6.0 | — | — | F-1/F-4 | 80/20 |
| Re-41 | — | — | I-6 | 3.0 | — | — | F-1/F-2 | 80/20 |
| Re-42 | — | — | I-7 | 5.0 | — | — | F-4 | 100 |
| Re-43 | — | — | I-8 | 4.0 | — | — | F-1/F-2/F-6 | 34/33/33 |
| Re-44 | — | — | — | — | — | — | F-1/F-5 | 80/20 |
| Re-45 | — | — | — | — | — | — | F-1/F-2 | 85/15 |
| Re-46 | — | — | — | — | — | — | F-1/F-2/F-8 | 50/40/10 |
| Re-47 | — | — | — | — | — | — | F-1/F-2 | 80/20 |
| Re-48 | — | — | — | — | — | — | F-1/F-9 | 80/20 |
| Re-49 | — | — | — | — | — | — | F-1/F-7 | 60/40 |
| Re-50 | — | — | I-6 | 3.0 | — | — | F-1/F-2 | 90/10 |

TABLE 6

| | Solid content | | | | | | | | | |
|---|---|---|---|---|---|---|---|---|---|---|
| | | | Photoacid | | Photoacid | | Acid diffusion | | Acid diffusion | |
| Table 3 | Resin (A) | | generator (B) | | generator (C) | | control agent (D) | | control agent (E) | |
| (continued) | Type | Amount | Type | Amount | Type | Amount | Type | Amount | Type | Amount |
| Re-51 | A-51 | 61.0 | B-9 | 30.0 | — | — | — | — | E-10 | 9.0 |
| Re-52 | A-52 | 70.0 | B-10 | 26.0 | — | — | — | — | E-11 | 4.0 |
| Re-53 | A-53 | 75.0 | B-11 | 20.0 | — | — | — | — | E-12 | 5.0 |
| Re-54 | A-54 | 55.0 | B-12 | 35.0 | — | — | — | — | E-13 | 10.0 |
| Re-55 | A-55 | 60.0 | B-13 | 30.0 | — | — | — | — | E-14 | 10.0 |
| Re-56 | A-56 | 60.0 | B-14 | 30.0 | — | — | D-1 | 10.0 | — | — |
| Re-57 | A-57 | 53.0 | B-15 | 30.0 | — | — | D-2 | 17.0 | — | — |
| Re-58 | A-58 | 65.0 | B-2 | 30.0 | — | — | D-3 | 5.0 | — | — |
| Re-59 | A-59 | 80.0 | B-3 | 15.0 | — | — | D-4 | 5.0 | — | — |
| Re-60 | A-60 | 65.0 | B-4 | 25.0 | — | — | D-5 | 1.1 | — | — |
| Re-61 | A-61 | 45.0 | B-5 | 45.0 | — | — | D-6 | 10.0 | — | — |
| Re-1R | A-1R | 65.0 | — | — | C-33/C-34 | 15.0/10.0 | — | — | E-15 | 8.0 |
| Re-2R | A-2R | 65.0 | — | — | — | — | — | — | — | — |
| Re-3R | A-3R | 65.0 | B-1 | 25.0 | C-14 | 10.0 | — | — | — | — |
| Re-4R | A-4R | 65.0 | B-1 | 25.0 | C-14 | 10.0 | — | — | — | — |
| Re-5R | A-5R | 65.0 | — | — | C-35 | 25.0 | — | — | E-15 | 10.0 |
| Re-6R | A-1 | 65.0 | — | — | C-30 | 25.0 | — | — | E-15 | 10.0 |

| | Solid content | | | | | | | |
|---|---|---|---|---|---|---|---|---|
| | Acid diffusion | | | | | | Solvent (F) | |
| Table 3 | control agent (G) | | Resin (I) | | Surfactant (H) | | | Mixing ratio |
| (continued) | Type | Amount | Type | Amount | Type | Amount | Type | (mass ratio) |
| Re-51 | — | — | — | — | — | — | F-1/F-2 | 80/20 |
| Re-52 | — | — | — | — | — | — | F-1/F-2/F-8 | 85/12/3 |
| Re-53 | — | — | — | — | — | — | F-1/F-2 | 80/20 |
| Re-54 | — | — | — | — | — | — | F-1/F-4 | 80/20 |
| Re-55 | — | — | — | — | — | — | F-1/F-2 | 60/40 |
| Re-56 | — | — | — | — | — | — | F-4 | 100 |
| Re-57 | — | — | — | — | — | — | F-1/F-2 | 80/20 |
| Re-58 | — | — | — | — | — | — | F-1/F-5 | 80/20 |
| Re-59 | — | — | — | — | — | — | F-1/F-2 | 80/20 |
| Re-60 | — | — | I-5 | 8.9 | — | — | F-1/F-2/F-8 | 34/33/33 |
| Re-61 | — | — | — | — | — | — | F-1/F-2 | 80/20 |
| Re-1R | G-1 | 2.0 | — | — | — | — | F-1/F-2 | 80/20 |
| Re-2R | — | — | — | — | — | — | F-1/F-2 | 80/20 |
| Re-3R | — | — | — | — | — | — | F-1/F-2 | 80/20 |
| Re-4R | — | — | — | — | — | — | F-1/F-2 | 80/20 |
| Re-5R | — | — | — | — | — | — | F-1/F-2 | 80/20 |
| Re-6R | — | — | — | — | — | — | F-1/F-2 | 80/20 |

### Pattern Formation

### EUV Exposure, Organic Solvent Development

An underlayer film-forming composition AL412 (manufactured by Brewer Science, Inc.) was applied onto a silicon wafer having a diameter of 12 inches and baked at 205° C. for 60 seconds to form an underlying film having a film thickness of 20 nm. A resist composition described in Table 3 was applied thereonto and baked at 100° C. for 60 seconds to form a resist film having a film thickness of 30 nm.

An EUV exposure apparatus (manufactured by Exitech Ltd., Micro Exposure Tool, NA: 0.3, Quadrupole, outer sigma: 0.68, inner sigma: 0.36) was used to subject the obtained silicon wafer having the resist film to pattern irradiation such that the resultant pattern would have an average line width of 14 nm. Note that the reticle employed was a mask having a line size=14 nm and a line:space=1:1.

The exposed resist film was baked at 90° C. for 60 seconds, and subsequently developed with n-butyl acetate for 30 seconds; and this was spin-dried to obtain a negative pattern.

### Evaluation

### Defect Evaluation (Defect Suppression Performance)

For the patterns obtained by the above-described method, UVision5 (manufactured by AMAT Inc.) and SEMVisionG4 (manufactured by AMAT Inc.) were used to count the number of defects per silicon wafer and evaluation was performed in accordance with the following evaluation grades. The smaller the number of defects, the better the defect suppression performance; “E” or higher grades can be regarded as passes.
“A”: The number of defects is 50 or less.
“B”: The number of defects is more than 50 and 100 or less.
“C”: The number of defects is more than 100 and 200 or less.
“D”: The number of defects is more than 200 and 300 or less.
“E”: The number of defects is more than 300 and 500 or less.
“F”: The number of defects is more than 500.

### Roughness Performance

The roughness performance was evaluated on the basis of line width roughness (LWR performance, nm).

The patterns obtained by the above-described method were observed from above the patterns using a critical dimension-scanning electron microscope (SEM, Hitachi, Ltd., S-9380II)). The line widths of such a pattern were observed at 250 points, and the standard deviation (a) thereof was determined. The measurement variation of the line widths was evaluated on the basis of 36, and the value of 36 was defined as LWR (nm). The smaller the value of LWR, the better the LWR performance.

The LWR (nm) is preferably 4.5 nm or less, more preferably 4.2 nm or less, even more preferably 3.9 nm or less, still more preferably 3.6 nm or less, particularly preferably 3.3 nm or less, and most preferably 3.0 nm or less.

TABLE 7

| | | Evaluation item 1 | Evaluation item 2 |
|---|---|---|---|
| | Resist | Defect suppression | LWR performance |
| Table 4 | composition | performance | (nm) |
| Example 1-1 | Re-1 | B | 3.2 |
| Example 1-2 | Re-2 | A | 2.8 |
| Example 1-3 | Re-3 | A | 2.9 |
| Example 1-4 | Re-4 | A | 2.8 |
| Example 1-5 | Re-5 | A | 3.0 |
| Example 1-6 | Re-6 | B | 3.1 |
| Example 1-7 | Re-7 | C | 3.6 |
| Example 1-8 | Re-8 | D | 3.8 |
| Example 1-9 | Re-9 | D | 3.7 |
| Example 1-10 | Re-10 | D | 3.9 |
| Example 1-11 | Re-11 | D | 3.9 |
| Example 1-12 | Re-12 | C | 3.5 |
| Example 1-13 | Re-13 | C | 3.4 |
| Example 1-14 | Re-14 | D | 3.7 |
| Example 1-15 | Re-15 | E | 4.4 |
| Example 1-16 | Re-16 | D | 3.8 |
| Example 1-17 | Re-17 | C | 3.4 |
| Example 1-18 | Re-18 | E | 4.2 |
| Example 1-19 | Re-19 | C | 3.5 |
| Example 1-20 | Re-20 | C | 3.4 |
| Example 1-21 | Re-21 | C | 3.6 |
| Example 1-22 | Re-22 | C | 3.4 |
| Example 1-23 | Re-23 | C | 3.4 |
| Example 1-24 | Re-24 | C | 3.5 |
| Example 1-25 | Re-25 | C | 3.5 |
| Example 1-26 | Re-26 | D | 3.8 |
| Example 1-27 | Re-27 | D | 3.8 |
| Example 1-28 | Re-28 | C | 3.4 |
| Example 1-29 | Re-29 | D | 3.9 |
| Example 1-30 | Re-30 | A | 2.9 |
| Example 1-31 | Re-31 | A | 2.9 |
| Example 1-32 | Re-32 | A | 2.8 |
| Example 1-33 | Re-33 | A | 3.0 |
| Example 1-34 | Re-34 | A | 2.8 |
| Example 1-35 | Re-35 | A | 2.8 |

TABLE 8

| | | Evaluation | Evaluation |
|---|---|---|---|
| | | item 1 | item 2 |
| | | Defect | LWR |
| Table 4 | Resist | suppression | performance |
| (continued) | composition | performance | (nm) |
| Example 1-36 | Re-36 | A | 2.8 |
| Example 1-37 | Re-37 | A | 2.9 |
| Example 1-38 | Re-38 | A | 2.8 |
| Example 1-39 | Re-39 | A | 2.9 |
| Example 1-40 | Re-40 | A | 2.9 |
| Example 1-41 | Re-41 | A | 3.0 |
| Example 1-42 | Re-42 | A | 2.8 |
| Example 1-43 | Re-43 | A | 2.9 |
| Example 1-44 | Re-44 | B | 3.1 |
| Example 1-45 | Re-45 | A | 3.0 |
| Example 1-46 | Re-46 | A | 2.9 |
| Example 1-47 | Re-47 | A | 2.8 |
| Example 1-48 | Re-48 | A | 2.8 |
| Example 1-49 | Re-49 | A | 2.9 |
| Example 1-50 | Re-50 | A | 3.0 |
| Example 1-51 | Re-51 | A | 2.9 |
| Example 1-52 | Re-52 | A | 2.9 |
| Example 1-53 | Re-53 | A | 2.8 |
| Example 1-54 | Re-54 | A | 3.0 |
| Example 1-55 | Re-55 | A | 2.9 |
| Example 1-56 | Re-56 | A | 2.9 |
| Example 1-57 | Re-57 | A | 2.8 |
| Example 1-58 | Re-58 | A | 3.0 |
| Example 1-59 | Re-59 | A | 2.9 |
| Example 1-60 | Re-60 | A | 2.9 |
| Example 1-61 | Re-61 | A | 2.8 |
| Comparative Example 1-1 | Re-1R | F | 5.1 |
| Comparative Example 1-2 | Re-2R | F | 5.2 |
| Comparative Example 1-3 | Re-3R | F | 5.1 |
| Comparative Example 1-4 | Re-4R | F | 5.2 |
| Comparative Example 1-5 | Re-5R | F | 5.1 |
| Comparative Example 1-6 | Re-6R | F | 5.1 |

Table 4 above has demonstrated that resist compositions of the present invention exhibit high defect performance (defect suppression performance) and high roughness performance in the case of forming a pattern by organic solvent development. On the other hand, the resist compositions of Comparative Examples were insufficient in terms of these performances.

### EUV Exposure, Alkaline Aqueous Solution Development

An underlayer film-forming composition AL412 (manufactured by Brewer Science, Inc.) was applied onto a silicon wafer having a diameter of 12 inches and baked at 205° C. for 60 seconds to form an underlying film having a film thickness of 20 nm. A resist composition described in Table 3 was applied thereonto and baked at 100° C. for 60 seconds to form a resist film having a film thickness of 30 nm.

An EUV exposure apparatus (manufactured by Exitech Ltd., Micro Exposure Tool, NA: 0.3, Quadrupole, outer sigma: 0.68, inner sigma: 0.36) was used to subject the obtained silicon wafer having the resist film to pattern irradiation such that the resultant pattern would have an average line width of 14 nm. Note that the reticle employed was a mask having a line size=14 nm and a line:space=1:1.

The exposed resist film was baked at 90° C. for 60 seconds, subsequently developed with an aqueous tetramethylammonium hydroxide solution (2.38 mass %) for 30 seconds, and subsequently rinsed with pure water for 30 seconds. Subsequently, this was spin-dried to obtain a positive pattern.

The obtained positive pattern was subjected to, in the same manner as described above, evaluation of the defect suppression performance and the LWR performance.

The evaluation results will be described in Table 5 below.

TABLE 9

| | | Evaluation item 1 | Evaluation item 2 |
|---|---|---|---|
| | Resist | Defect suppression | LWR performance |
| Table 5 | composition | performance | (nm) |
| Example 2-1 | Re-1 | B | 3.1 |
| Example 2-2 | Re-2 | A | 2.8 |
| Example 2-3 | Re-3 | A | 2.9 |
| Example 2-4 | Re-4 | A | 2.9 |
| Example 2-5 | Re-5 | A | 3.0 |
| Example 2-6 | Re-6 | B | 3.1 |
| Example 2-7 | Re-7 | C | 3.6 |
| Example 2-8 | Re-8 | D | 3.8 |
| Example 2-9 | Re-9 | D | 3.8 |
| Example 2-10 | Re-10 | D | 3.7 |
| Example 2-11 | Re-11 | D | 3.9 |
| Example 2-12 | Re-12 | C | 3.5 |
| Example 2-13 | Re-13 | C | 3.4 |
| Example 2-14 | Re-14 | D | 3.7 |
| Example 2-15 | Re-15 | E | 4.5 |
| Example 2-16 | Re-16 | D | 3.8 |
| Example 2-17 | Re-17 | C | 3.4 |
| Example 2-18 | Re-18 | E | 4.3 |
| Example 2-19 | Re-19 | C | 3.5 |
| Example 2-20 | Re-20 | C | 3.6 |
| Example 2-21 | Re-21 | C | 3.5 |
| Example 2-22 | Re-22 | C | 3.4 |
| Example 2-23 | Re-23 | C | 3.4 |
| Example 2-24 | Re-24 | C | 3.5 |
| Example 2-25 | Re-25 | C | 3.4 |
| Example 2-26 | Re-26 | D | 3.7 |
| Example 2-27 | Re-27 | D | 3.8 |
| Example 2-28 | Re-28 | C | 3.4 |
| Example 2-29 | Re-29 | D | 3.9 |
| Example 2-30 | Re-30 | A | 2.9 |
| Example 2-31 | Re-31 | A | 2.8 |
| Example 2-32 | Re-32 | A | 2.8 |
| Example 2-33 | Re-33 | A | 3.0 |
| Example 2-34 | Re-34 | A | 2.8 |
| Example 2-35 | Re-35 | A | 2.8 |

TABLE 10

| | | Evaluation | Evaluation |
|---|---|---|---|
| | | item 1 | item 2 |
| | | Defect | LWR |
| Table 5 | Resist | suppression | performance |
| (continued) | composition | performance | (nm) |
| Example 2-36 | Re-36 | A | 2.8 |
| Example 2-37 | Re-37 | A | 2.9 |
| Example 2-38 | Re-38 | A | 2.8 |
| Example 2-39 | Re-39 | A | 2.8 |
| Example 2-40 | Re-40 | A | 2.9 |
| Example 2-41 | Re-41 | A | 3.0 |
| Example 2-42 | Re-42 | A | 2.8 |
| Example 2-43 | Re-43 | A | 2.9 |
| Example 2-44 | Re-44 | B | 3.1 |
| Example 2-45 | Re-45 | A | 3.0 |
| Example 2-46 | Re-46 | A | 2.9 |
| Example 2-47 | Re-47 | A | 2.8 |
| Example 2-48 | Re-48 | A | 2.9 |
| Example 2-49 | Re-49 | A | 2.8 |
| Example 2-50 | Re-50 | A | 3.0 |
| Example 2-51 | Re-51 | A | 2.9 |
| Example 2-52 | Re-52 | A | 2.9 |
| Example 2-53 | Re-53 | A | 2.8 |
| Example 2-54 | Re-54 | A | 2.9 |
| Example 2-55 | Re-55 | A | 2.8 |
| Example 2-56 | Re-56 | A | 2.9 |
| Example 2-57 | Re-57 | A | 2.8 |
| Example 2-58 | Re-58 | A | 3.0 |
| Example 2-59 | Re-59 | A | 2.8 |
| Example 2-60 | Re-60 | A | 3.0 |
| Example 2-61 | Re-61 | A | 2.8 |
| Comparative Example 2-1 | Re-1R | F | 5.1 |
| Comparative Example 2-2 | Re-2R | F | 5.2 |
| Comparative Example 2-3 | Re-3R | F | 5.1 |
| Comparative Example 2-4 | Re-4R | F | 5.2 |
| Comparative Example 2-5 | Re-5R | F | 5.1 |
| Comparative Example 2-6 | Re-6R | F | 5.1 |

Table 5 above has demonstrated that resist compositions of the present invention exhibit high defect performance (defect suppression performance) and high roughness performance even in the case of forming a pattern by alkali development. On the other hand, the resist compositions of Comparative Examples were insufficient in terms of these performances.

Note that, even in the case of using an electron beam as the exposure light source, resist compositions of the present invention exhibit high defect performance (defect suppression performance) and high roughness performance in the case of forming an ultrafine pattern as in Examples 1-1 to 1-61 and Examples 2-1 to 2-61.

The present invention can provide an actinic ray-sensitive or radiation-sensitive resin composition having both of high defect suppression performance and high roughness performance in formation of an ultrafine pattern (for example, a line-and-space pattern having a line width or a space width of 30 nm or less, or a hole pattern having a hole diameter of 30 nm or less); an actinic ray-sensitive or radiation-sensitive film formed from the actinic ray-sensitive or radiation-sensitive resin composition; and a pattern forming method and a method for producing an electronic device that use the actinic ray-sensitive or radiation-sensitive resin composition.

The present invention has been described in detail and with reference to specific embodiments thereof; however, it would be apparent to those skilled in the art that various changes and modifications can be made therein without departing from the spirit and scope of the present invention.

What is claimed is:

1. An actinic ray-sensitive or radiation-sensitive resin composition comprising:
a resin (A) including a repeating unit (i) represented by a formula (1) below and a repeating unit (ii) represented by a formula (2) below; and
an ionic compound (Y) having an anionic moiety represented by a formula (3) below in which a structure represented by “—SO₂—N⁻—” in the anionic moiety has a pKa of −3.00 or more, 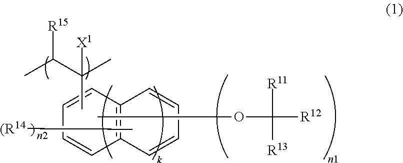
wherein, in the formula (1), X¹ represents a hydrogen atom, a halogen atom, a hydroxy group, or an organic group,
R¹¹ to R¹³ each independently represent an alkyl group having 1 to 12 carbon atoms or a cycloalkyl group having 3 to 12 carbon atoms, and any two among R¹¹ to R¹³ may be bonded together to form a ring,
R¹⁴ represents a halogen atom, a hydroxy group, or an organic group,
R¹⁵ represents a hydrogen atom or an organic group, and R¹⁵ may be bonded to R¹⁴ to form a ring,
k represents 0 or 1,
n1 represents an integer of 1 to 2k+5,
n2 represents an integer of 0 to 2k+4, 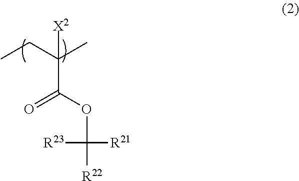
in the formula (2), X² represents a hydrogen atom, a halogen atom, a hydroxy group, or an organic group,
R²¹ to R²³ each independently represent a hydrocarbon group having 1 to 12 carbon atoms, any two among R²¹ to R²³ may be bonded together to form a ring, and a part of alkylene groups in R²¹ to R²³ may be converted into an ether group, a thioether group, or a carbonyl group, 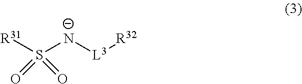
in the formula (3), R³¹ and R³² represent an organic group, and
L³ represents a single bond or a divalent linking group.

2. The actinic ray-sensitive or radiation-sensitive resin composition according to claim 1, wherein the repeating unit represented by the formula (1) is a repeating unit represented by a formula (1A) below: 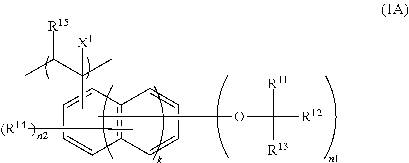
in the formula (1A), X¹ represents a hydrogen atom, a halogen atom, a hydroxy group, or an organic group,
R¹¹ to R¹³ each independently represent an alkyl group having 1 to 12 carbon atoms or a cycloalkyl group having 3 to 12 carbon atoms, and any two among R¹¹ to R¹³ may be bonded together to form a ring,
R¹⁴ represents a halogen atom, a hydroxy group, or an organic group,
R¹⁵ represents a hydrogen atom or an organic group, and R¹⁵ may be bonded to R¹⁴ to form a ring,
k represents 0 or 1,
n1 represents an integer of 1 to 2k+5, and
n2 represents an integer of 0 to 2k+4.

3. The actinic ray-sensitive or radiation-sensitive resin composition according to claim 1, wherein the repeating unit represented by the formula (1) is a repeating unit represented by a formula (1a) below: 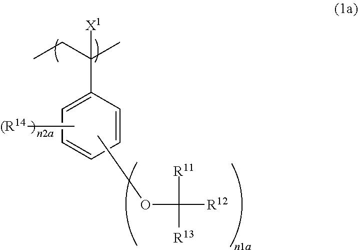
in the formula (1a), X represents a hydrogen atom, a halogen atom, a hydroxy group, or an organic group,
R¹¹ to R¹³ each independently represent an alkyl group having 1 to 12 carbon atoms or a cycloalkyl group having 3 to 12 carbon atoms, and any two among R¹¹ to R¹³ may be bonded together to form a ring,
R¹⁴ represents a halogen atom, a hydroxy group, or an organic group,
n1a represents an integer of 1 to 5, and
n2a represents an integer of 0 to 4.

4. The actinic ray-sensitive or radiation-sensitive resin composition according to claim 1, wherein the anionic moiety represented by the formula (3) is an anionic moiety represented by a formula (3-1) below: 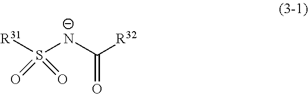
in the formula (3-1), R³¹ and R³² represent an organic group.

5. The actinic ray-sensitive or radiation-sensitive resin composition according to claim 1, wherein the repeating unit represented by the formula (2) is a repeating unit represented by a formula (2a) or a formula (2b) below: 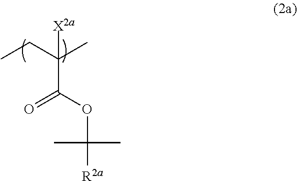
in the formula (2a), X^{2a} represents a hydrogen atom, a halogen atom, or a methyl group,
R^{2a} represents a methyl group, an ethyl group, a phenyl group, or an adamantyl group, 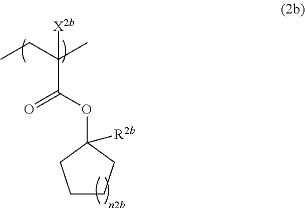
in the formula (2b), X^{2b} represents a hydrogen atom, a halogen atom, or a methyl group,
R^{2b} represents a hydrocarbon group having 6 or less carbon atoms, and
n2b represents 1 or 2.

6. The actinic ray-sensitive or radiation-sensitive resin composition according to claim 3, wherein the repeating unit represented by the formula (1a) is a repeating unit represented by a formula (1b) below: 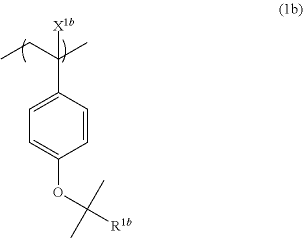
in the formula (1b), X^{1b} represents a hydrogen atom, a halogen atom, or a methyl group, and
R^{1b} represents a methyl group or an ethyl group.

7. The actinic ray-sensitive or radiation-sensitive resin composition according to claim 5, wherein the repeating unit represented by the formula (2b) is a repeating unit represented by a formula (2c) below: 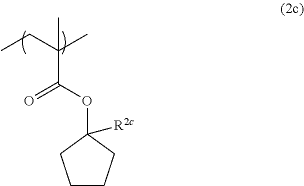
in the formula (2c), R^{2c} represents a methyl group, an ethyl group, an isopropyl group, a t-butyl group, or a phenyl group.

8. The actinic ray-sensitive or radiation-sensitive resin composition according to claim 1, wherein the resin (A) contains a repeating unit (iii) having a phenolic hydroxyl group.

9. An actinic ray-sensitive or radiation-sensitive film formed from the actinic ray-sensitive or radiation-sensitive resin composition according to claim 1.

10. A pattern forming method comprising:
using the actinic ray-sensitive or radiation-sensitive resin composition according to claim 1 to form an actinic ray-sensitive or radiation-sensitive film on a substrate;
exposing the actinic ray-sensitive or radiation-sensitive film; and
using a developer to develop the exposed actinic ray-sensitive or radiation-sensitive film to form a pattern.

11. A method for producing an electronic device, the method comprising the pattern forming method according to claim 10.
